(19) United States
(12) Patent Application Publication
(10) Pub. No.: US 2026/0282572 A1
(43) Pub. Date: Sep. 17, 2026

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventors: RYOSUKE YAMACHI, KANAGAWA (JP); SHINJI FUKUMOTO, KANAGAWA (JP); SHINICHI MIYAKE, KANAGAWA (JP); HISASHI CHIBA, KANAGAWA (JP); AKIKO HONJO, KANAGAWA (JP); AKITO SHIMIZU, KANAGAWA (JP); HIDETOSHI OISHI, KANAGAWA (JP); MASAO KANDA, KANAGAWA (JP)

(21) Appl. No.: 19/167,433

(22) PCT Filed: Jan. 31, 2024
(86) PCT No.: PCT/JP2024/003141

§ 371 Date: Sep. 22, 2025

(30) Foreign Application Priority Data
Mar. 31, 2023 (JP) 2023-058860

(51) Int. Cl. H10F 39/00; H04N 25/778; H10F 39/18

(52) U.S. Cl. CPC H10F 39/80373; H04N 25/778; H10F 39/014; H10F 39/18; H10F 39/807; H10F 39/811

(57) ABSTRACT

A light detection device capable of securing an arrangement space of pixel transistors, even when pixels are miniaturized, is provided. The light detection device includes a semiconductor layer, an inter-pixel separation part, and a plurality of pixel transistors. The semiconductor layer has a first surface part and a second surface part positioned on sides opposite to each other in a thickness direction, and plurality of pixels generating electric charge through photoelectric conversion based on light incident in the first surface part are formed in a matrix pattern in a plan view. The inter-pixel separation part has an upper surface port positioned on the second surface part side of the semiconductor layer, extends in the thickness direction of the semiconductor layer, and separates the pixels adjacent to each other. At least one of the plurality of pixel transistors has a gate electrode crossing two or more pixels adjacent to each other across an upper surface part of the inter-pixel separation part in a plan view.

### TECHNICAL FIELD

A technology according to the present disclosure (present technique) relates to a light detection device and an electronic device including the light detection device.

### BACKGROUND ART

As a solid-state imaging device, a complementary metal oxide semiconductor (CMOS) image sensor is known. The CMOS image sensor has a low power supply voltage and low power consumption and thus is used in digital still cameras, digital video cameras, and various portable terminal devices such as cellular phones with cameras, printers, and the like. The CMOS image sensor is configured such that each of pixels arranged in a pixel region is configured to include a plurality of pixel transistors in addition to a photodiode that is a photoelectric conversion unit.

In recent years, in conjunction with miniaturization of the pixels, a so-called multiple-pixel sharing structure, i.e., a structure in which the occupancy area of components, other than a photodiode, per pixel is suppressed by sharing among a plurality of pixels a pixel transistor, has become an essential technology.

In CMOS image sensors of recent years, in order to suppress color mixture, an inter-pixel separation part separating pixels from each other is configured by using a full trench. For this reason, it is difficult to form a multiple-pixel sharing structure.

In an invention described in PTL 1, a multiple-pixel sharing structure is realized by routing wiring across an inter-pixel separation part.

### CITATION LIST

### Patent Literature

### PTL 1

US 2022/0052084

### SUMMARY

### Technical Problem

However, due to miniaturization of pixels the area occupied by an inter-pixel separation part becomes large.

The present disclosure has been made in consideration of such situations, and an object thereof is to provide a light detection device and an electronic device capable of securing a space in which pixel transistors are disposed even when pixels are miniaturized.

### Solution to Problem

One aspect of the present disclosure is a light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; an inter-pixel separation part that extends in the thickness direction of the semiconductor layer and separates the pixels adjacent to each other; and a plurality of pixel transistors that are formed on the second surface part of the semiconductor layer and configure a reading circuit that outputs a pixel signal based on the electric charge, in which the inter-pixel separation part has an upper surface part positioned on the second surface part side of the semiconductor layer, and at least one of the plurality of pixel transistors has a gate electrode crossing two or more adjacent pixels across an upper surface part of the inter-pixel separation part in a plan view.

Another aspect of the present disclosure is an electronic device including a light detecting device that includes: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; an inter-pixel separation part that extends in the thickness direction of the semiconductor layer and separates the pixels adjacent to each other; and a plurality of pixel transistors that are formed on the second surface part of the semiconductor layer and configure a reading circuit that outputs a pixel signal based on the electric charge, in which the inter-pixel separation part has an upper surface part positioned on the second surface part side of the semiconductor layer, and at least one of the plurality of pixel transistors has a gate electrode crossing two or more adjacent pixels across an upper surface part of the inter-pixel separation part in a plan view.

### BRIEF DESCRIPTION OF DRAWINGS

FIG. 1 is a chip layout diagram showing a configuration example of a light detection device according to a first embodiment of the present technique.

FIG. 2 is a block diagram showing a configuration example of the light detection device according to the first embodiment of the present technique.

FIG. 3 is an equivalent circuit diagram illustrating a configuration example of a sensor pixel and a pixel circuit according to the first embodiment of the present technique.

FIG. 4 is a plan view schematically illustrating a configuration example of a pixel block included in a pixel array unit of FIG. 1.

FIG. 5 is a plan view illustrating an example of an arrangement pattern of pixel transistors in a pixel.

FIG. 6 is a diagram illustrating an example of a schematic cross-sectional structure of an a1-a2 cross-section of the amplification transistor illustrated in FIG. 5.

FIG. 7A is a cross-sectional view (1) illustrating a processing sequence of a method of manufacturing a pixel transistor according to the first embodiment of the present technique.

FIG. 7B is a cross-sectional view (2) illustrating a processing sequence of a method of manufacturing a pixel transistor according to the first embodiment of the present technique.

FIG. 7C is a cross-sectional view (3) illustrating a processing sequence of a method of manufacturing a pixel transistor according to the first embodiment of the present technique.

FIG. 7D is a cross-sectional view (4) illustrating a processing sequence of a method of manufacturing a pixel transistor according to the first embodiment of the present technique.

FIG. 8 is a cross-sectional view illustrating an embedding structure of a pixel transistor for an inter-pixel separation part according to a second embodiment of the present technique.

FIG. 9 is a cross-sectional view illustrating an embedding structure of a pixel transistor for an inter-pixel separation part as a comparative example of the second embodiment.

FIG. 10 is a cross-sectional view illustrating an embedding structure of a pixel transistor for an inter-pixel separation part according to a third embodiment of the present technique.

FIG. 11 is a cross-sectional view illustrating an embedding structure of a pixel transistor for an inter-pixel separation part according to a fourth embodiment of the present technique.

FIG. 12 is a plan view illustrating an example of an arrangement pattern of an amplification transistor in a pixel according to a fifth embodiment of the present technique.

FIG. 13 is a diagram illustrating an example of a schematic cross-section structure of the amplification transistor illustrated in FIG. 12 on a b1-b2 cross-section.

FIG. 14A is a plan view illustrating an example of an arrangement pattern of an amplification transistor in a pixel according to a sixth embodiment of the present technique.

FIG. 14B is a diagram illustrating an example of a schematic cross-section structure of the amplification transistor illustrated in FIG. 14A on a c1-c2 cross-section.

FIG. 15A is a plan view illustrating an example of an arrangement pattern of an amplification transistor in a pixel 3 according to a seventh embodiment of the present technique.

FIG. 15B is a diagram illustrating an example of a schematic cross-section structure of the amplification transistor AMP illustrated in FIG. 15A on a d1-d2 cross-section.

FIG. 15C is a diagram illustrating an example of a schematic cross-section structure of the amplification transistor AMP illustrated in FIG. 15A on a d3-d4 cross-section.

FIG. 16A is a plan view illustrating an example of an arrangement pattern of an amplification transistor AMP in a pixel 3 according to an eighth embodiment of the present technique.

FIG. 16B is a diagram illustrating an example of a schematic cross-section structure of the amplification transistor AMP illustrated in FIG. 16A on an e1-e2 cross-section.

FIG. 16C is a diagram illustrating an example of a schematic cross-section structure of the amplification transistor AMP illustrated in FIG. 16A on an e3-e4 cross-section.

FIG. 17A is a plan view illustrating an example of an arrangement pattern of an amplification transistor AMP in a pixel 3 according to a ninth embodiment of the present technique.

FIG. 17B is a diagram illustrating an example of a schematic cross-section structure of the amplification transistor AMP illustrated in FIG. 17A on an f1-f2 cross-section.

FIG. 17C is a diagram illustrating an example of a schematic cross-section structure of the amplification transistor AMP illustrated in FIG. 17A on an f3-f4 cross-section.

FIG. 18A is a plan view illustrating an example of an arrangement pattern of an amplification transistor AMP in a pixel 3 according to a 10th embodiment of the present technique.

FIG. 18B is a diagram illustrating an example of a schematic cross-sectional structure of the amplification transistor AMP illustrated in FIG. 18A on a g1-g2 cross-section.

FIG. 19A is a plan view illustrating an example of an arrangement pattern of an amplification transistor AMP in a pixel 3 according to an 11th embodiment of the present technique.

FIG. 19B is a diagram illustrating an example of a schematic cross-sectional structure of the amplification transistor AMP illustrated in FIG. 19A on an h1-h2 cross-section.

FIG. 20 is a plan view illustrating an example of an arrangement pattern of an amplification transistor AMP in a pixel 3 according to a 12th embodiment of the present technique.

FIG. 21 is a plan view illustrating an example of an arrangement pattern of an amplification transistor AMP in a pixel 3 according to a 13th embodiment of the present technique.

FIG. 22A is a plan view illustrating an example of an arrangement pattern of an amplification transistor AMP in a pixel 3 according to a 14th embodiment of the present technique.

FIG. 22B is a diagram illustrating an example of a schematic cross-sectional structure of the amplification transistor AMP illustrated in FIG. 22A on an i1-i2 cross-section.

FIG. 23 is a cross-sectional view illustrating an embedded structure of a pixel transistor in an inter-pixel separation part according to a 15th embodiment of the present technique.

FIG. 24 is a cross-sectional view illustrating an embedded structure of a pixel transistor in an inter-pixel separation part according to a 16th embodiment of the present technique.

FIG. 25 is a cross-sectional view illustrating an embedded structure of a pixel transistor in an inter-pixel separation part according to a 17th embodiment of the present technique.

FIG. 26 is a plan view schematically illustrating one configuration example of a pixel block included in a pixel array unit of a light detection device according to an 18th embodiment of the present technique.

FIG. 27 is a plan view schematically illustrating one configuration example of a pixel block included in a pixel array unit of a light detection device according to a 19th embodiment of the present technique.

FIG. 28 is a plan view schematically illustrating one configuration example of a pixel block included in a pixel array unit of a light detection device according to a 20th embodiment of the present technique.

FIG. 29 is a plan view schematically illustrating one configuration example of a pixel block included in a pixel array unit of a light detection device according to a 21st embodiment of the present technique.

FIG. 30 is a plan view illustrating an example of an arrangement pattern of a pixel transistor according to a modified example of the 21st embodiment of the present technique.

FIG. 31 is a plan view illustrating an example of an arrangement pattern of a pixel transistor according to a comparative example of the 21st embodiment.

FIG. 32 is a plan view schematically illustrating one configuration example of a pixel block included in a pixel array unit of a light detection device according to a 22nd embodiment of the present technique.

FIG. 33 is a plan view schematically illustrating one configuration example of a pixel block included in a pixel array unit of a light detection device according to a 23rd embodiment of the present technique.

FIG. 34 is a plan view schematically illustrating one configuration example of a pixel block included in a pixel array unit of a light detection device according to a 24th embodiment of the present technique.

FIG. 35 is a plan view schematically illustrating one configuration example of a pixel block included in a pixel array unit of a light detection device according to a 25th embodiment of the present technique.

FIG. 36 is a plan view schematically illustrating one configuration example of a pixel block included in a pixel array unit of a light detection device according to a 26th embodiment of the present technique.

FIG. 37 is a plan view schematically illustrating one configuration example of a pixel block included in a pixel array unit of a light detection device according to a 27th embodiment of the present technique.

FIG. 38 is a circuit block diagram illustrating a reading circuit 16A of a light detection device according to a 28th embodiment of the present technique.

FIG. 39 is a plan view, for example, illustrating an example of an arrangement pattern of a selection transistor in a pixel.

FIG. 40 is a plan view illustrating an example of an arrangement pattern of a selection transistor SEL in a pixel according to a 29th embodiment of the present technique.

FIG. 41 is a plan view illustrating an example of an arrangement pattern of a selection transistor SEL in a pixel 3 according to a 30th embodiment of the present technique.

FIG. 42 is a plan view illustrating an example of an arrangement pattern of a selection transistor SEL in a pixel 3 according to a 31st embodiment of the present technique.

FIG. 43A is a plan view illustrating an example of an arrangement pattern of a selection transistor SEL in a pixel 3 according to a 32nd embodiment of the present technique.

FIG. 43B is a diagram illustrating an example of a schematic cross-section structure of the selection transistor SEL illustrated in FIG. 43A on a j1-j2 cross-section.

FIG. 44 is a plan view illustrating an example of an arrangement pattern of a selection transistor SEL in a pixel 3 according to a modified example of the 32nd embodiment of the present technique.

FIG. 45 is a circuit configuration diagram illustrating a serial connection of two reset transistors RST as a 33rd embodiment of the present technique.

FIG. 46 is a circuit configuration diagram illustrating a serial connection of a plurality of selection transistors as a 33rd embodiment of the present technique.

FIG. 47 is a plan view schematically illustrating a configuration example of a pixel block included in a pixel array unit of a light detection device according to a 34th embodiment of the present technique.

FIG. 48 is a partial longitudinal cross-sectional view illustrating an example of a semiconductor structure of a pixel on an A1-A2 cross-section illustrated in FIG. 47.

FIG. 49A is a plan view schematically illustrating a configuration example of a pixel block included in a pixel array unit of a light detection device according to a first modified example of a 34th embodiment of the present technique.

FIG. 49B is a plan view schematically illustrating a configuration example of a pixel block included in a pixel array unit of a light detection device according to a second modified example of the 34th embodiment of the present technique.

FIG. 49C is a plan view schematically illustrating a configuration example of a pixel block included in a pixel array unit of a light detection device according to a third modified example of the 34th embodiment of the present technique.

FIG. 49D is a plan view schematically illustrating a configuration example of a pixel block included in a pixel array unit of a light detection device according to a fourth modified example of the 34th embodiment of the present technique.

FIG. 49E is a plan view schematically illustrating a configuration example of a pixel block included in a pixel array unit of a light detection device according to a fifth modified example of the 34th embodiment of the present technique.

FIG. 49F is a plan view schematically illustrating a configuration example of a pixel block included in a pixel array unit of a light detection device according to a sixth modified example of the 34th embodiment of the present technique.

FIG. 49G is a plan view schematically illustrating a configuration example of a pixel block included in a pixel array unit of a light detection device according to a seventh modified example of the 34th embodiment of the present technique.

FIG. 50 is a plan view schematically illustrating a configuration example of a pixel block included in a pixel array unit of a light detection device according to a 35th embodiment of the present technique.

FIG. 51 is a partial longitudinal cross-sectional view illustrating an example of a semiconductor structure of a pixel illustrated in FIG. 50 on a B1-B2 cross-section.

FIG. 52 is a plan view schematically illustrating a configuration example of a pixel block included in a pixel array unit of a light detection device according to a first modified example of the 35th embodiment of the present technique.

FIG. 53 is a plan view schematically illustrating a configuration example of a pixel block included in a pixel array unit of a light detection device according to a second modified example of the 35th embodiment of the present technique.

FIG. 54A is a plan view schematically illustrating a configuration example of a pixel block included in a pixel array unit of a light detection device according to a third modified example of the 35th embodiment of the present technique.

FIG. 54B is a plan view schematically illustrating a configuration example of a pixel block included in a pixel array unit of a light detection device according to a fourth modified example of the 35th embodiment of the present technique.

FIG. 54C is a plan view schematically illustrating a configuration example of a pixel block included in a pixel array unit of a light detection device according to a fifth modified example of the 35th embodiment of the present technique.

FIG. 54D is a plan view schematically illustrating a configuration example of a pixel block included in a pixel array unit of a light detection device according to a sixth modified example of the 35th embodiment of the present technique.

FIG. 55 is a plan view schematically illustrating a configuration example of a pixel block included in a pixel array unit of a light detection device according to a 36th embodiment of the present technique.

FIG. 56 is a partial longitudinal cross-sectional view illustrating an example of a semiconductor structure of a pixel on a C1-C2 cross-section illustrated in FIG. 55.

FIG. 57A is a plan view schematically illustrating a configuration example of a pixel block included in a pixel array unit of a light detection device according to a first modified example of the 36th embodiment of the present technique.

FIG. 57B is a plan view schematically illustrating a configuration example of a pixel block included in a pixel array unit of a light detection device according to a second modified example of the 36th embodiment of the present technique.

FIG. 57C is a plan view schematically illustrating a configuration example of a pixel block included in a pixel array unit of a light detection device according to a third modified example of the 36th embodiment of the present technique.

FIG. 57D is a plan view schematically illustrating a configuration example of a pixel block included in a pixel array unit of a light detection device according to a fourth modified example of the 36th embodiment of the present technique.

FIG. 58 is a plan view schematically illustrating a configuration example of a pixel block included in a pixel array unit of a light detection device according to a 37th embodiment of the present technique.

FIG. 59 is a partial longitudinal cross-sectional view illustrating an example of a semiconductor structure of a pixel on a D1-D2 cross-section illustrated in FIG. 58.

FIG. 60 is a plan view schematically illustrating a configuration example of a pixel block included in a pixel array unit of a light detection device according to a 38th embodiment of the present technique.

FIG. 61 is a partial longitudinal cross-sectional view illustrating an example of a semiconductor structure of a pixel on an E1-E2 cross-section illustrated in FIG. 60.

FIG. 62 is a partial longitudinal cross-sectional view illustrating an example of a semiconductor structure on a cross-section of a pixel 3 of a light detection device according to a modified example of the 38th embodiment of the present technique.

FIG. 63 is a plan view schematically illustrating a configuration example of a pixel block included in a pixel array unit of a light detection device according to a 39th embodiment of the present technique.

FIG. 64 is a plan view schematically illustrating a configuration example of a pixel block included in a pixel array unit of a light detection device according to a first modified example of the 39th embodiment of the present technique.

FIG. 65 is a plan view schematically illustrating a configuration example of a pixel block included in a pixel array unit of a light detection device according to a second modified example of the 39th embodiment of the present technique.

FIG. 66 is a block diagram showing a configuration example of an imaging device as an electronic device to which the present technique is applied.

FIG. 67 is a block diagram illustrating an example of a schematic configuration of a vehicle control system to which the present technique is applied.

FIG. 68 is an explanatory diagram illustrating an example of installation positions of a vehicle external information detecting unit and an imaging unit illustrated in FIG. 67.

### DESCRIPTION OF EMBODIMENTS

An embodiment of the present disclosure will be described below with reference to the drawings. In descriptions of the drawings referred to in the following description, the same or similar portions will be denoted by the same or similar reference signs and redundant descriptions will be omitted. It should be noted that the drawings are schematic, and the relationships between thicknesses and two-dimensional sizes and the ratios of thicknesses of devices or members may not be true to reality. Therefore, specific thicknesses and dimensions should be determined in consideration of the following description. In addition, it is understood that some portions have different dimensional relationships and ratios among drawings.

Herein, a “first conductivity type” refers to one of p-type and n-type, and a “second conductivity type” refers to one of p-type and n-type that is different from the “first conductivity type”. The semiconductor regions with “+” and “−” suffixed to “n” and “p” indicate that the semiconductor regions have relatively higher and lower impurity densities than semiconductor regions without “+” and “−”. However, it does not necessarily mean that semiconductor regions with the same character “n” have exactly the same impurity density.

In addition, it is to be understood that definitions of directions such as up-down in the following descriptions are merely definitions provided for the sake of brevity and are not intended to limit the technical spirit of the present disclosure. For example, it is obvious that when an object is observed after being rotated by 90 degrees, up-down is converted into and interpreted as left-right, and when an object is observed after being rotated by 180 degrees, up-down is interpreted as being inverted.

The advantageous effects described in the present specification are merely exemplary and are not restrictive, and other advantageous effects may be produced.

Furthermore, in the following embodiments, in the three directions orthogonal to each other in a space, a first direction and a second direction orthogonal to each other in the same plane are defined as an X direction and a Y direction, respectively, and a third direction orthogonal to both the first direction and the second direction is defined as a Z direction. Furthermore, in the following embodiments, a thickness direction of a semiconductor layer 31 (described later) will be defined as being the Z direction.

### First Embodiment

### Overall Configuration of Light Detection Device

The overall configuration of a light detection device 1A will be described to start with.

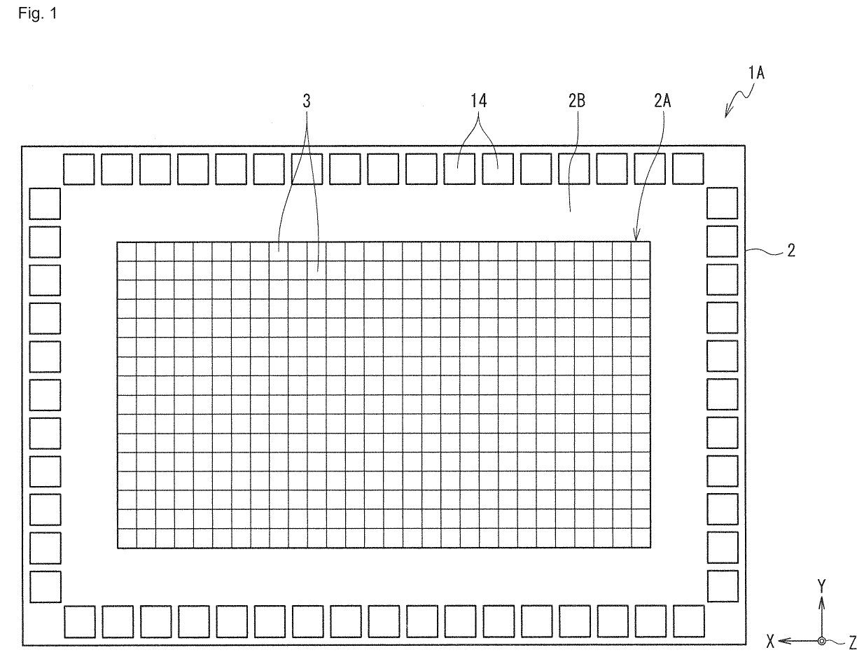

As illustrated in FIG. 1, a light detection device 1A according to a first embodiment of the present technique is configured using a semiconductor chip 2 having a rectangular two-dimensional plan shape in the plan view as a main body. In other words, the light detection device 1A is mounted in the semiconductor chip 2, and the semiconductor chip 2 can be regarded as the light detection device 1A. The light detection device 1A takes in image light (incident light) from a subject through an optical lens (not shown), converts the light quantity of incident light that forms an image on an imaging surface into an electrical signal on a pixel basis, and outputs the signal as a pixel signal.

As illustrated in FIG. 1, the semiconductor chip 2 on which the light detection device 1A is mounted includes a square pixel array unit 2A provided in a central area and a peripheral portion 2B provided outside the pixel array unit 2A so as to surround the pixel array unit 2A, in a two-dimensional plane including the X direction and the Y direction orthogonal to each other. The semiconductor chip 2 is formed by subdividing a semiconductor wafer, which includes the semiconductor layer 31 (described later), into each of chip formation regions in a manufacturing process. Accordingly, the configuration of the light detection device 1A described below is generally the same also in a wafer state prior to subdividing the semiconductor wafer. In other words, the present technique can be applied in both a semiconductor chip state and a semiconductor wafer state.

The pixel array unit 2A is a light receiving surface that receives light collected by, for example, the optical lens (optical system). In addition, in the pixel array unit 2A, a plurality of pixels 3 are arranged in a matrix on a two-dimensional plane including the X direction and the Y direction. Stated differently, the pixels 3 are repeatedly arranged in the X and Y directions which are orthogonal to each other within the two-dimensional plane.

As shown in FIG. 1, a plurality of bonding pads 14 are disposed in the peripheral portion 2B. For example, each of the plurality of bonding pads 14 is arrayed along each of four sides in the two-dimensional plane of the semiconductor chip 2. Each of the plurality of bonding pads 14 functions as an input/output terminal that electrically connects the semiconductor chip 2 to an external device.

### Logic Circuitry

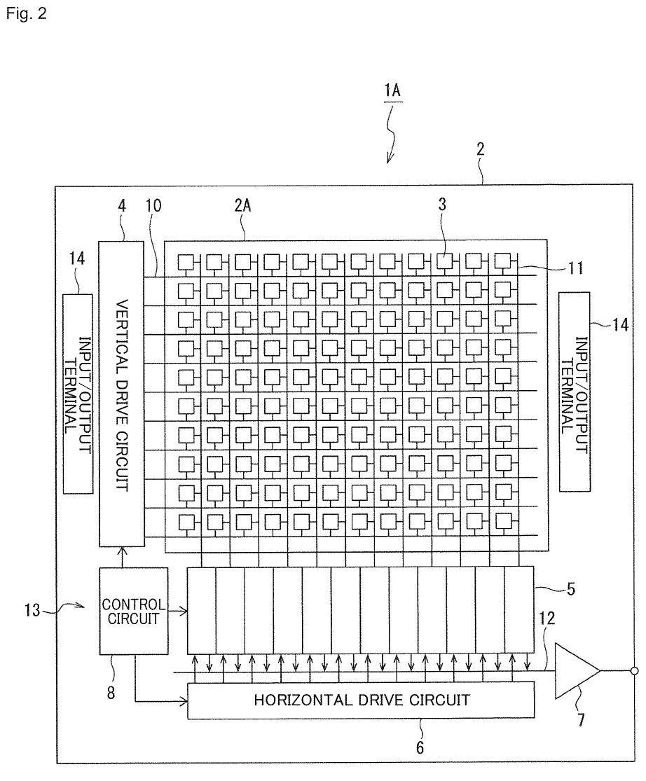

The semiconductor chip 2 includes a logic circuit 13 shown in FIG. 2. As shown in FIG. 2, the logic circuit 13 includes a vertical drive circuit 4, a column signal processing circuit 5, a horizontal drive circuit 6, an output circuit 7, a control circuit 8, and the like. For example, the logic circuit 13 is constituted by complementary MOS (CMOS) circuits having a metal oxide semiconductor field effect transistor (MOSFET) of an n-channel conductivity type and a MOSFET of a p-channel conductivity type as field-effect transistors.

For example, the vertical drive circuit 4 shown in FIG. 2 is constituted by a shift register. The vertical drive circuit 4 sequentially selects a desired pixel drive line 10, supplies a pulse for driving the pixels 3 to the selected pixel drive line 10, and drives respective pixels 3 in units of rows. In other words, the vertical drive circuit 4 sequentially performs selective scanning of the pixels 3 of the pixel array unit 2A in units of rows in a vertical direction and supplies a pixel signal from the pixels 3 based on a signal electric charge generated in accordance with a received light quantity by the photoelectric conversion unit of each pixel 3 to the column signal processing circuit 5 through a vertical signal line 11.

For example, the column signal processing circuit 5 is provided for each of the columns of pixels 3 to perform signal processing such as noise removal to signals output from a row of pixels 3 on a pixel column basis. For example, the column signal processing circuit 5 performs signal processing such as correlated double sampling (CDS) for removing pixel-specific fixed pattern noise and analog-digital (AD) conversion.

The horizontal drive circuit 6 shown in FIG. 2, for example, is constituted by a shift register. The horizontal drive circuit 6 sequentially selects each column signal processing circuit 5 by sequentially outputting a horizontal scanning pulse to the column signal processing circuit 5, and outputs a pixel signal on which signal processing has been performed from each column signal processing circuit 5 to the horizontal signal line 12.

The output circuit 7 shown in FIG. 2 performs signal processing on pixel signals sequentially supplied from the respective column signal processing circuits 5 through the horizontal signal line 12 and outputs resultant pixel signals. Examples of the signal processing include buffering, black level adjustment, column variation correction, various types of digital signal processing, and the like.

The control circuit 8 shown in FIG. 2 generates a clock signal or a control signal as a reference for operations of the vertical drive circuit 4, the column signal processing circuit 5, the horizontal drive circuit 6, and the like on the basis of a vertical synchronization signal, a horizontal synchronization signal, and a master clock signal. The control circuit 8 then outputs the generated clock signal or control signal to the vertical drive circuit 4, the column signal processing circuits 5, the horizontal drive circuit 6, and the like.

### Pixel Block

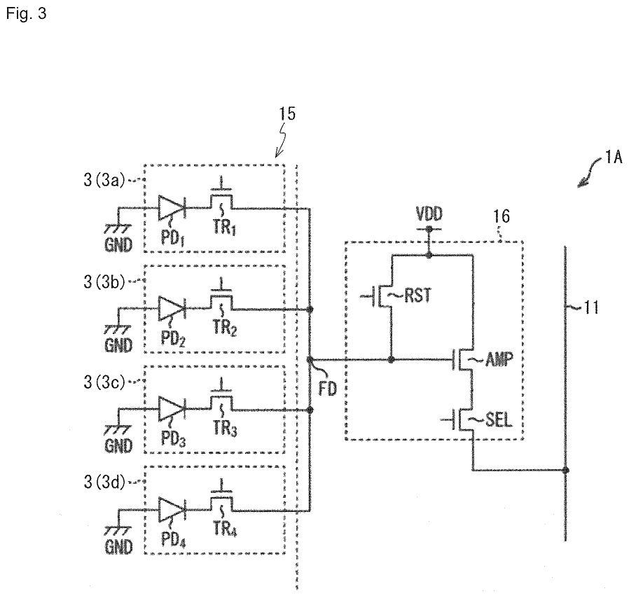

The semiconductor chip 2 includes a pixel block 15 and a reading circuit 16 shown in FIG. 3.

As shown in FIG. 3, one pixel unit PU is constituted by four pixels 3 and one reading circuit 16. In other words, one reading circuit 16 is shared by four pixels 3, and respective outputs of the four pixels 3 are input to the shared reading circuit 16.

Each pixel 3 has a photodiode PD that is a photoelectric conversion element, a transfer transistor TR that is electrically connected to the photodiode PD, and a floating diffusion FD (one example of a floating diffusion part).

Although not limited to this, the reading circuit 16, for example, has an amplification transistor AMP, a reset transistor RST, and a selection transistor SEL as pixel transistors. Note that the selection transistor SEL may be omitted as necessary.

Hereinafter, in a case in which four pixels 3 connected to one reading circuit 16 are to be distinguished from each other, as shown in FIG. 3, they are described as pixels 3a to 3d. Similarly, photodiodes PD and transfer transistors TR included in the pixels 3a to 3d are described as photodiodes PD1 to PD4 and transfer transistors TR1 to TR4. On the other hand, in a case in which the four pixels 3, the photodiodes PD, and the transfer transistors TR do not need to be distinguished from each other, the suffixes are omitted.

The photodiodes PD generates electric charge corresponding to a light reception quantity by performing photoelectric conversion. A cathode of the photodiode PD is electrically connected to a source of the transfer transistor TR, and an anode of the photodiode PD is electrically connected to a reference potential line (for example, the ground). A drain of the transfer transistor TR is electrically connected to the floating diffusion FD, and a gate electrode of the transfer transistor TR is electrically connected to the pixel drive line 10.

An input terminal of the reading circuit 16 is a floating diffusion FD, and a source of the reset transistor RST is electrically connected to the floating diffusion FD. A predetermined power supply voltage VDD is supplied to a drain of the reset transistor RST together with a drain of the amplification transistor AMP. A gate electrode of the reset transistor RST is electrically connected to the pixel drive line 10 (FIG. 2). A source of the amplification transistor AMP is electrically connected to a drain of the selection transistor SEL, and a gate electrode of the amplification transistor AMP is electrically connected to the source of the reset transistor RST. A source of the selection transistor SEL serves as an output terminal of the reading circuit 16 and is electrically connected to the vertical signal line 11. A gate electrode of the selection transistor SEL is electrically connected to the pixel drive line 10 (FIG. 2).

When the transfer transistor TR is caused to be in the on state in accordance with a control signal supplied to the gate electrode through the pixel drive line 10, the electric charge of the photodiode PD is transferred to the floating diffusion FD. The floating diffusion FD temporarily holds the electric charge output from the photodiode PD through the transfer transistor TR. The reset transistor RST resets the potential of the floating diffusion FD to a predetermined potential. When the reset transistor RST is caused to be in the on state, the potential of the floating diffusion FD is reset to the power supply voltage VDD.

The amplification transistor AMP generates a signal having a voltage corresponding to the electric charge held in the floating diffusion FD as a pixel signal. The amplification transistor AMP forms a source-follower circuit with a load MOS (not shown) as a constant current source and outputs a pixel signal having a voltage corresponding to the level of electric charge generated by the photodiode PD. When the selection transistor SEL is caused to be in the on state, the amplification transistor AMP amplifies the potential of the floating diffusion FD and outputs a pixel signal having a voltage corresponding to potential to the column signal processing circuit 5 via the vertical signal line 11. The selection transistor SEL controls an output timing of a pixel signal from the reading circuit 16. In other words, when the selection transistor SEL is caused to be in the on state, a pixel signal having a voltage corresponding to the level of the electric charge held in the floating diffusion FD can be output.

The transfer transistor TR, the reset transistor RST, the amplification transistor AMP, and the selection transistor SEL, for example, are configured using N-type metal oxide semiconductor field effect transistors (MOSFETs).

### Configuration of Pixel Array Unit

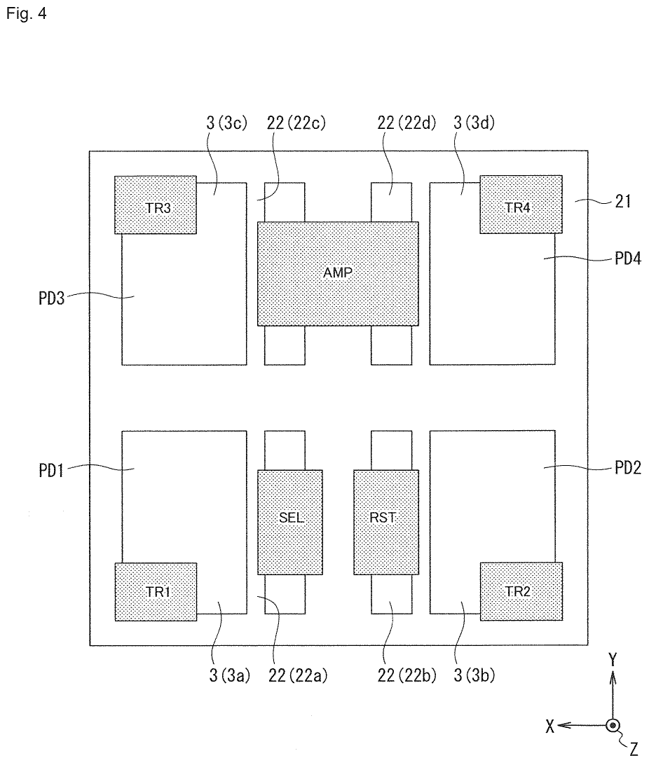

FIG. 4 is a plan view schematically illustrating a configuration example of a pixel block 15 included in the pixel array unit shown in FIG. 1. In addition, FIG. 4 is vertically inverted with respect to FIG. 1. In other words, although FIG. 1 shows a light incident surface side of the semiconductor chip 2, FIG. 4 is a plan view acquired when viewed from a side opposite to the light incident surface of the semiconductor chip 2 shown in FIG. 1.

In the semiconductor chip 2, an inter-pixel separation part 21 that separates each pixel 3 may be formed. The inter-pixel separation part 21, for example, has a trench structure formed using an etching process and extends in a thickness direction of the semiconductor chip 2, that is, a direction denoted by arrow Z in FIG. 4. The inter-pixel separation part 21 prevents light incident in a pixel 3 from entering an adjacent pixel 3. Furthermore, in each pixel 3, an element separation part 22 that separates elements of the pixel 3 may be formed. The element separation part 22 has a trench structure, for example, formed through an etching process.

In the pixel 3a, for example, a selection transistor SEL as a pixel transistor is provided between the element separation part 22a and the inter-pixel separation part 21. In the pixel 3b, for example, a reset transistor RST as a pixel transistor is provided between the element separation part 22b and the inter-pixel separation part 21. An amplification transistor AMP is provided across the inter-pixel separation part 21 between the element separation part 22c of the pixel 3c and the element separation part 22d of the pixel 3d.

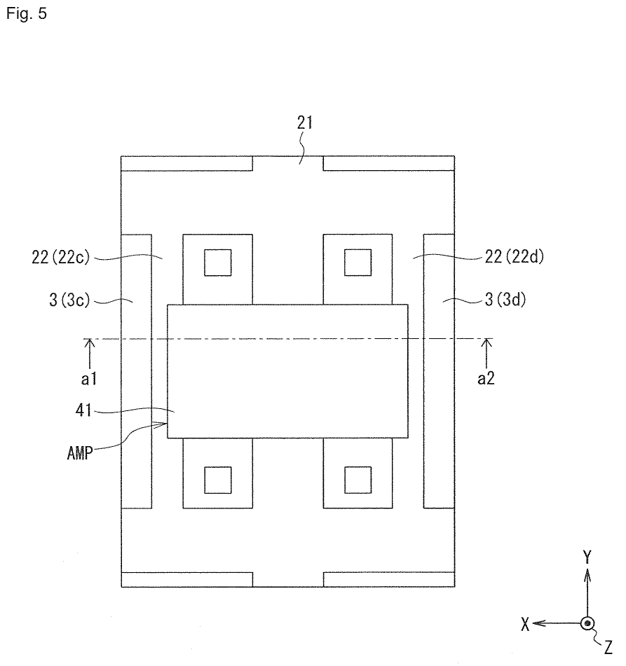

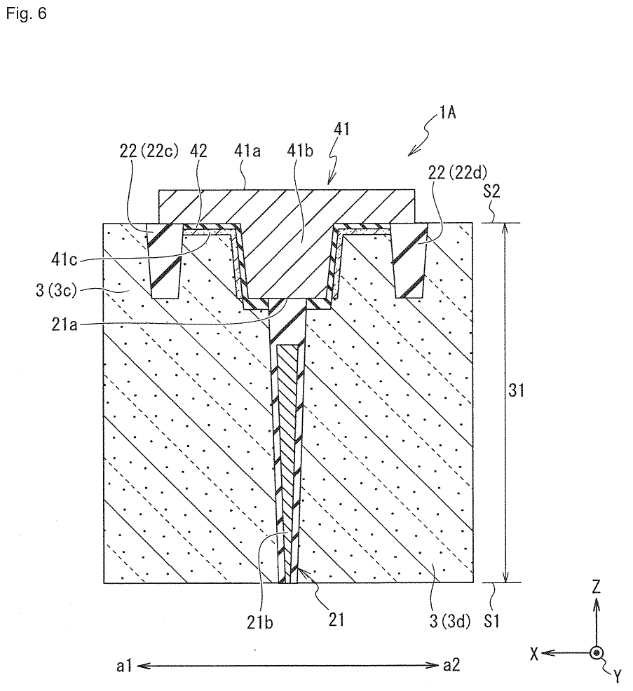

FIG. 5, for example, is a plan view illustrating an example of an arrangement pattern of an amplification transistor AMP in a pixel 3. The amplification transistor AMP is disposed between the pixel 3c and the pixel 3d. FIG. 6 is a diagram illustrating an example of a schematic cross-sectional structure on an a1-a2 cross-section of the amplification transistor AMP shown in FIG. 5. The light detection device 1A may include a semiconductor layer 31.

The semiconductor layer 31 has a first surface part S1 and a second surface part S2 on sides opposite to each other in a thickness direction (a direction denoted by arrow Z in FIG. 6) and has a photodiode PD constituting each pixel 3. The photodiode PD of the semiconductor layer 31 generates an amount of electric charge corresponding to the intensity of light incident in the first surface part S1 via an on-chip lens (not shown) and a color filter (not shown). The semiconductor layer 31 is produced on a silicon substrate through a semiconductor manufacturing process.

On the second surface part S2 of the semiconductor layer 31, a pixel transistor constituting a reading circuit 16 that outputs a pixel signal based on electric charge is formed. The inter-pixel separation part 21 has an upper surface part 21a positioned on the second surface part S2 side of the semiconductor layer 31. In addition, an n-type region 21b made of polysilicon or the like is provided inside the inter-pixel separation part 21. The inter-pixel separation part 21 may not have the n-type region 21b inside. Furthermore, a p-type region made of polysilicon or the like may be provided inside the inter-pixel separation part 21. In any structure, the first embodiment of the present disclosure can be implemented.

As an example of the pixel transistor, the amplification transistor AMP has a gate electrode 41 that crosses the pixels 3c and 3d, which are adjacent to each other, across the upper surface part 21a of the inter-pixel separation part 21 in a plan view (an X-Y plane in FIG. 6). The gate electrode 41 has a head part 41a provided outside the second surface part S2 of the semiconductor layer 31 with a gate insulating film 42 interposed therebetween, and an embedded part 41b that protrudes from the head part 41a to the semiconductor layer 31 side and is partially embedded in the upper surface part 21a of the inter-pixel separation part 21. In addition, a channel part 41c is provided on a bottom part of the head part 41a and a side wall part of the embedded part 41b via a gate insulating film 42.

### Method of Manufacturing Pixel Transistor

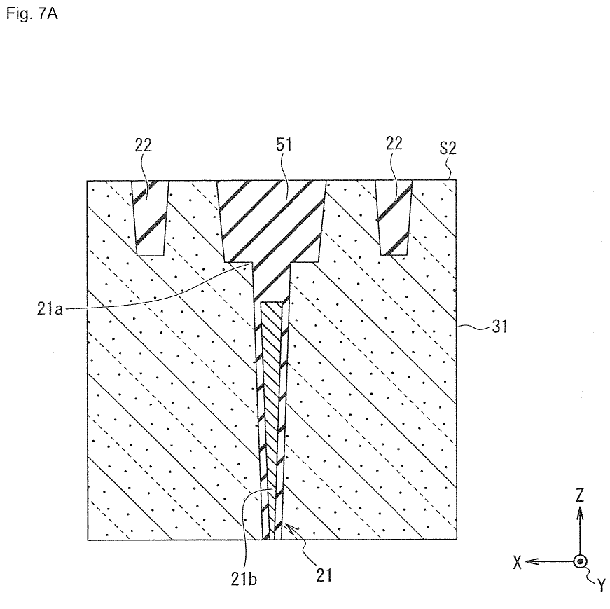

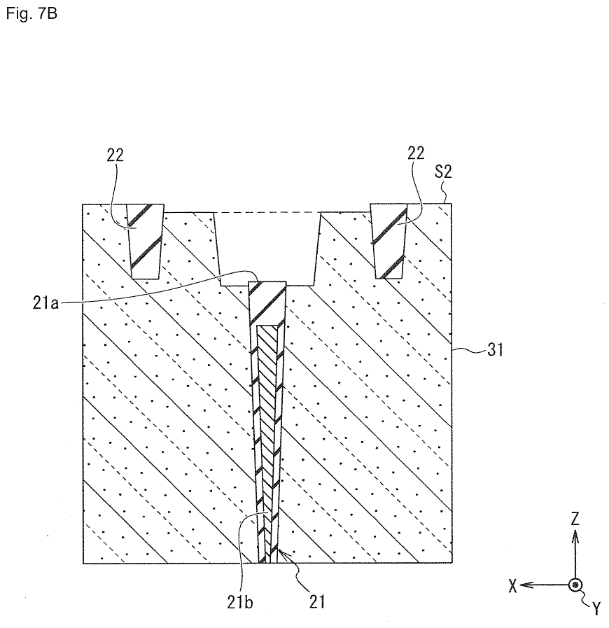

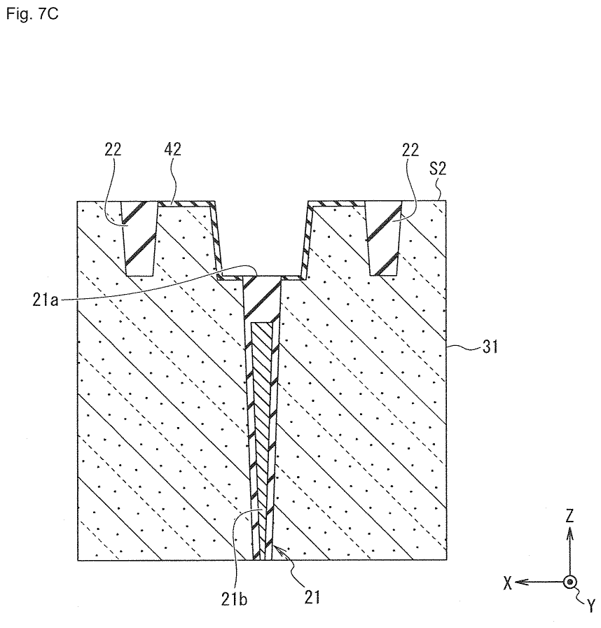

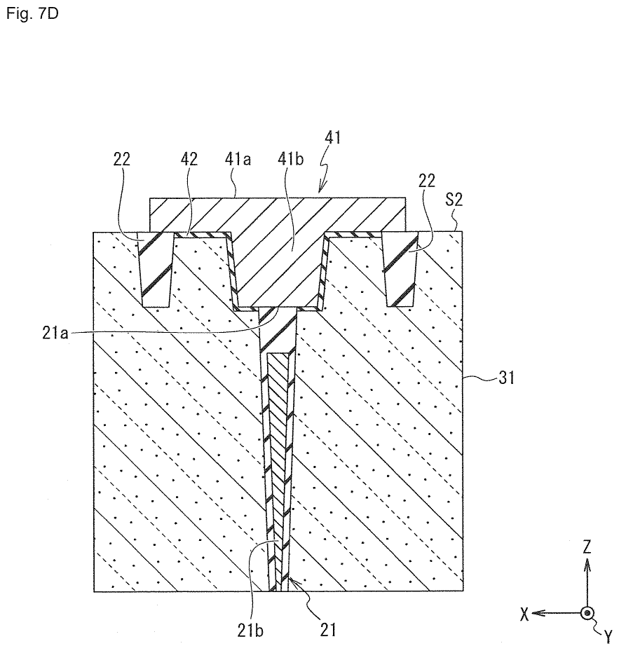

FIGS. 7A to 7D are cross-sectional views illustrating a processing sequence of a method of manufacturing a pixel transistor according to the first embodiment of the present technique. The amplification transistor AMP that is an example of the pixel transistor is manufactured using various devices such as a film forming apparatus (including a chemical vapor deposition (CVD) apparatus and a sputtering apparatus), an ion implantation apparatus, a heat treatment apparatus, an etching apparatus, a chemical mechanical polishing (CMP) apparatus, a bonding apparatus, and the like. Hereinafter, these apparatuses will be collectively referred to as a manufacturing apparatus.

The manufacturing apparatus forms an element separation part 51 on an upper surface part 21a of an inter-pixel separation part 21 (FIG. 7A). Subsequently, the manufacturing apparatus etches the element separation part 51 formed on the upper surface part 21a of the inter-pixel separation part 21 (FIG. 7B) and forms a gate insulating film 42 on the second surface part S2 of the semiconductor layer 31 (FIG. 7C). Thereafter, the manufacturing apparatus forms a head part 41a and an embedded part 41b of the gate electrode 41 made of polysilicon on the gate insulating film 42 (FIG. 7D).

### Function and Effect According to First Embodiment

As described above, according to the first embodiment, the effective gate width W can be enlarged by extending the gate electrode 41 of the amplification transistor AMP across the upper surface part 21a of the inter-pixel separation part 21 and embedding a part of the gate electrode 41 in the upper surface part 21a of the inter-pixel separation part 21, and, in accordance with this, the improvement of the mutual conductance gm of the amplification transistor AMP and the improvement of the noise characteristics can be achieved.

### Second Embodiment

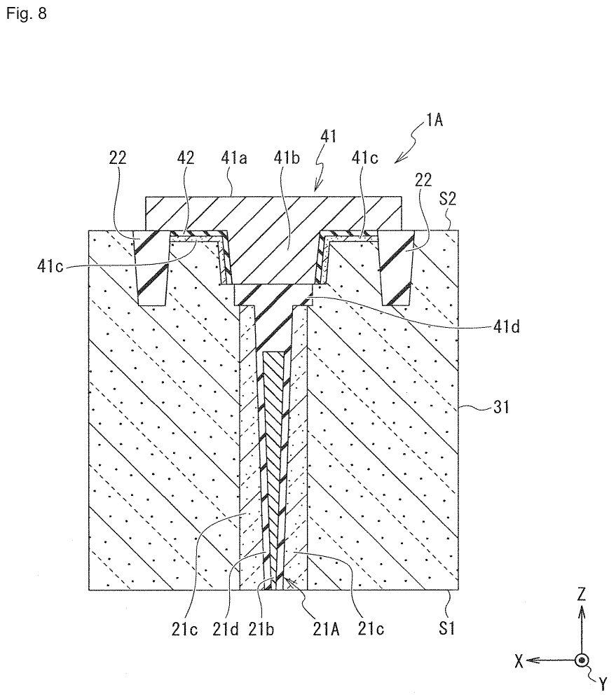

FIG. 8 is a cross-sectional view illustrating an embedding structure of a pixel transistor for an inter-pixel separation part according to a second embodiment of the present technique. In FIG. 8, the same reference signs are applied to the same parts as those shown in FIG. 6, and a detailed description thereof is omitted. Here, an amplification transistor AMP is used as an example of the pixel transistor.

An inter-pixel separation part 21A has an n-type region 21b, which becomes a first conductivity type, and a p-type region 21c, which becomes a second conductivity type, that are provided in the extending direction and an insulating film 21d interposed between the n-type region 21b and the p-type region 21c.

### Comparative Example of Second Embodiment

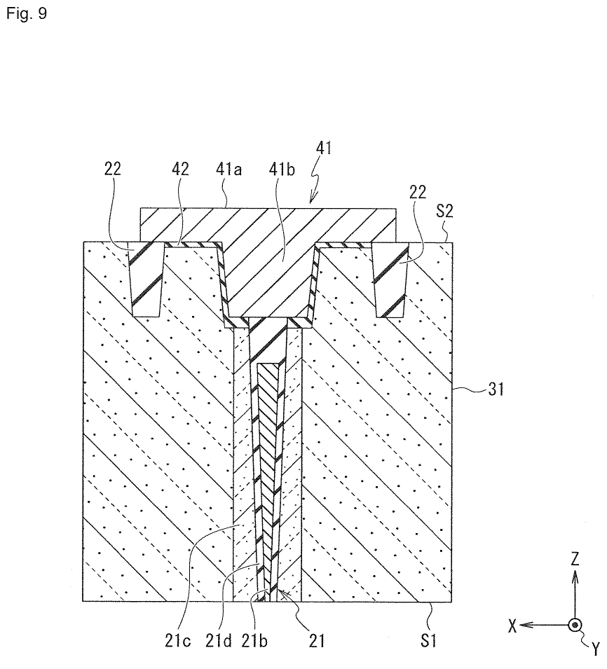

FIG. 9 is a cross-sectional view illustrating an embedding structure of a pixel transistor for an inter-pixel separation part 21 as a comparative example of the second embodiment. In the bottom part of the embedded part 41b of the gate electrode 41, a p-type region 21c is present in the inter-pixel separation part 21, and no channel is formed. In addition, there is a processing damage, and the TDDB is poor. In addition, capacitance is formed between the bottom part of the embedded part 41b and the n-type region 21b.

### Solving Means According to Second Embodiment

Thus, in the gate electrode 41A of the amplification transistor AMP according to the second embodiment, an insulating film 41d, which is thicker than the gate insulating film 42, is provided between the bottom part of the embedded part 41b and the n-type region 21b and the p-type region 21c of the inter-pixel separation part 21A.

### Function and Effect According to Second Embodiment

As described above, according to the second embodiment, since the insulating film 41d thicker than the gate insulating film 42 remains between the bottom part of the embedded part 41b of the gate electrode 41A and the n-type region 21b and the p-type region 21c of the inter-pixel separation part 21A, reduction of the gate capacitance and improvement of the reliability can be achieved.

### Third Embodiment

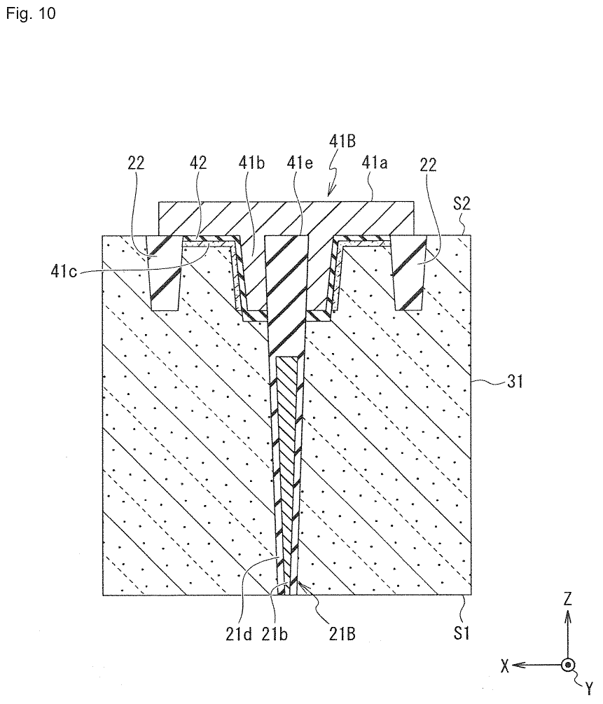

FIG. 10 is a cross-sectional view illustrating an embedding structure of a pixel transistor for an inter-pixel separation part according to a third embodiment of the present technique. In FIG. 10, the same reference signs are assigned to the same parts as those shown in FIG. 6, and detailed description is omitted. Here, an amplification transistor AMP is used as an example of the pixel transistor.

A gate electrode 41B of the amplification transistor AMP according to the third embodiment has an opening part 41e that is formed from a bottom part of an embedded part 41b toward a head part 41a. The opening part 41e is in contact with an insulating film 21d of an inter-pixel separation part 21B.

### Function and Effect According to Third Embodiment

As described above, according to the third embodiment, the capacitance with the n-type region 21b inside the inter-pixel separation part 21B can be reduced.

### Fourth Embodiment

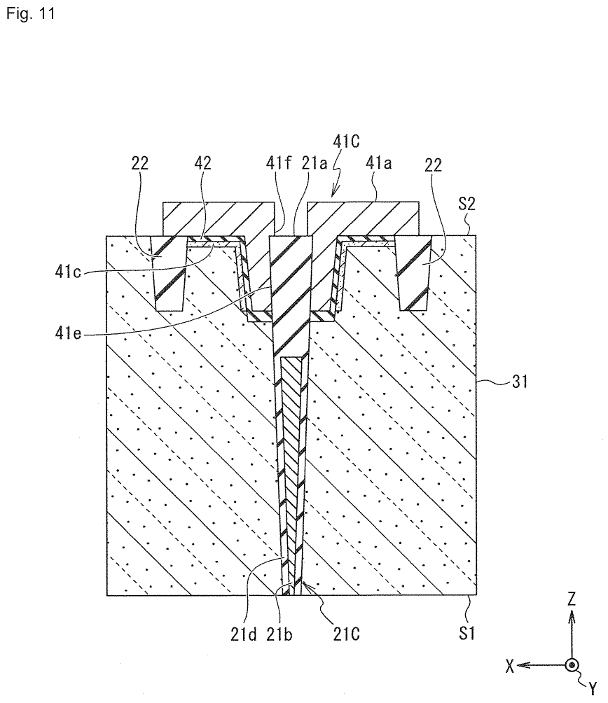

FIG. 11 is a cross-sectional view illustrating an embedding structure of a pixel transistor for an inter-pixel separation part according to a fourth embodiment of the present technique. In FIG. 11, the same reference signs are assigned to the same parts as those shown in FIG. 10, and detailed description is omitted. Here, an amplification transistor AMP is used as an example of the pixel transistor.

In a gate electrode 41C of the amplification transistor AMP according to the fourth embodiment, an exposed part 41f is formed in a head part 41a. The exposed part 41f exposes an upper surface part 21a of an inter-pixel separation part 21C that is in contact with the opening part 41e.

### Function and Effect According to Fourth Embodiment

As described above, according to the fourth embodiment, the effective gate width W of the gate electrode 41C can be enlarged in the depth direction of the semiconductor layer 31 by utilizing the side surfaces of the inter-pixel separation part 21C by dividing the gate electrode 41C on the inter-pixel separation part 21C, and further divided amplification transistors AMP can be used as separate transistors.

### Fifth Embodiment

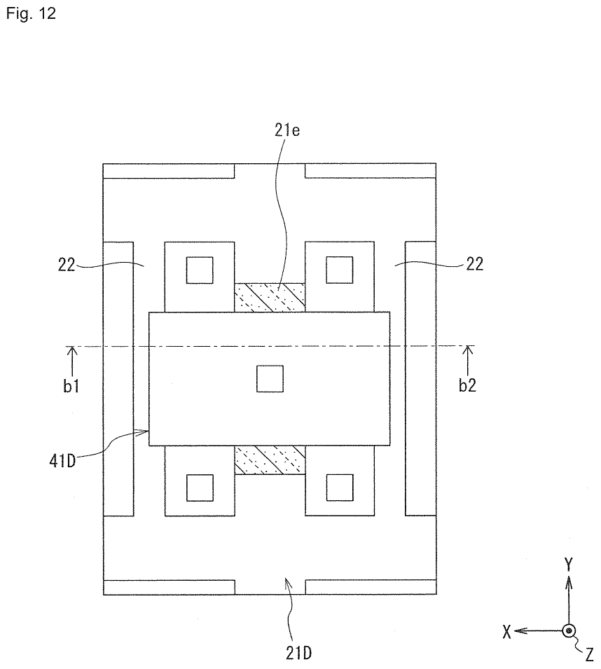

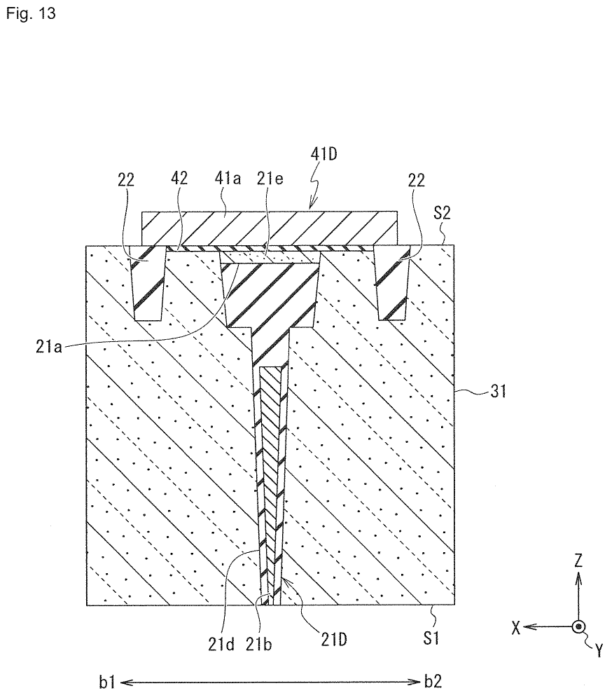

FIG. 12 is a plan view illustrating an example of an arrangement pattern of an amplification transistor AMP in a pixel 3 according to a fifth embodiment of the present technique. FIG. 13 is a diagram illustrating an example of a schematic cross-section structure of the amplification transistor AMP illustrated in FIG. 12 on a b1-b2 cross-section.

In a fifth embodiment of the present technique, a channel part 21e is formed by embedding a material in an upper surface part 21a of an inter-pixel separation part 21D. As the material, epitaxial silicon, poly-silicon, or other oxide semiconductor is used.

### Function and Effect According to Fifth Embodiment

As described above, according to the fifth embodiment, similar to the previous first embodiment, the effective gate width W can be enlarged, and thus improvement of the mutual conductance gm of the amplification transistor AMP and improvement of the noise characteristics can be achieved.

### Sixth Embodiment

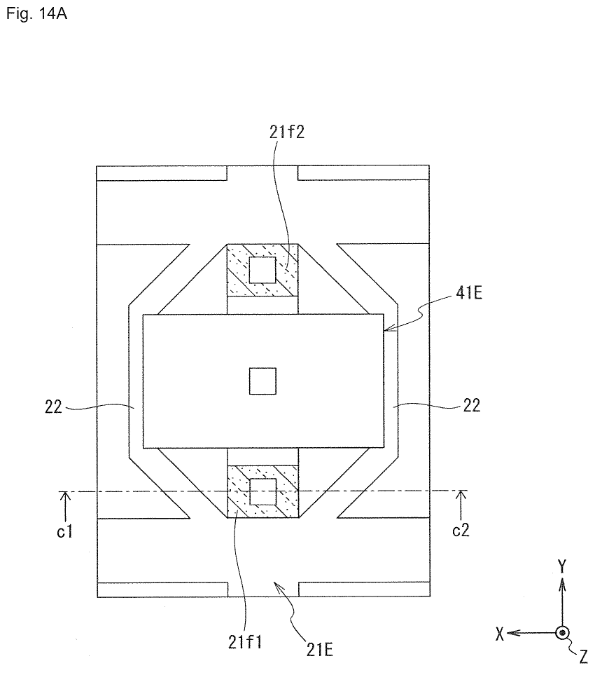

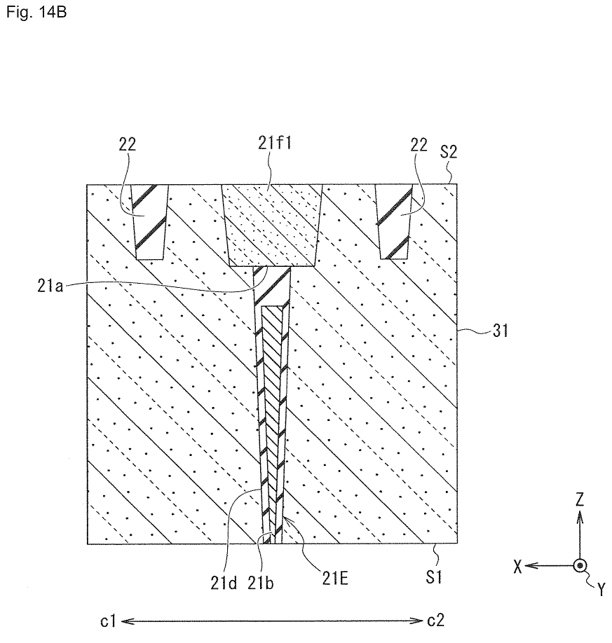

FIG. 14A is a plan view illustrating an example of an arrangement pattern of an amplification transistor AMP in a pixel 3 according to a sixth embodiment of the present technique. FIG. 14B is a diagram illustrating an example of a schematic cross-section structure of the amplification transistor AMP illustrated in FIG. 14A on a c1-c2 cross-section.

In the sixth embodiment of the present technique, a source region 21f1 and a drain region 21f2 are formed on an upper surface part 21a of an inter-pixel separation part 21E using epitaxial silicon.

### Function and Effect According to Sixth Embodiment

As described above, according to the sixth embodiment, the number of contacts respectively connected to the gate electrode 41E, the source region 21f1, and the drain region 21f2 can be reduced, and reduction of the capacitance can be achieved by reducing the element separation part 22 of the source region 21f1 and the drain region 21f2.

### Seventh Embodiment

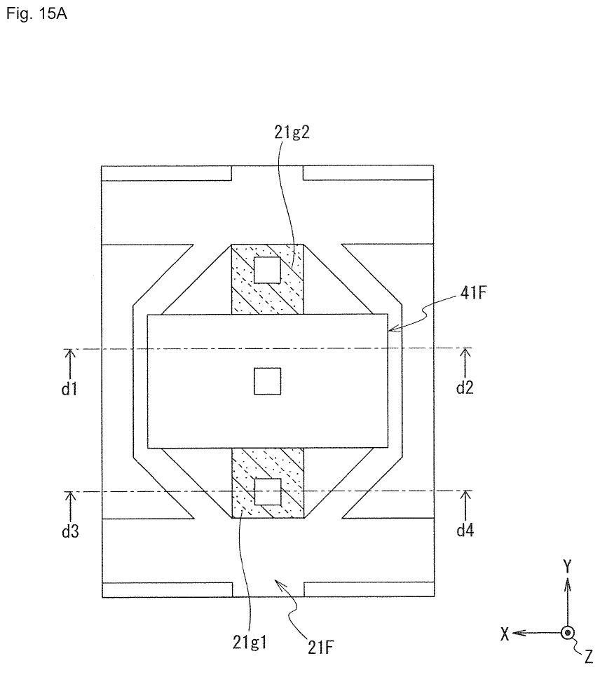

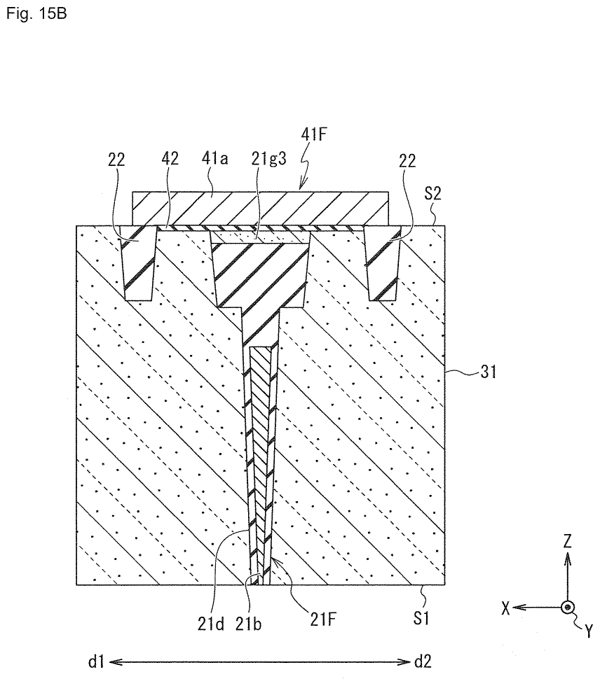

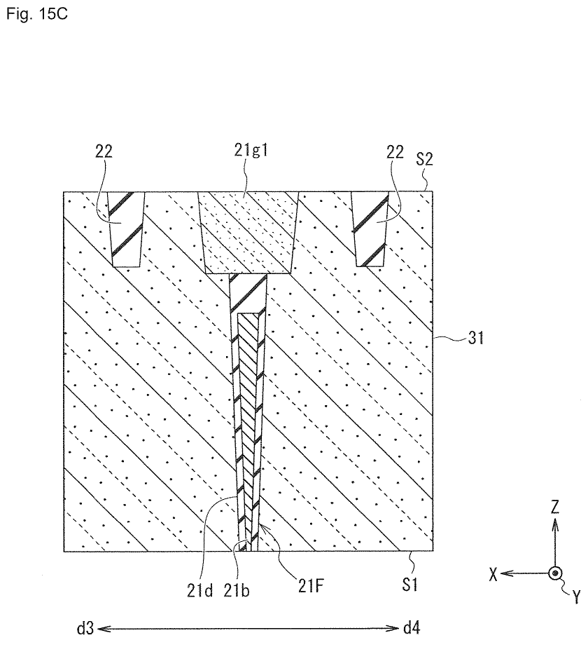

FIG. 15A is a plan view illustrating an example of an arrangement pattern of an amplification transistor AMP in a pixel 3 according to a seventh embodiment of the present technique. FIG. 15B is a diagram illustrating an example of a schematic cross-section structure of the amplification transistor AMP illustrated in FIG. 15A on a d1-d2 cross-section.

FIG. 15C is a diagram illustrating an example of a schematic cross-section structure of the amplification transistor AMP illustrated in FIG. 15A on a d3-d4 cross-section.

In a seventh embodiment of the present technique, a source region 21g1, a drain region 21g2, and a channel part 21g3 electrically connecting the source region 21g1 and the drain region 21g2 are formed on an upper surface part 21a of an inter-pixel separation part 21D. A gate electrode 41F has a head part 41a formed on a second surface part S2 of a semiconductor layer 31 across the upper surface part 21a of the inter-pixel separation part 21D. A gate insulating film 42 is formed between the bottom part of the head part 41a and the second surface part S2 of the semiconductor layer 31 and between the bottom part of the head part 41a and the channel part 21g3.

### Function and Effect According to Seventh Embodiment

As described above, according to the seventh embodiment, the number of contacts respectively connected to the gate electrode 41F, the source region 21g1, and the drain region 21g2 can be reduced, and the effective gate width W can be enlarged, and thus, in accordance with this, improvement of the mutual conductance gm of the amplification transistor AMP and improvement of the noise characteristics can be achieved.

### Eighth Embodiment

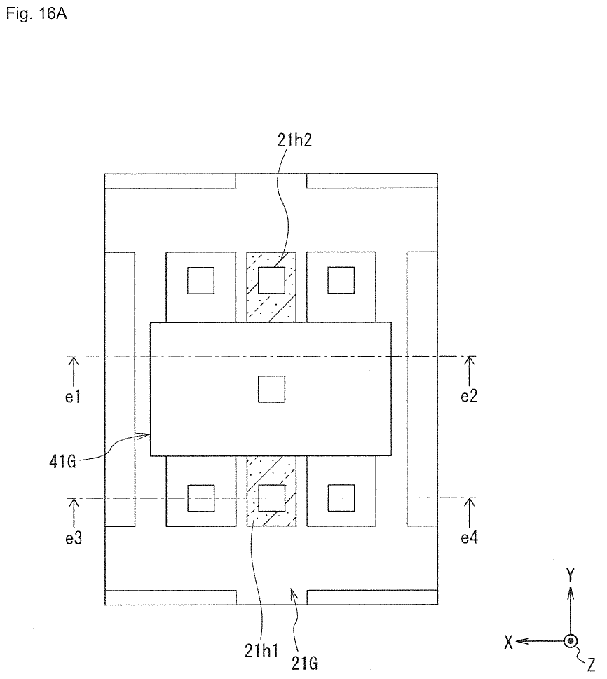

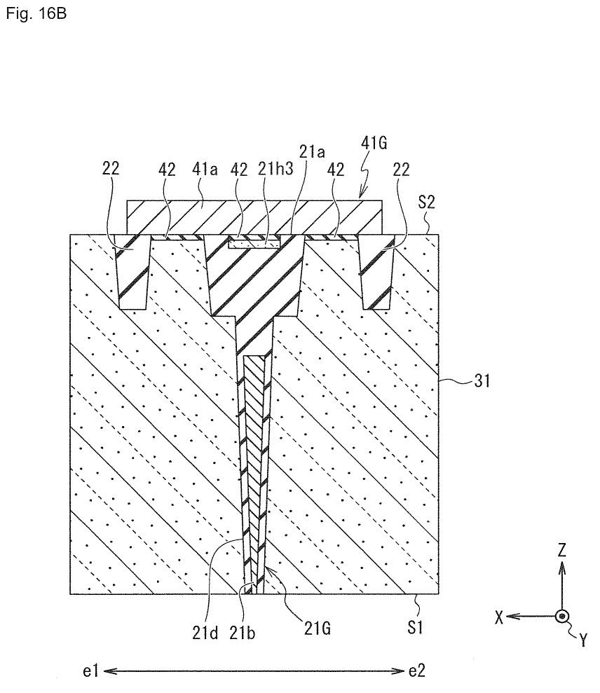

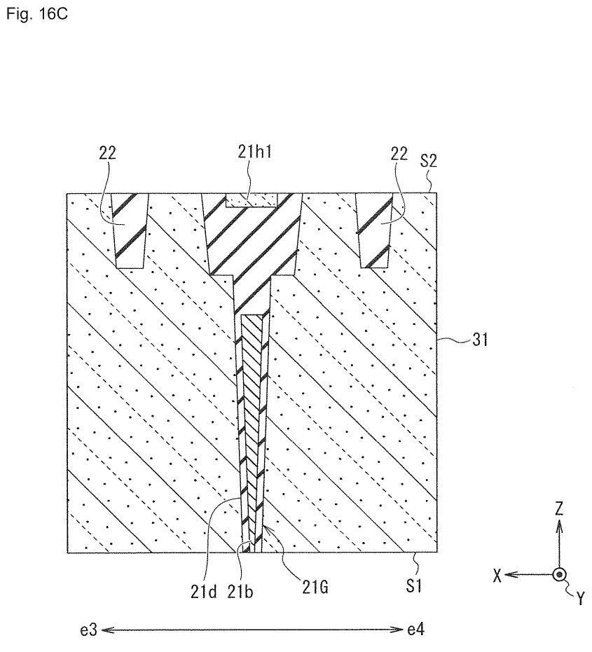

FIG. 16A is a plan view illustrating an example of an arrangement pattern of an amplification transistor AMP in a pixel 3 according to an eighth embodiment of the present technique. FIG. 16B is a diagram illustrating an example of a schematic cross-section structure of the amplification transistor AMP illustrated in FIG. 16A on an e1-e2 cross-section. FIG. 16C is a diagram illustrating an example of a schematic cross-section structure of the amplification transistor AMP illustrated in FIG. 16A on an e3-e4 cross-section.

In the eighth embodiment of the present technique, a source region 21h1, a drain region 21h2, and a channel part 21h3 electrically connecting the source region 21h1 and the drain region 21h2 are formed on an upper surface part 21a of an inter-pixel separation part 21G with a part of STI remaining. A gate electrode 41G has a head part 41a formed on a second surface part S2 of a semiconductor layer 31 across an upper surface part 21a of an inter-pixel separation part 21G. A gate insulating film 42 is formed between the bottom part of the head part 41a and the second surface part S2 of the semiconductor layer 31 and between the bottom part of the head part 41a and the channel part 21h3.

### Function and Effect According to Eighth Embodiment

As described above, according to the eighth embodiment, functions and effects that are similar to those according to the previous seventh embodiment can be acquired.

### Ninth Embodiment

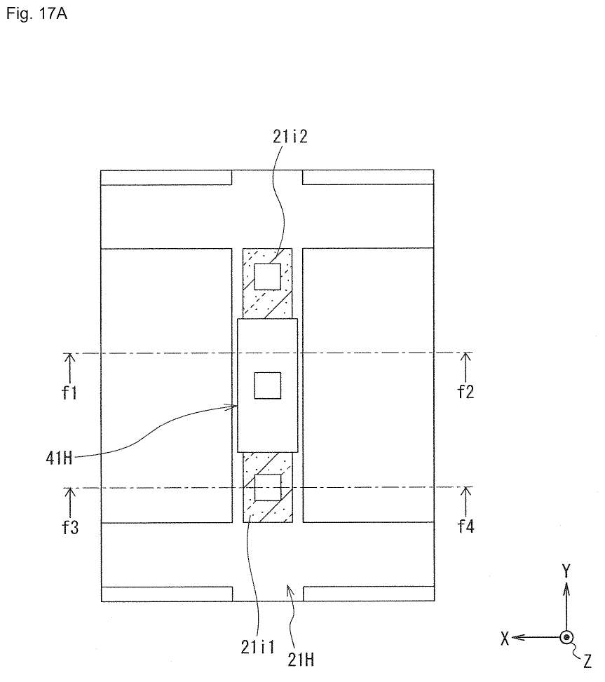

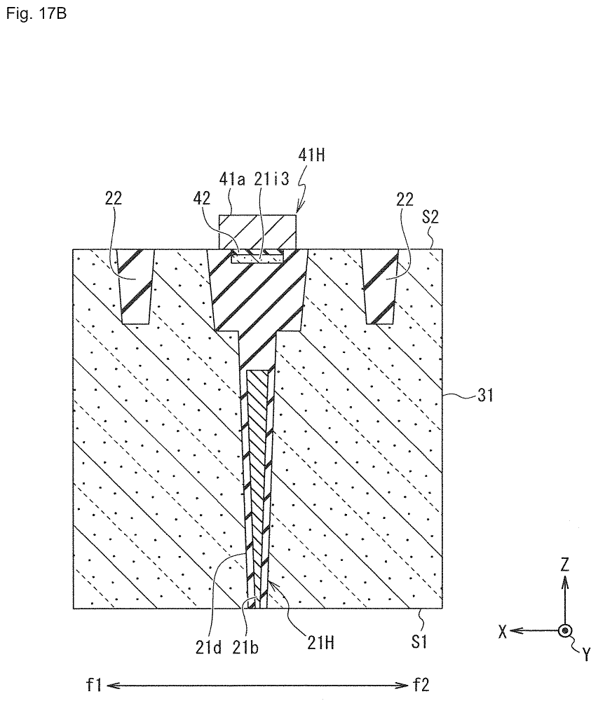

FIG. 17A is a plan view illustrating an example of an arrangement pattern of an amplification transistor AMP in a pixel 3 according to a ninth embodiment of the present technique. FIG. 17B is a diagram illustrating an example of a schematic cross-section structure of the amplification transistor AMP illustrated in FIG. 17A on an f1-f2 cross-section. FIG. 17C is a diagram illustrating an example of a schematic cross-section structure of the amplification transistor AMP illustrated in FIG. 17A on an f3-f4 cross-section.

In a ninth embodiment of the present technique, a source region 21i1, a drain region 21i2, and a channel part 21i3 electrically connecting the source region 21i1 and the drain region 21i2 are formed on an upper surface part 21a of an inter-pixel separation part 21H with a part of STI remaining. The width of a gate electrode 41H (the width corresponding to a direction denoted by arrow X in FIG. 17A) is larger than the width of the channel part 21i3 and smaller than the width of the inter-pixel separation part 21H.

### Function and Effect According To Ninth Embodiment

As described above, according to the ninth embodiment, one pixel transistor can be formed on the upper surface part 21a of the inter-pixel separation part 21H, and, in accordance with this, a space for arranging the pixel transistor can be further secured even when the pixel 3 is finely formed.

### 10th Embodiment

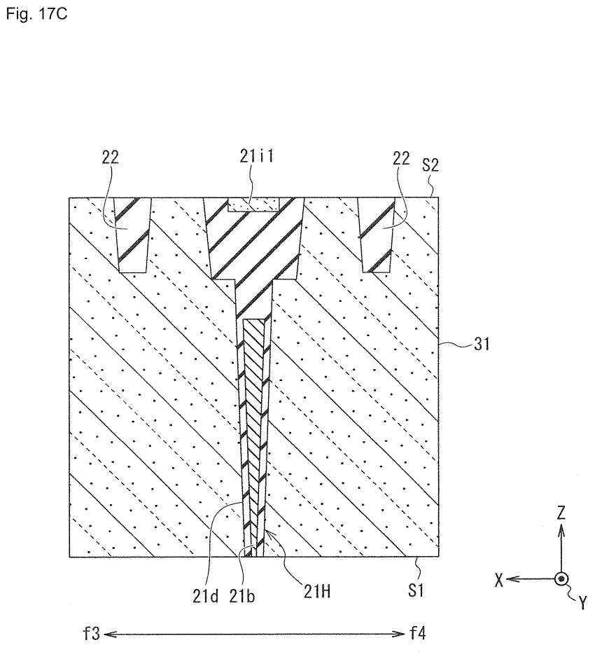

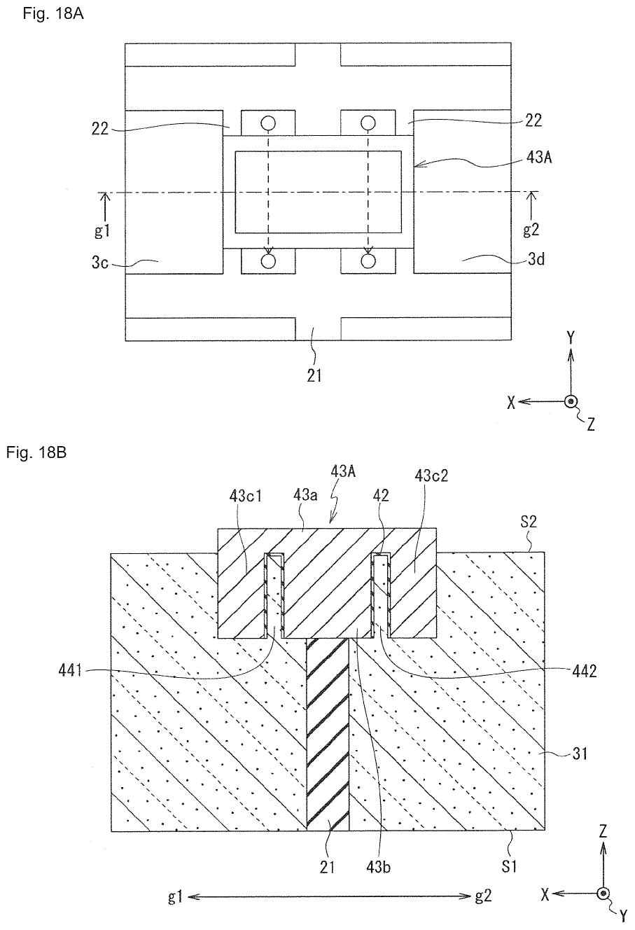

FIG. 18A is a plan view illustrating an example of an arrangement pattern of an amplification transistor AMP in a pixel 3 according to a 10th embodiment of the present technique. FIG. 18B is a diagram illustrating an example of a schematic cross-sectional structure of the amplification transistor AMP illustrated in FIG. 18A on a g1-g2 cross-section.

The amplification transistor AMP as an example of the pixel transistor has a gate electrode 43A crossing pixels 3c and 3d, which are adjacent to each other, across an upper surface part 21a of an inter-pixel separation part 21 in a plan view (an X-Y plane in FIG. 18A). The gate electrode 43A has a head part 43a provided on the outside of a second surface part S2 of a semiconductor layer 31 via a gate insulating film 42, a first embedded part 43b protruding from the head part 43a to the semiconductor layer 31 side and partially embedded in the upper surface part 21a of the inter-pixel separation part 21, and second embedded parts 43c1 and 43c2 partially embedded in the upper surface part of an element separation part 22.

A first channel part 441 is formed from the bottom surface part of the element separation part 22 of the pixel 3c toward the head part 43a of the gate electrode 43A. A second channel part 442 is formed from the bottom surface part of the element separation part 22 of the pixel 3d toward the head part 43a of the gate electrode 43A.

The bottom part of the first embedded part 43b is in contact with the upper surface part 21a of the inter-pixel separation part 21. In addition, the bottom parts of the second embedded parts 43c1 and 43c2 are in contact with the bottom surface part of the element separation part 22.

### Function and Effect According to 10th Embodiment

As described above, according to the 10th embodiment, the effective gate width W can be enlarged by embedding a part of the gate electrode 43A of the pixel transistor in the upper surface part 21a of the inter-pixel separation part 21, and the channel width of the first channel part 441 and the channel width of the second channel part 442 can be enlarged by further embedding a part of the gate electrode 43A in the element separation part 22.

### 11th Embodiment

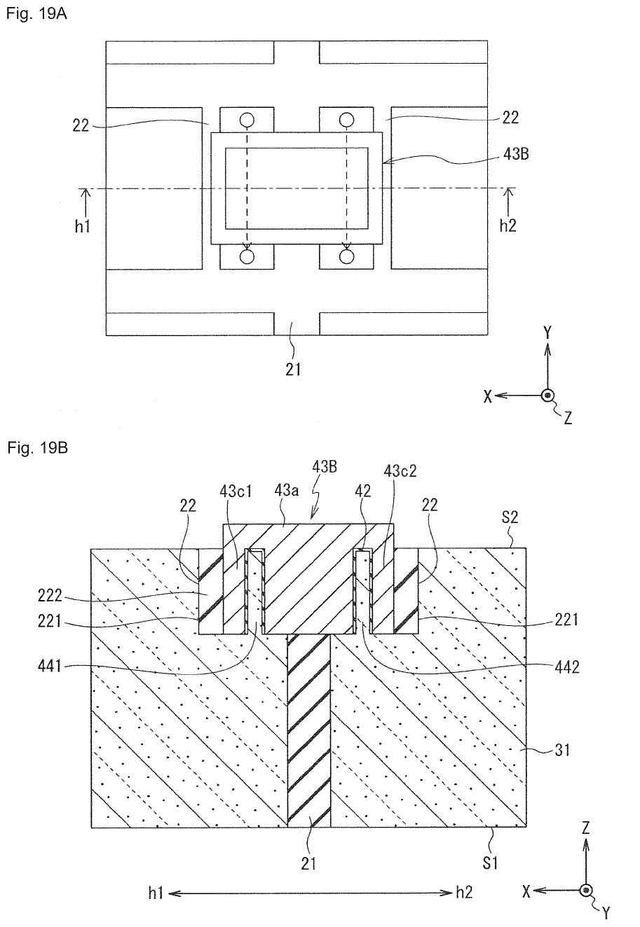

FIG. 19A is a plan view illustrating an example of an arrangement pattern of an amplification transistor AMP in a pixel 3 according to an 11th embodiment of the present technique. FIG. 19B is a diagram illustrating an example of a schematic cross-sectional structure of the amplification transistor AMP illustrated in FIG. 19A on an h1-h2 cross-section.

In the 11th embodiment of the present technique, an insulating film 222 is provided between a side surface part 221 of an element separation part 22 and second embedded parts 43c1 and 43c2 of a gate electrode 43B.

### Function and Effect According to 11th Embodiment

As described above, according to the 11th embodiment, when a gate voltage is applied, the electric field outside the pixel transistor is shielded by the side surface part 221 of the element separation part 22, whereby there is an effect of reducing the capacitance.

### 12th Embodiment

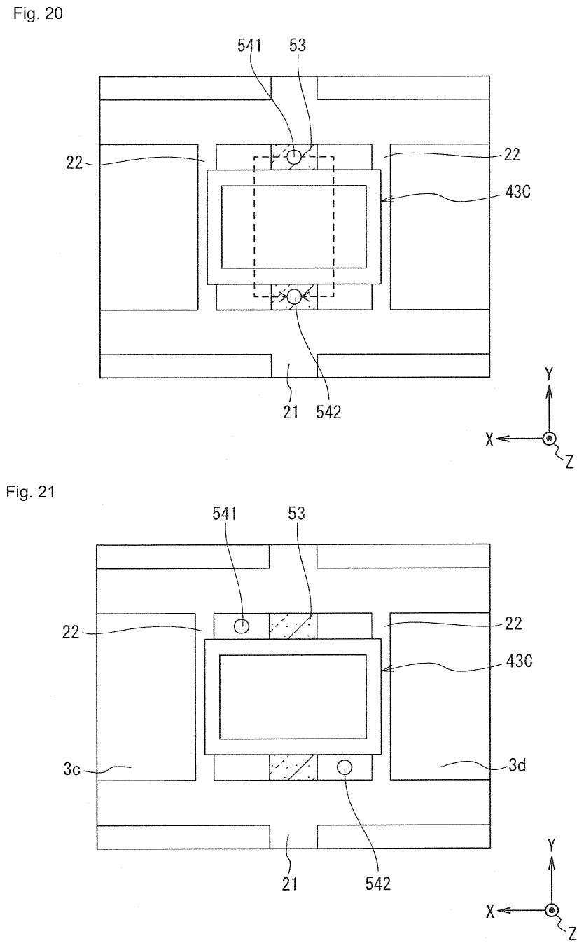

FIG. 20 is a plan view illustrating an example of an arrangement pattern of an amplification transistor AMP in a pixel 3 according to a 12th embodiment of the present technique.

In the 12th embodiment of the present technique, a conductive layer 53 is provided on an upper surface part 21a of an inter-pixel separation part 21. In the conductive layer 53, a first contact part 541 connected to the source region of a first channel part 441 and the source region of the second channel part 442 and a second contact part 542 connected to the drain region of the first channel part 441 and the drain region of the second channel part 442 are provided. The first channel part 441 and the second channel part 442 are formed at the bottom part of the gate electrode 43C.

### Function and Effect According to 12th Embodiment

As described above, according to the 12th embodiment, the arrangement space of the first contact part 541 and the second contact part 542 can be secured by utilizing the conductive layer 53 of the inter-pixel separation part 21.

In addition, according to the 12th embodiment, since a contact connected to the source region of the first channel part 441 and a contact connected to the source region of the second channel part 442 can be shared by the first contact part 541 on the conductive layer 53, and a contact connected to the drain region of the first channel part 441 and a contact connected to the drain region of the second channel part 442 can be shared by the second contact part 542 on the conductive layer 53, the number of contacts can be reduced, and, in accordance with this, the capacitance can be reduced.

### 13th Embodiment

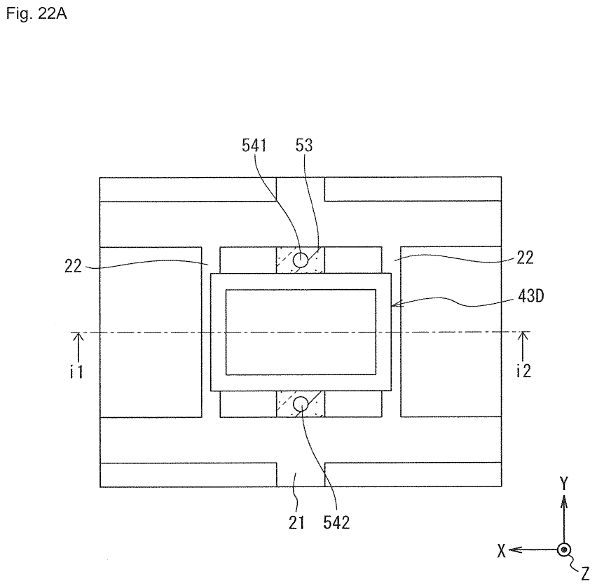

FIG. 21 is a plan view illustrating an example of an arrangement pattern of an amplification transistor AMP in a pixel 3 according to an 13th embodiment of the present technique. In FIG. 21, the same parts as those in FIG. 20 are denoted with the same reference signs, and detailed descriptions thereof will not be provided.

In the 13th embodiment of the present technique, a first contact part 541 is disposed in a pixel 3c, and a second contact part 542 is disposed in a pixel 3d.

### Function and Effect According to 13th Embodiment

As described above, according to the 13th embodiment, functions and effect that are similar to those of the 12th embodiment described above can be acquired.

### 14th Embodiment

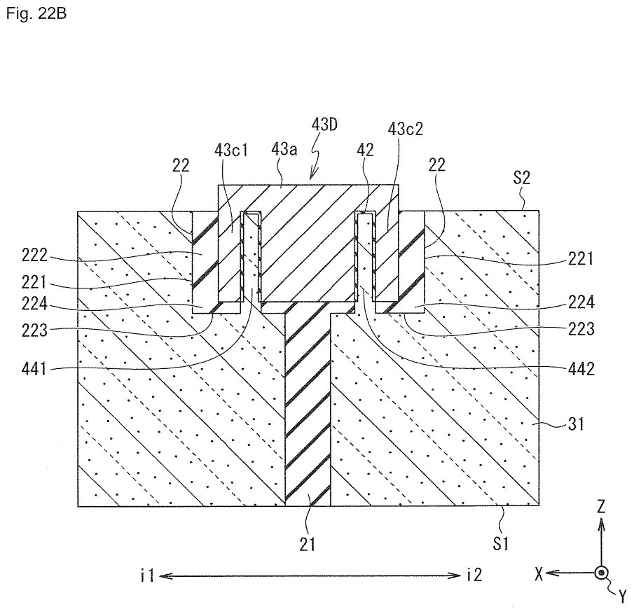

FIG. 22A is a plan view illustrating an example of an arrangement pattern of an amplification transistor AMP in a pixel 3 according to a 14th embodiment of the present technique. FIG. 22B is a diagram illustrating an example of a schematic cross-sectional structure of the amplification transistor AMP illustrated in FIG. 22A on an i1-i2 cross-section.

In the 14th embodiment of the present technique, an insulating film 224 is provided between a bottom surface part 223 of an element separation part 22 and second embedded parts 43c1, 43c2 of a gate electrode 43D. In addition, in the 14th embodiment, an insulating film 224 is provided between a first embedded part 43b of the gate electrode 43D and an upper surface part of an inter-pixel separation part 21.

### Function and Effect According to 14th Embodiment

As described above, according to the 14th embodiment, by forming the gate electrode 43D with the bottom surface part 223 of the element separation part 22 remaining, the gate capacitance can be reduced.

### 15th Embodiment

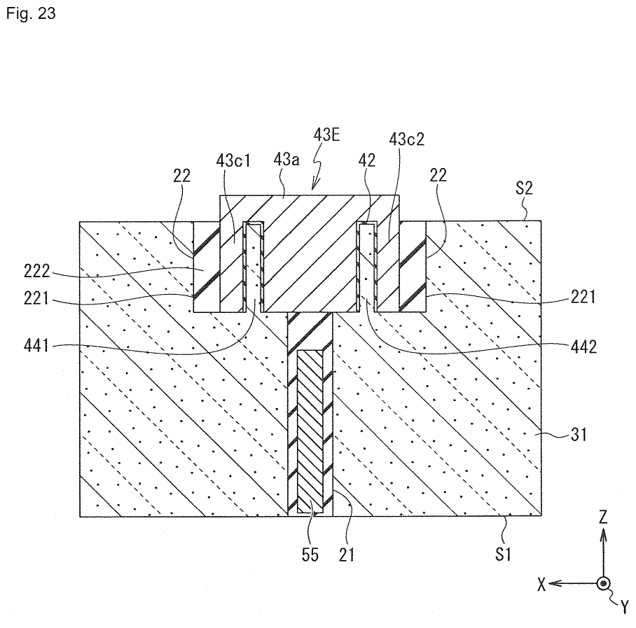

FIG. 23 is a cross-sectional view illustrating an embedding structure of a pixel transistor in an inter-pixel separation part according to a 15th embodiment of the present technique. In FIG. 23, the same reference signs are assigned to the same parts as those of FIG. 18B, and detailed description thereof is omitted. Here, an amplification transistor AMP is used as an example of the pixel transistor.

In the 15th embodiment, an inter-pixel separation part 21 has a conductive material 55 in an extending direction (a direction denoted by arrow Z in FIG. 23).

### Function and Effect According to 15th Embodiment

As described above, according to the 15th embodiment, since the conductive material 55 is contained in the inter-pixel separation part 21 when the gate electrode 43E is formed, the voltage can be applied.

### 16th Embodiment

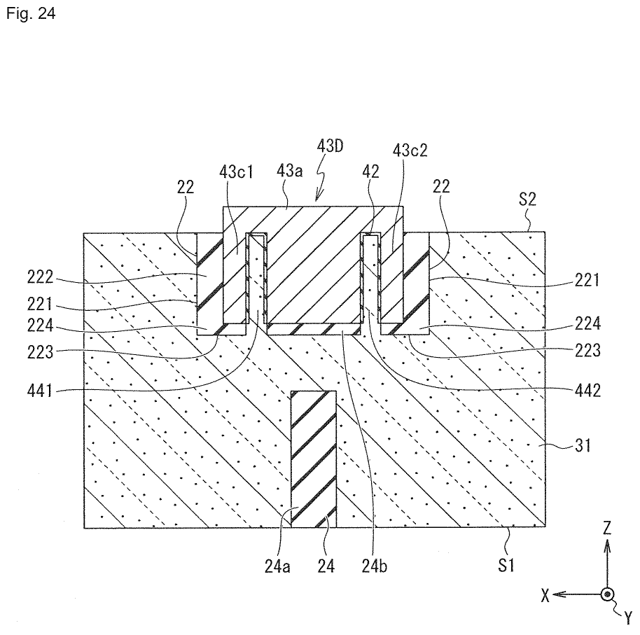

FIG. 24 is a cross-sectional view illustrating an embedding structure of a pixel transistor in an inter-pixel separation part according to a 16th embodiment of the present technique. In FIG. 24, the same reference signs are assigned to the same parts as those of FIG. 22B, and detailed description thereof is omitted. Here, an amplification transistor AMP is used as an example of the pixel transistor.

In the 16th embodiment, an inter-pixel separation part 24 has an RDTI structure in which an insulating film 24a is formed to extend from a first surface part S1 of a semiconductor layer 31 to the middle of the thickness direction (a direction denoted by arrow Z in FIG. 24). In addition, an upper surface part 24b of the inter-pixel separation part 24 is in contact with a bottom part of a first embedded part 43b of a gate electrode 43B.

### Function and Effect According to 16th Embodiment

As described above, according to the 16th embodiment, even in the case of the inter-pixel separation part 24 of the RDTI structure, the same functions and effects as those according to the previous 14th embodiment can be acquired.

### 17th Embodiment

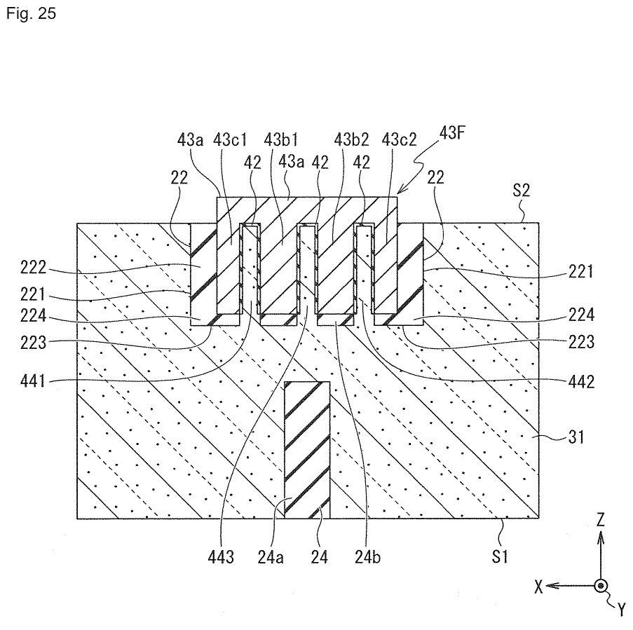

FIG. 25 is a cross-sectional view illustrating an embedding structure of a pixel transistor in an inter-pixel separation part according to a 17th embodiment of the present technique. In FIG. 25, the same reference signs are assigned to the same parts as those of FIG. 24, and detailed description thereof is omitted. Here, an amplification transistor AMP is used as an example of the pixel transistor.

In the 17th embodiment, the amplification transistor AMP has a third channel part 443 formed from an upper surface part 24b of an inter-pixel separation part 24 toward a head part 43a of a gate electrode 43F in a direction denoted by arrow Z in FIG. 25.

### Function and Effect According to 17th Embodiment

As described above, according to a 17th embodiment, multi-parallel pixel transistors can be realized on the upper surface part 24b of the inter-pixel separation part 24.

### 18th Embodiment

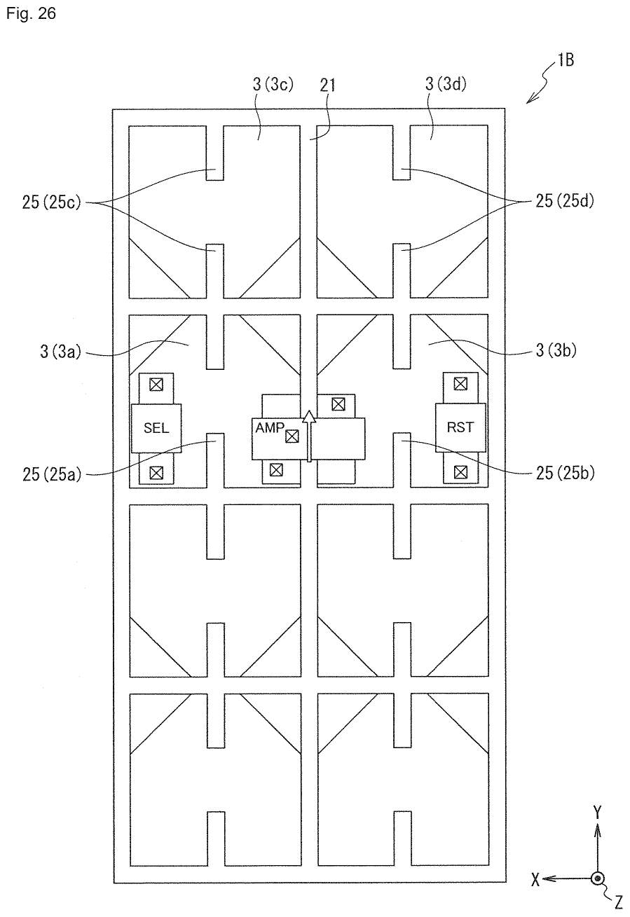

FIG. 26 is a plan view schematically illustrating one configuration example of a pixel block included in a pixel array unit of a light detection device 1B according to an 18th embodiment of the present technique. In FIG. 26, the same parts as those in FIG. 4 are denoted with the same reference signs, and detailed descriptions thereof will not be provided.

In the light detection device 1B, in addition to an inter-pixel separation part 21, an intra-pixel separation part 25 that separates the inside of each pixel 3 into two parts can be formed in a semiconductor chip 2. The intra-pixel separation part 25 is formed of a trench structure formed by, for example, an etching process and extends in the thickness direction of the semiconductor chip 2 (a direction denoted by arrow Z in FIG. 26) and in the row direction (a direction denoted by arrow Y in FIG. 26) in the plan view.

In a pixel 3a, for example, a selection transistor SEL as a pixel transistor is provided between the inter-pixel separation part 21 and the intra-pixel separation part 25a. In a pixel 3b, for example, a reset transistor RST as a pixel transistor is provided between the inter-pixel separation part 21 and the intra-pixel separation part 25b. In addition, an amplification transistor AMP is provided between the pixel 3a and the pixel 3b across the inter-pixel separation part 21.

A first channel part 441 and a second channel part 442 of the amplification transistor AMP are formed in a direction parallel to the extending direction of the intra-pixel separation part 25 (a direction denoted by arrow Y in FIG. 26).

### Function and Effect According to 18th Embodiment

As described above, according to the 18th embodiment, functions and effects that are the same as those of the previous 10th embodiment can be acquired. In the 18th embodiment, the intra-pixel separation part 25 may extend in a column direction (a direction denoted by arrow X in FIG. 26) in the plan view.

### 19th Embodiment

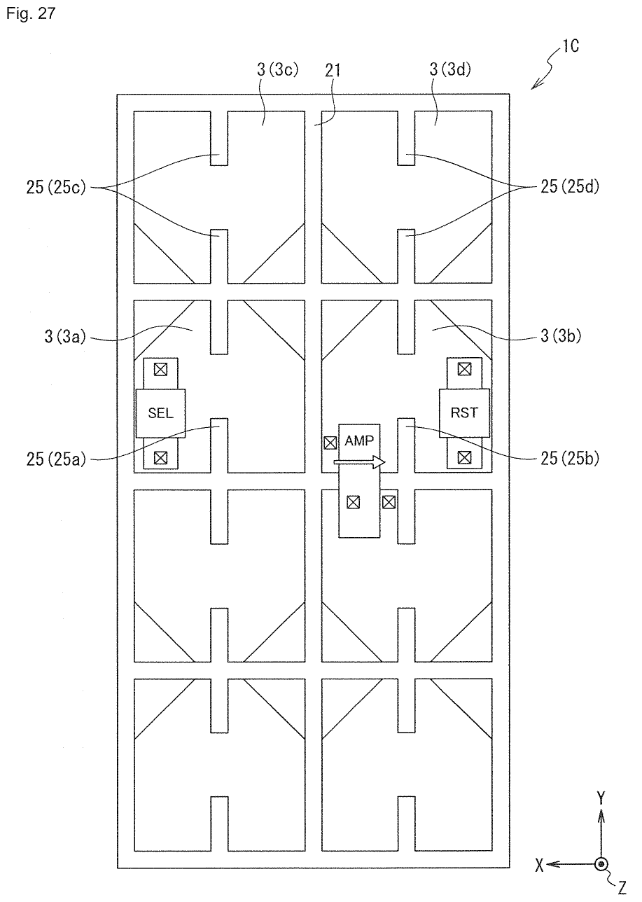

FIG. 27 is a plan view schematically illustrating one configuration example of a pixel block included in a pixel array unit of a light detection device 1C according to a 19th embodiment of the present technique. In FIG. 27, the same parts as those in FIG. 26 are denoted with the same reference signs, and detailed descriptions thereof will not be provided.

In the light detection device 1C, an amplification transistor AMP is provided across an inter-pixel separation part 21 between a pixel 3b and a pixel 3 adjacent thereto in a row direction. A first channel part 441 and a second channel part 442 of the amplification transistor AMP is formed in a direction perpendicular to an extending direction of an intra-pixel separation part 25 (a direction denoted by arrow Y in FIG. 27).

### Function and Effect According to 19th Embodiment

As described above, according to the 19th embodiment, functions and effects that are similar to those of the previous 18th embodiment can be obtained. In the 19th embodiment, the intra-pixel separation part 25 may extend in a column direction (a direction denoted by arrow X in FIG. 27) in the plan view.

### 20th Embodiment

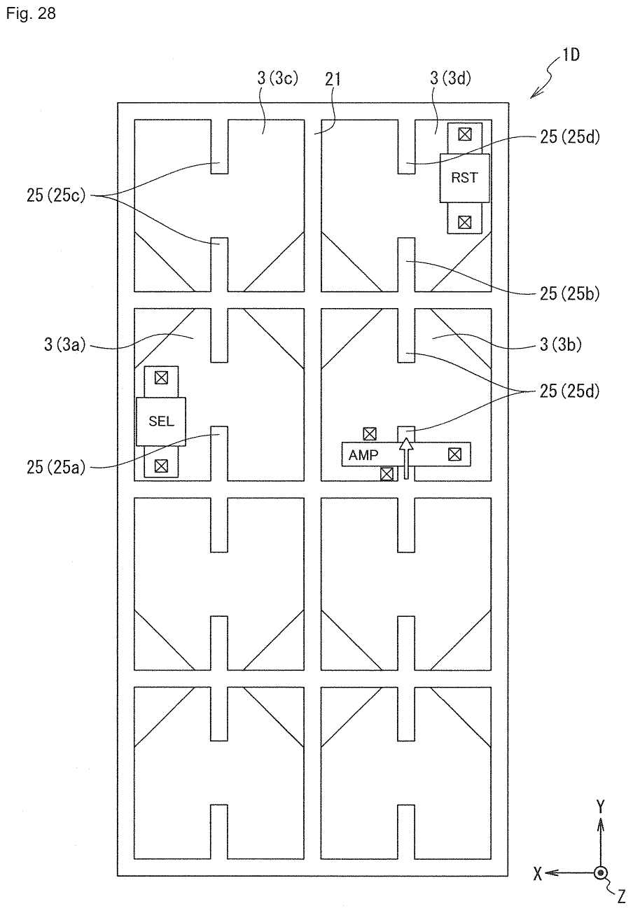

FIG. 28 is a plan view schematically illustrating one configuration example of a pixel block included in a pixel array unit of a light detection device 1D according to a 20th embodiment of the present technique. In FIG. 28, the same parts as those in FIG. 26 are denoted with the same reference signs, and detailed descriptions thereof will not be provided.

In the light detection device 1D, an amplification transistor AMP is provided across an inter-pixel separation part 21 across an intra-pixel separation part 25b of a pixel 3b. A first channel part 441 and a second channel part 442 of the amplification transistor AMP are formed in a direction parallel to an extending direction of the intra-pixel separation part 25 (a direction denoted by arrow Y in FIG. 28). In a pixel 3d, for example, a reset transistor RST as a pixel transistor is provided between the inter-pixel separation part 21 and an intra-pixel separation part 25d.

### Function and Effect According to 20th Embodiment

As described above, according to the 20th embodiment, functions and effect that are similar to those of the previous 18th embodiment can be acquired. In the 20th embodiment, the intra-pixel separation part 25 may extend in a column direction (a direction denoted by arrow X in FIG. 28) in the plan view.

### 21st Embodiment

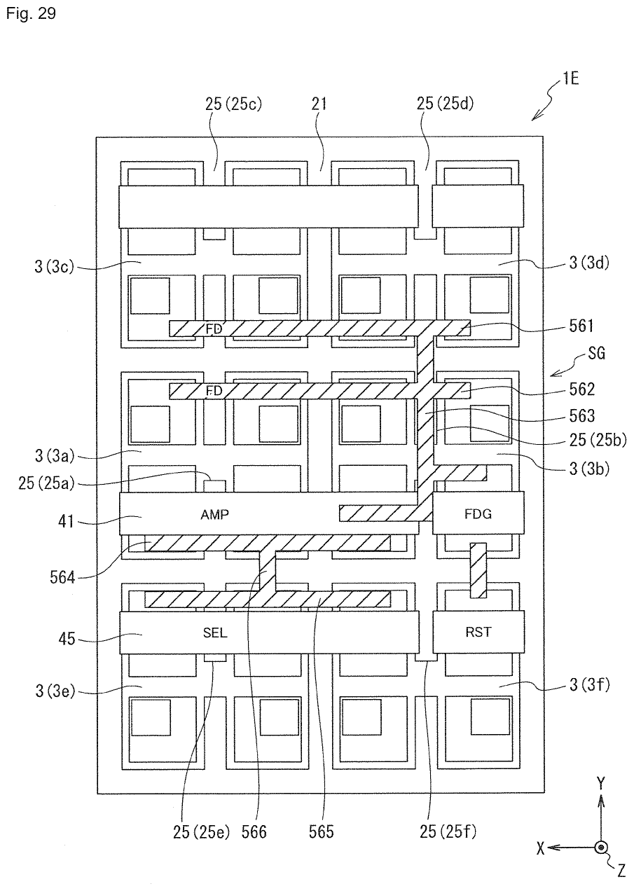

FIG. 29 is a plan view schematically illustrating one configuration example of a pixel block included in a pixel array unit of a light detection device 1E according to a 21st embodiment of the present technique. In FIG. 29, the same parts as those in FIG. 4 are denoted with the same reference signs, and detailed descriptions thereof will not be provided.

In the light detection device 1E, a floating diffusion (floating diffusion part) FD is provided in each pixel 3. For example, four pixels 3a to 3d among a plurality of pixels 3 constitute a shared pixel SG. In the shared pixel SG, a gate electrode 41 of an amplification transistor AMP is arranged in the pixel 3a and the pixel 3b across an intra-pixel separation part 25a of the pixel 3a and an inter-pixel separation part 21. In the shared pixel SG, a selection transistor SEL is arranged in a pixel 3e and a pixel 3f other than the shared pixel SG, and a reset transistor RST is arranged in a pixel 3f other than the shared pixel SG. A gate electrode 45 of the selection transistor SEL is arranged in the pixel 3e and the pixel 3f across an intra-pixel separation part 25e of the pixel 3e and the inter-pixel separation part 21.

In the pixel 3b, a gate electrode of a switching transistor FDG is arranged between an intra-pixel separation part 25b and the inter-pixel separation part 21. The switching transistor FDG electrically couples a floating diffusion FD to additional capacitance to adjust the potential conversion efficiency of the floating diffusion FD. A gate electrode of the reset transistor RST is arranged between the inter-pixel separation part 21 and the intra-pixel separation part 25f of the pixel 3f.

The floating diffusion FD of each of the pixel 3c and the pixel 3d is connected using a wiring 561 made of metal or polysilicon. The floating diffusion FD of each of the pixel 3a and the pixel 3b is connected using a wiring 562 made of metal or polysilicon. The wirings 561 and 562 are connected to the gate electrode 41 of the amplification transistor AMP using a wiring 563 made of metal or polysilicon.

A plurality of channel parts of the amplification transistor AMP are connected using a wiring 564 made of metal or polysilicon. The plurality of channel parts of the selection transistor SEL are connected using a wiring 565 made of metal or polysilicon. The wirings 564 and 565 are connected using a wiring 566.

### Function and Effect According to 21st Embodiment

As described above, according to the 21st embodiment, by arranging the gate electrode 41 of the amplification transistor AMP and the gate electrode 45 of the selection transistor by effectively utilizing the upper surface part of the inter-pixel separation part 21 in the shared pixel SG, the maximum area efficiency can be acquired in accordance with miniaturization of the pixel 3.

In addition, according to the 21st embodiment, the floating diffusion FD, the amplification transistor AMP, and the selection transistor SEL can be connected to each other in a shortest distance in units of shared pixels SG using the wirings 561 to 566.

### Modified Example of 21st Embodiment

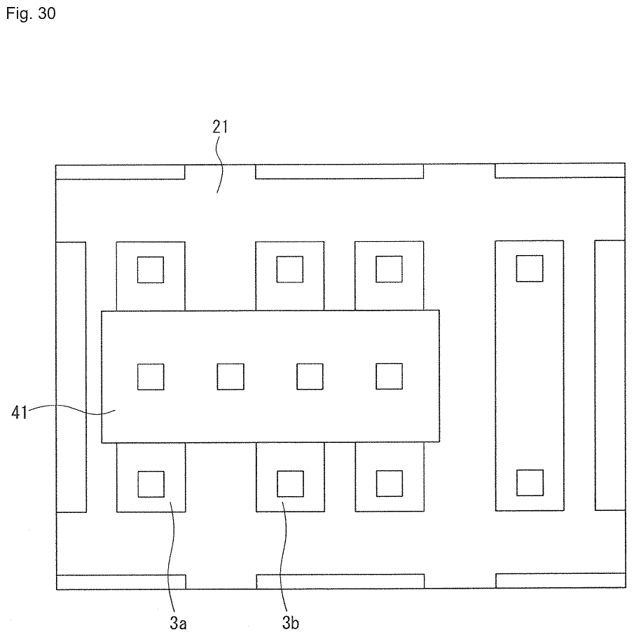

FIG. 30 is a plan view illustrating an example of an arrangement pattern of a pixel transistor according to a modified example of the 21st embodiment of the present technique. In FIG. 30, an amplification transistor AMP is used as an example of the pixel transistor.

### Comparative Example of the Modified Example of 21st Embodiment

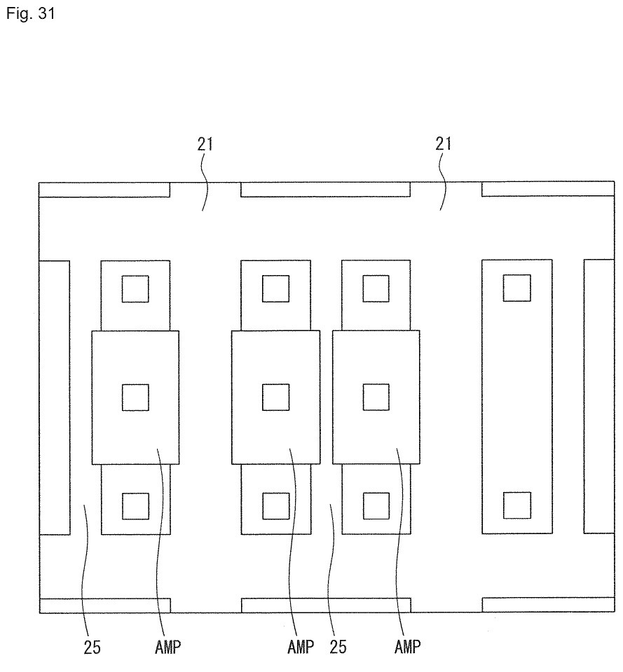

FIG. 31 is a plan view illustrating an example of an arrangement pattern of a pixel transistor according to a comparative example. One contact can be arranged in the gate electrode of the amplification transistor AMP.

### Solving Means According to Modified Example of 21st Embodiment

According to the modified example of the 21st embodiment, since the gate electrode 41 of the amplification transistor AMP is arranged across the inter-pixel separation part 21 and the intra-pixel separation part 25, a plurality of contacts (four contacts in FIG. 30) can be arranged. In accordance with this, since the gate electrodes 41 of the plurality of amplification transistors are connected, the number of contacts that can be arranged can be increased, and, in accordance with this, the RN improvement effect according to reduction of the gate resistance can be also expected.

### 22nd Embodiment

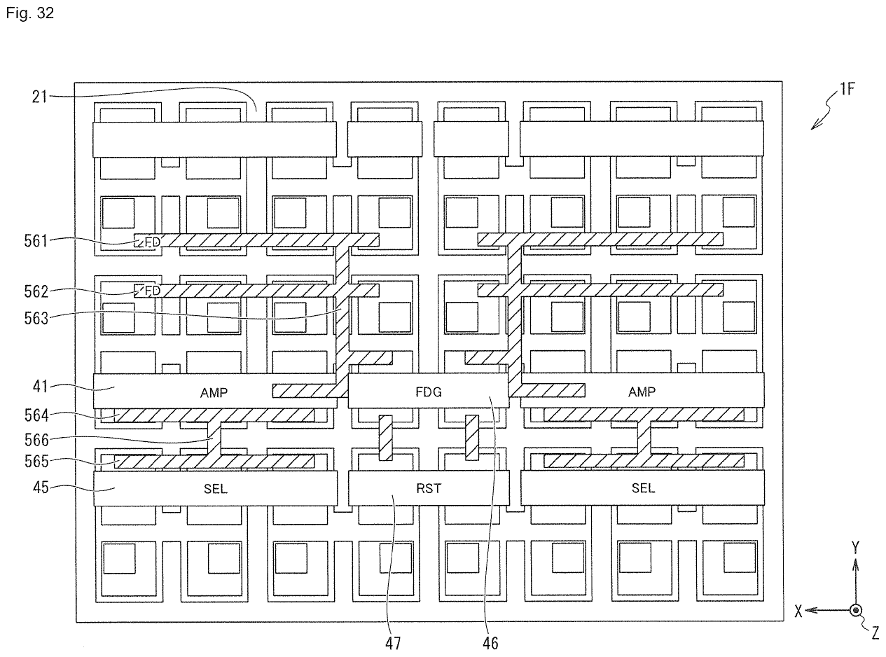

FIG. 32 is a plan view schematically illustrating one configuration example of a pixel block included in a pixel array unit of a light detection device 1F according to a 22nd embodiment of the present technique. In FIG. 32, the same parts as those in FIG. 29 are denoted with the same reference signs, and detailed descriptions thereof will not be provided.

In a shared pixel SG, a gate electrode 46 of a switching transistor FDG is arranged in two pixels 3 across an inter-pixel separation part 21. A gate electrode 47 of a reset transistor RST is arranged in two pixels 3 across the inter-pixel separation part 21.

<Function and Effect according to 22nd Embodiment>

As described above, according to the 22nd embodiment, functions and effects that are similar to those of the previous 21st embodiment can be acquired.

### 23rd Embodiment

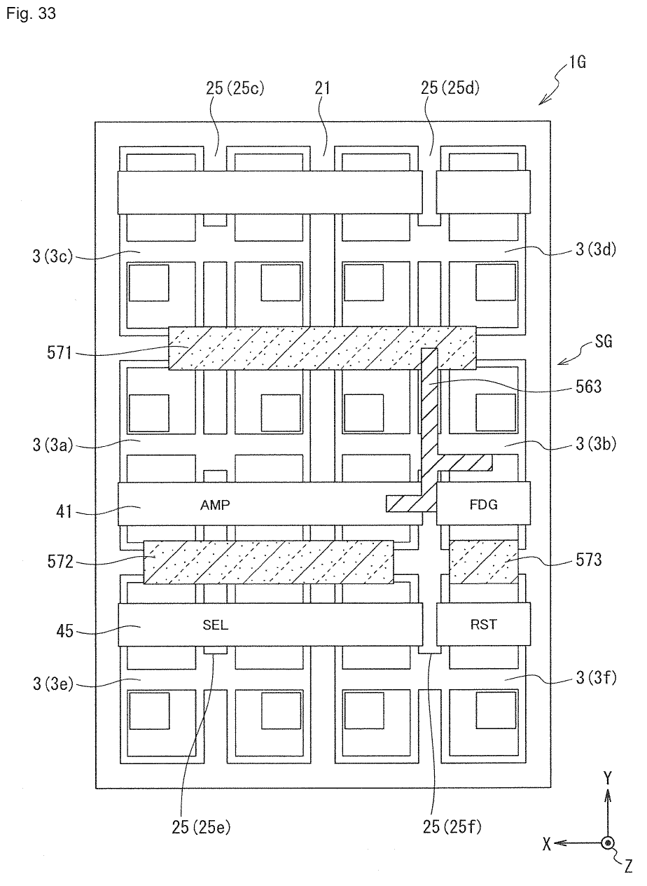

FIG. 33 is a plan view schematically illustrating one configuration example of a pixel block included in a pixel array unit of a light detection device 1G according to a 23rd embodiment of the present technique. In FIG. 33, the same parts as those in FIG. 29 are denoted with the same reference signs, and detailed descriptions thereof will not be provided.

In the light detection device 1G, four floating diffusions FD of pixels 3a to 3d, for example, are electrically connected using a conductive material 571 made of polysilicon. A plurality of channel parts of an amplification transistor AMP and a plurality of channel parts of a selection transistor SEL are electrically connected, for example, using a conductive material 572 made of polysilicon. In addition, a switching transistor FDG and a reset transistor RST are electrically connected, for example, using a conductive material 572 made of polysilicon.

### Function and Effects According to 23rd Embodiment

As described above, according to the 23rd embodiment, the floating diffusion FD of each of the plurality of pixels 3 is electrically connected using the conductive material 571 of the upper surface part of the inter-pixel separation part 21, and the amplification transistor AMP of the shared pixel SG and the selection transistor SEL are electrically connected using the conductive material 572 of the upper surface part of the inter-pixel separation part 21, whereby low resistance according to reduction of the wiring capacitance and shortest connection can be achieved.

### 24th Embodiment

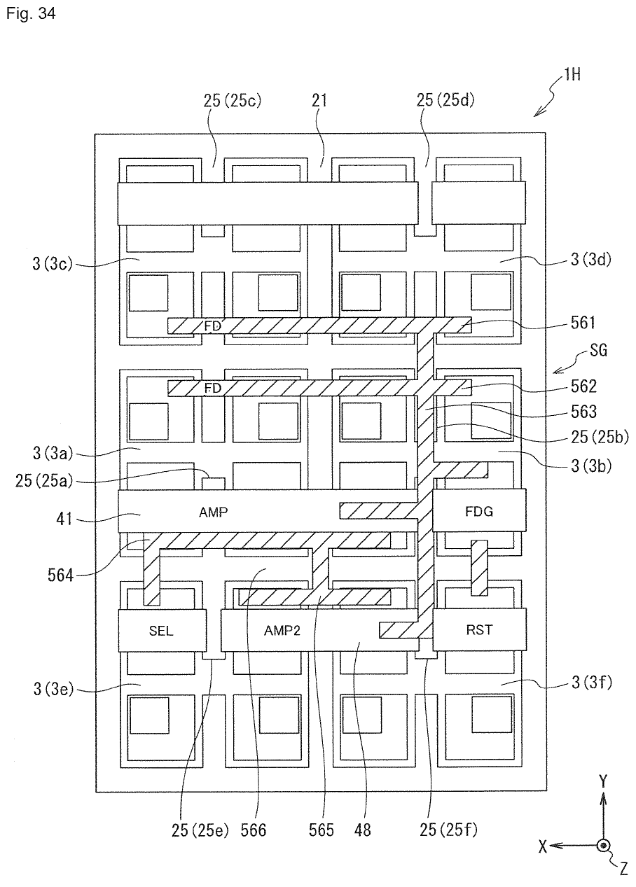

FIG. 34 is a plan view schematically illustrating one configuration example of a pixel block included in a pixel array unit of a light detection device 1H according to a 24th embodiment of the present technique. In FIG. 34, the same parts as those in FIG. 29 are denoted with the same reference signs, and detailed descriptions thereof will not be provided.

In a shared pixel SG, a gate electrode 41 of a first amplification transistor AMP1 is arranged in a pixel 3a and a pixel 3b across an intra-pixel separation part 25a and an inter-pixel separation part 21 of the pixel 3a. In the shared pixel SG, a gate electrode 48 of a second amplification transistor AMP2 is arranged in a pixel 3e and a pixel 3f across the inter-pixel separation part 21.

A floating diffusion FD of each of pixels 3c and 3d is connected using a wiring 561 made of metal or polysilicon. A floating diffusion FD of each of a pixel 3a and a pixel 3b is connected using a wiring 562 made of metal or polysilicon. The wirings 561 and 562 are connected to the gate electrode 41 of the first amplification transistor AMP1 and the gate electrode 48 of the second amplification transistor AMP2 using a wiring 563 made of metal or poly-silicon.

### Function and Effect According to 24th Embodiment

As described above, according to the 24th embodiment, in a case in which the parallel number of first amplification transistors AMP1 and second amplification transistors AMP2 is maximized, improvement of the mutual conductance gm, RN, and RTS can be expected by maximizing the effective gate width W.

### 25th Embodiment

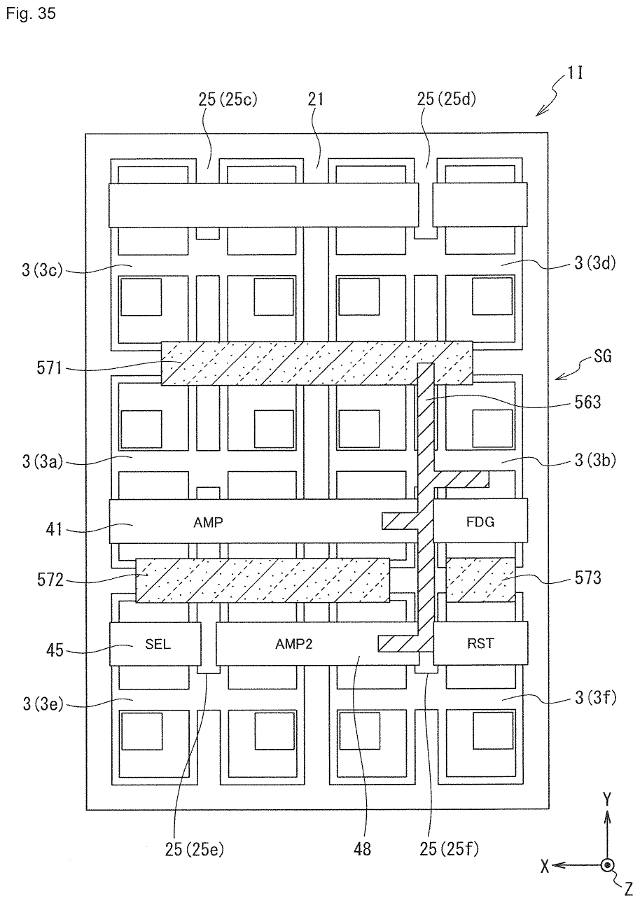

FIG. 35 is a plan view schematically illustrating one configuration example of a pixel block included in a pixel array unit of a light detection device 1I according to a 25th embodiment of the present technique. In FIG. 35, the same parts as those in FIG. 33 are denoted with the same reference signs, and detailed descriptions thereof will not be provided.

In the light detection device 1I, four floating diffusions FD of a pixels 3a to a pixel 3d, for example, are electrically connected using a conductive material 571 made of polysilicon. A plurality of channel parts of a first amplification transistor AMP1, a plurality of channel parts of a second amplification transistor AMP2, and a plurality of channel parts of a selection transistor SEL are electrically connected, for example, using a conductive material 574 made of polysilicon. In addition, a switching transistor FDG and a reset transistor RST are electrically connected, for example, using a conductive material 573 made of polysilicon.

### Function and Effect According to 25th Embodiment

As described above, according to the 25th embodiment, in addition to the functions and effects of the previous 24th embodiment, implementation of low resistance according to reduction of the wiring capacitance and shortest connection can be achieved.

### 26th Embodiment

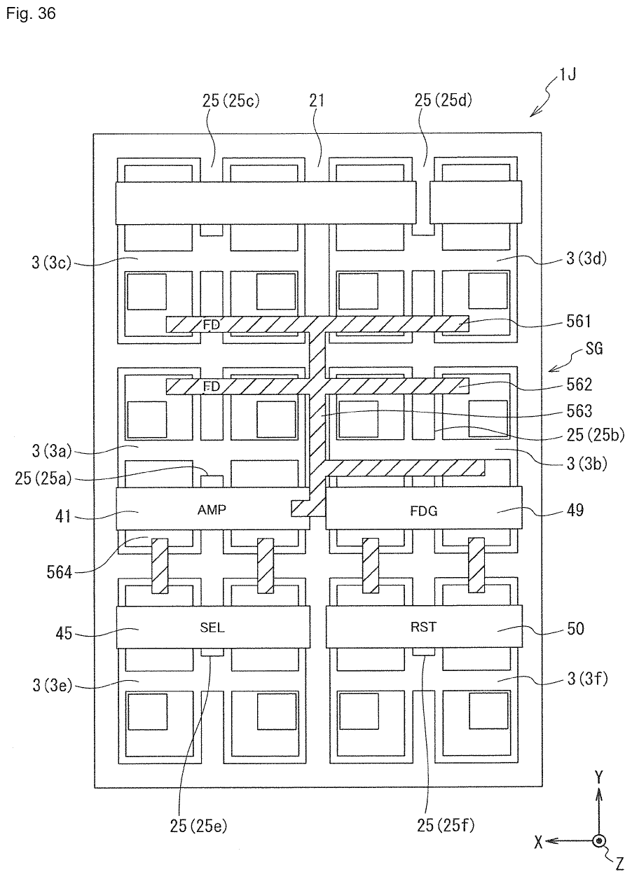

FIG. 36 is a plan view schematically illustrating one configuration example of a pixel block included in a pixel array unit of a light detection device 1J according to a 26th embodiment of the present technique. In FIG. 36, the same parts as those in FIG. 29 are denoted with the same reference signs, and detailed descriptions thereof will not be provided.

In the light detection device 1J, a gate electrode 41 of an amplification transistor AMP is arranged in a pixel 3a across an intra-pixel separation part 25a of the pixel 3a. A gate electrode 45 of a selection transistor SEL is arranged in a pixel 3e across the intra-pixel separation part 25e of the pixel 3e. A gate electrode 49 of a switching transistor FDG is arranged in a pixel 3b across the intra-pixel separation part 25b of the pixel 3b. Furthermore, a gate electrode 50 of a reset transistor RST is arranged in a pixel 3f across an intra-pixel separation part 25f of a pixel 3f.

A floating diffusion FD of each of a pixel 3c and a pixel 3d is connected using a wiring 561 made of metal or polysilicon. A floating diffusion FD of each of a pixel 3a and a pixel 3b is connected using a wiring 562 made of metal or polysilicon. The wirings 561 and 562 are connected to a gate electrode 41 of the amplification transistor AMP and a plurality of channel parts of the switching transistor FDG using a wiring 563 made of metal or polysilicon.

The plurality of channel parts of the amplification transistor AMP are connected to the plurality of channel parts of the selection transistor SEL using a wiring made of metal or polysilicon. The plurality of channel parts of the switching transistor FDG are connected to the plurality of channel parts of the reset transistor RST using a wiring made of metal or polysilicon.

### Function and Effect According to 26th Embodiment

As described above, according to the 26th embodiment, reduction of the resistance of the switching transistor FDG at the time of switching the conversion efficiency and an increase in the capacitance at the time of driving with low conversion efficiency can be achieved.

### 27th Embodiment

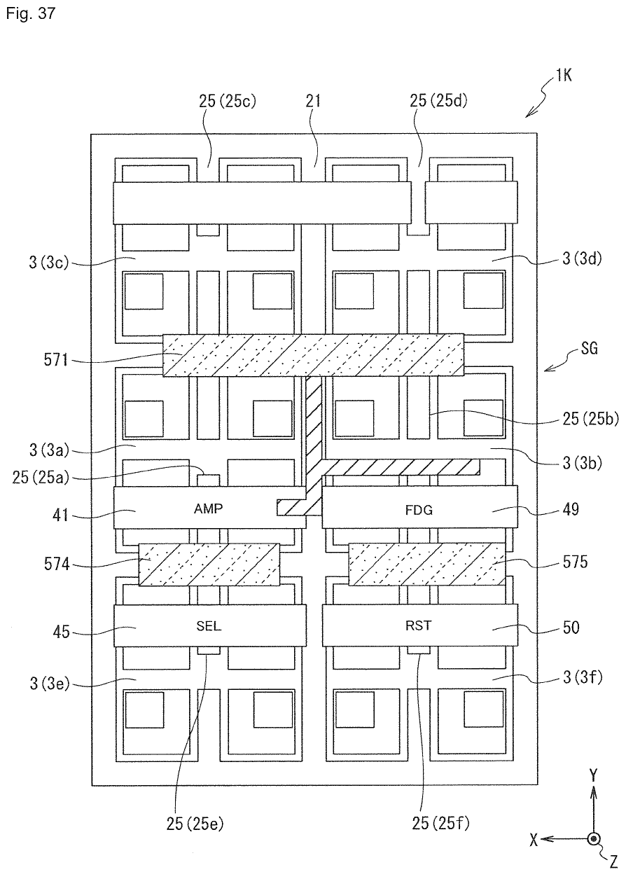

FIG. 37 is a plan view schematically illustrating one configuration example of a pixel block included in a pixel array unit of a light detection device 1K according to a 27th embodiment of the present technique. In FIG. 37, the same parts as those in FIG. 36 are denoted with the same reference signs, and detailed descriptions thereof will not be provided.

In the light detection device 1K, four floating diffusions FD of pixels 3a to 3d are electrically connected, for example, using a conductive material 571 made of polysilicon. A plurality of channel parts of an amplification transistor AMP and a plurality of channel parts of a selection transistor SEL are electrically connected, for example, using a conductive material 574 made of polysilicon. In addition, a plurality of channel parts of a switching transistor FDG and a plurality of channel parts of a reset transistor RST are electrically connected, for example, using a conductive material 575 made of polysilicon. <Function and effect according to 27th embodiment>

As described above, according to the 27th embodiment, functions and effects that are similar to those of the previous 26th embodiment can be acquired.

### 28th Embodiment

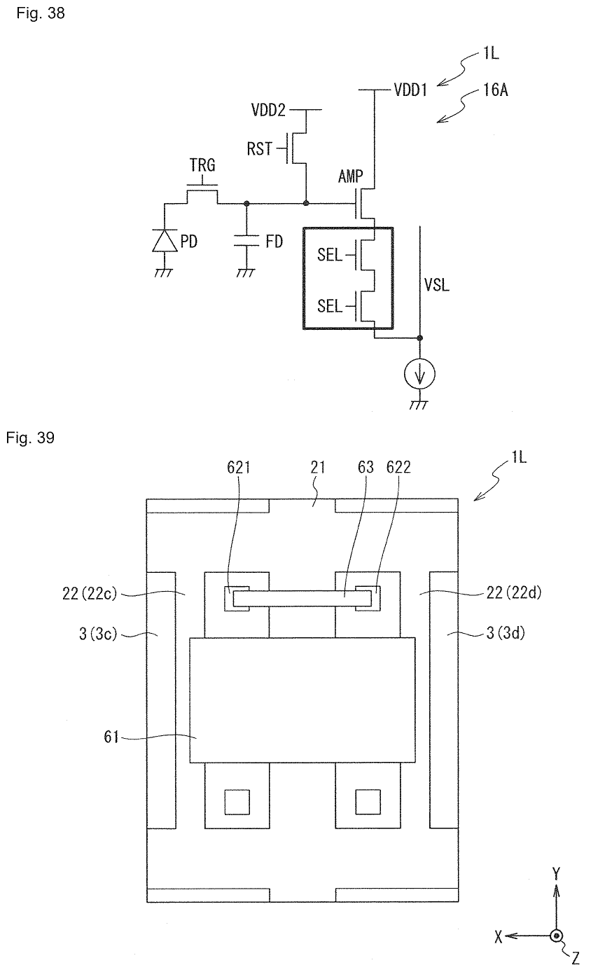

FIG. 38 is a circuit block diagram illustrating a reading circuit 16A of a light detection device 1L according to a 28th embodiment of the present technique. A reading circuit 16A connects two selection transistors SEL in series. In addition, the reading circuit 16A connects an amplification transistor AMP to a power supply VDD1 and connects a reset transistor RST to a power supply VDD2 different from that of the amplification transistor AMP.

FIG. 39 is a plan view, for example, illustrating an example of an arrangement pattern of a selection transistor SEL in a pixel 3. The selection transistor SEL is arranged, for example, between a pixels 3c and a pixel 3d.

The selection transistor SEL has a gate electrode 61 arranged between an element separation part 22c and an element separation part 22d across an inter-pixel separation parts 21. In addition, in the selection transistor SEL, a first channel part is formed between the inter-pixel separation part 21 and an element separation part 22c, and a second channel part is formed between the inter-pixel separation part 21 and an element separation part 22d. A source region 621 of the first channel part of the selection transistor SEL and a drain region 622 of the second channel part are electrically connected using a wiring 63 in a column direction (a direction denoted by arrow X in FIG. 39) in the plan view (XY plane in FIG. 39).

The wiring 63 is made of a metal wiring or a polysilicon wiring and connects a source region 621 of the first channel part of the selection transistor SEL and a drain region 622 of the second channel part across the upper surface part of the inter-pixel separation part 21.

### Function and Effect According to 28th Embodiment

As described above, according to the 28th embodiment, in a case in which a plurality of selection transistors SEL having gate electrodes 61 of the same node are connected in series, the gate electrode 61 extends over the upper surface part of the inter-pixel separation part 21, and the source region 621 of the first channel section and the drain region 622 of the second channel section are electrically connected via the wiring 63 across the upper surface part of the inter-pixel separation part 21, whereby the effective gate length L can be expanded, and an operation margin accompanying formation of fine pixels can be secured.

### 29th Embodiment

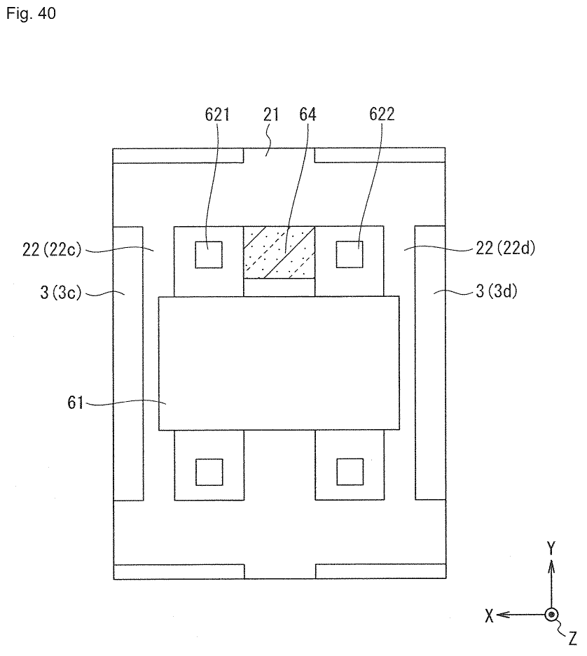

FIG. 40 is a plan view illustrating an example of an arrangement pattern of a selection transistor SEL in a pixel 3 according to a 29th embodiment of the present technique.

In the 29th embodiment of the present technique, a conductive layer 64 is provided in an upper surface part of an inter-pixel separation part 21 between a source region 621 of a first channel part and a drain region 622 of a second channel part of the selection transistor SEL. The conductive layer 64 is made of an epitaxial silicon, a polysilicon, or an oxide semiconductor and can electrically connect the source region 621 of the first channel part and the drain region 622 of the second channel part.

### Function and Effect According to 29th Embodiment

As described above, according to the 29th embodiment, functions and effect that are similar to those of the previous 28th embodiment can be acquired.

### 30th Embodiment

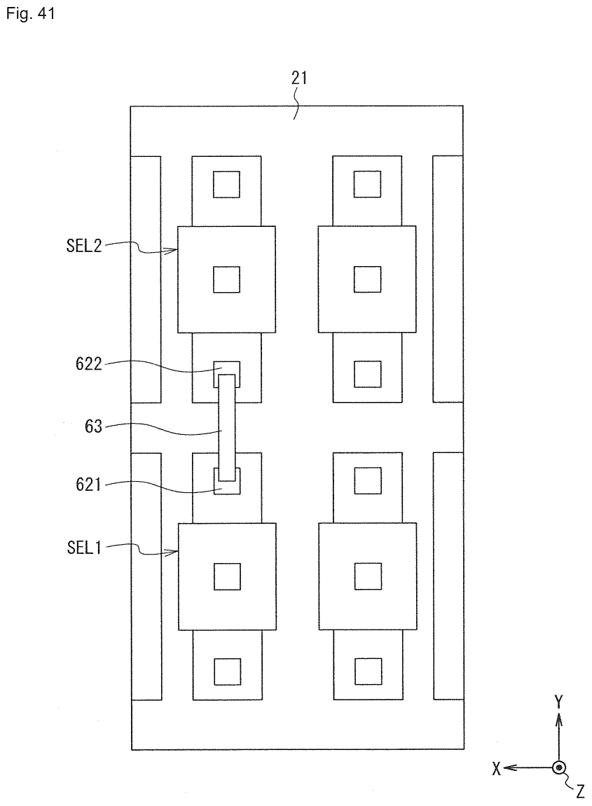

FIG. 41 is a plan view illustrating an example of an arrangement pattern of a selection transistor SEL in a pixel 3 according to a 30th embodiment of the present technique.

In the 30th embodiment of the present technique, a source region 621 of a first channel part of one selection transistor SEL1 and a drain region 622 of a second channel part of the other selection transistor SEL2 are electrically connected using a wiring 63 in a row direction (a direction denoted by arrow X in FIG. 39) in the plan view (XY plane in FIG. 41).

### Function and Effect According to 30th Embodiment

As described above, according to the 30th embodiment, functions and effects that are similar to those of the previous 28th embodiment can be acquired.

### 31st Embodiment

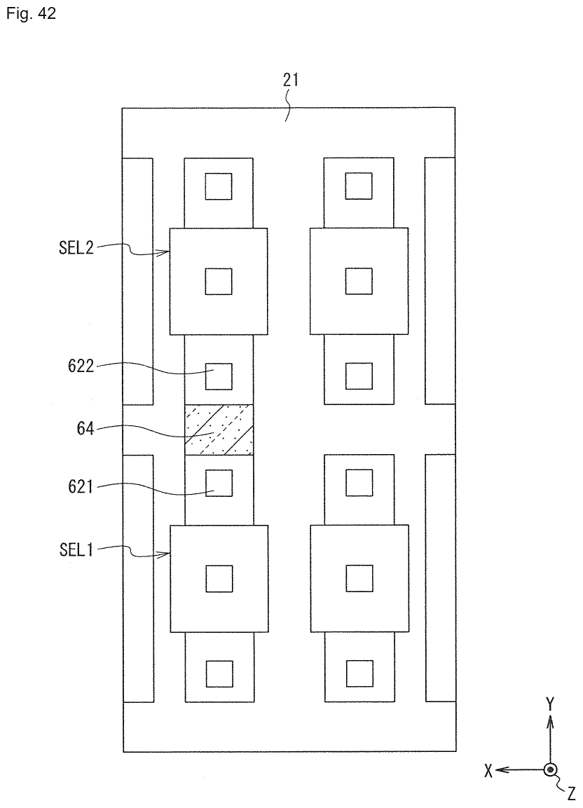

FIG. 42 is a plan view illustrating an example of an arrangement pattern of a selection transistor SEL in a pixel 3 according to a 31st embodiment of the present technique.

In the 31st embodiment of the present technique, a conductive layer 64 is provided in an upper surface part of an inter-pixel separation part 21 between a source region 621 of a first channel part of one selection transistor SEL1 and a drain region 622 of a second channel part of the other selection transistor SEL2.

### Function and Effect According to 31st Embodiment

As described above, according to the 31st embodiment, functions and effects that are similar to those of the previous 28th embodiment can be acquired.

### <32nd Embodiment

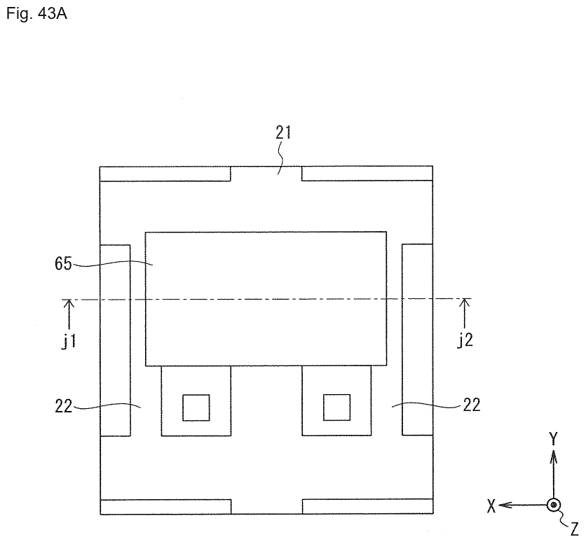

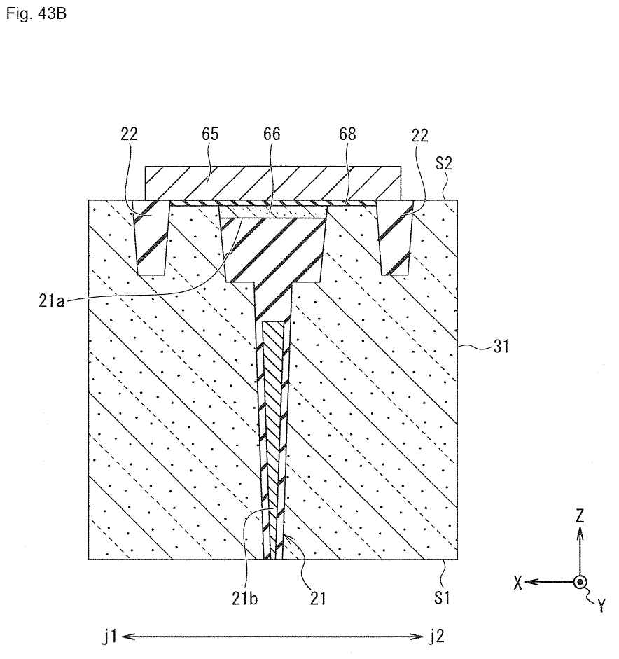

FIG. 43A is a plan view illustrating an example of an arrangement pattern of a selection transistor SEL in a pixel 3 according to a 32nd embodiment of the present technique. In FIG. 43A, the same parts as those in FIG. 39 are denoted with the same reference signs, and detailed descriptions thereof will not be provided.

A selection transistor SEL has a gate electrode 65 covering a source region 621 of a first channel part and a drain region 622 of a second channel part of the selection transistor SEL.

FIG. 43B is a diagram illustrating an example of a schematic cross-section structure of the selection transistor SEL illustrated in FIG. 43A on a j1-j2 cross-section.

In the 32nd embodiment of the present technique, a channel part 66 is formed by embedding a material in an upper surface part 21a of an inter-pixel separation part 21. As the material, epitaxial silicon, polysilicon, or any other oxide semiconductor is used. In addition, a gate insulating film 68 is formed between a second surface part S2 of a semiconductor layer 31 and a channel part 66 and the gate electrode 65.

### Function and Effect According to 32nd Embodiment

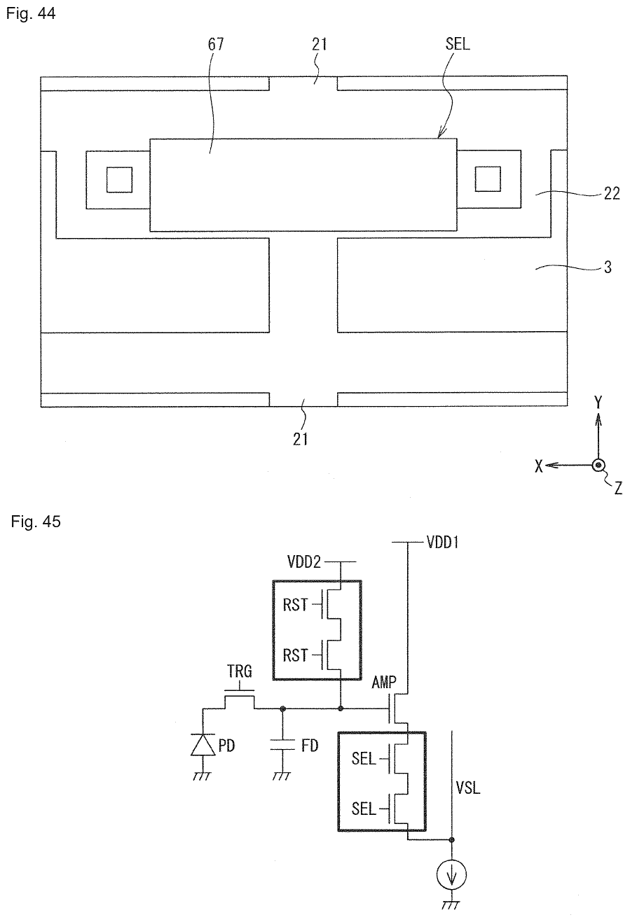

As described above, according to the 31st embodiment, functions and effects that are similar to those of the previous 28th embodiment can be acquired. In addition, as illustrated in FIG. 44, a channel part may be formed in the upper surface part of the pixel separation part 21 under the gate electrode 67 of the selection transistor SEL arranged between the inter-pixel separation part 21 and the element separation part 22.

### 33rd Embodiment

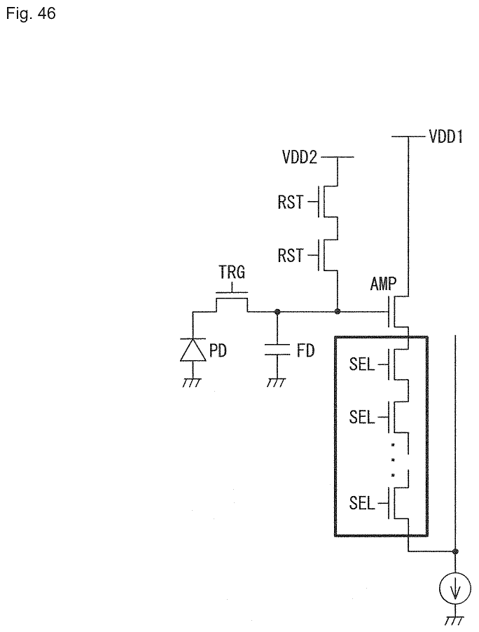

As a 33rd embodiment of the present technique, as illustrated in FIG. 45, not only the series connection of two selection transistors SEL but also series connection of two reset transistors RST can be considered. Furthermore, as illustrated in FIG. 46, a large number of selection transistors SEL that is two or more may be connected in series.

### 34th Embodiment

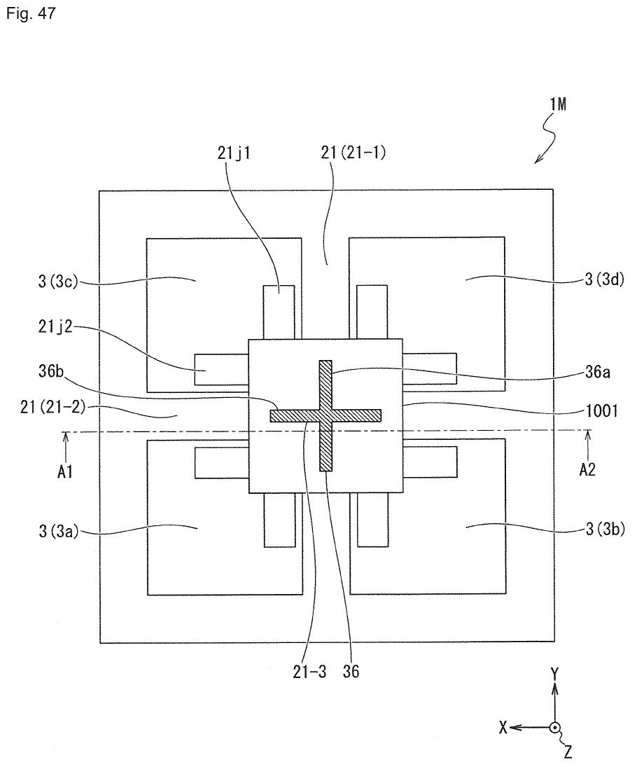

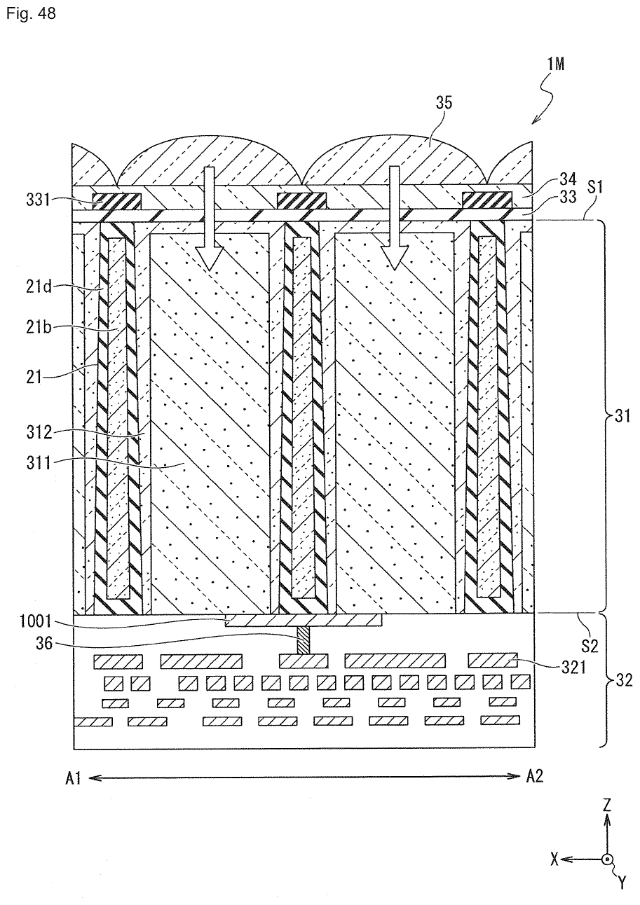

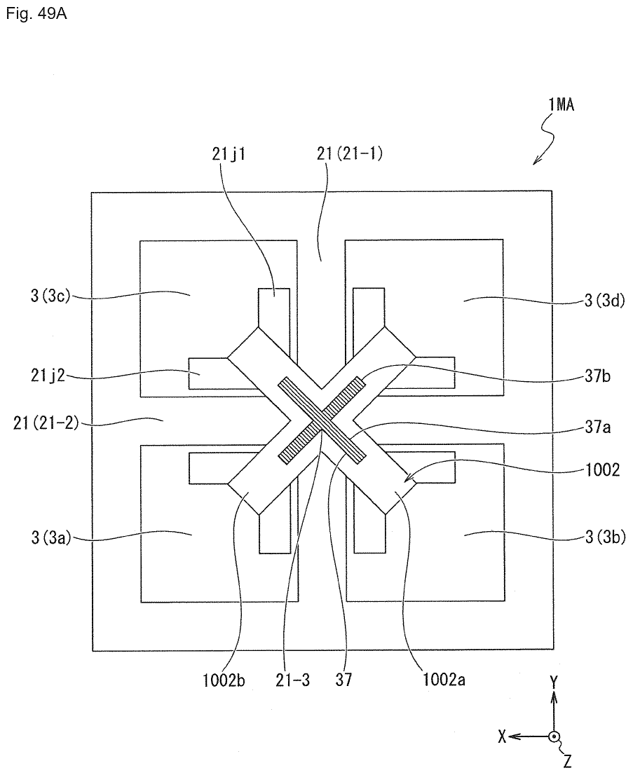

FIG. 47 is a plan view schematically illustrating a configuration example of a pixel block included in a pixel array unit of a light detection device 1M according to a 34th embodiment of the present technique. FIG. 47 illustrates a planar layout acquired when seen from a surface (an element forming surface) on a side opposite to the surface of a pixel 3 in which light is incident (a light reception surface). FIG. 48 is a partial longitudinal cross-sectional view illustrating an example of a semiconductor structure of the pixel 3 illustrated in FIG. 47 on an A1-A2 cross-section. Note that in the present disclosure, a plane parallel to the element forming surface of the pixel 3 is referred to as an XY plane, and a direction perpendicular to the XY plane is referred to as a Z direction or a depth direction.

In FIG. 47, a gate electrode 1001 of a pixel transistor crosses four pixels 3a, 3b, 3c, and 3d, which are adjacent to each other, across the upper surface part of an intersection portion 21-3 at which an inter-pixel separation part 21-1 extending in a row direction (a direction denoted by arrow Y in FIG. 47) in the plan view (XY plane) intersects an inter-pixel separation part 21-2 extending in a column direction (a direction denoted by arrow X in FIG. 47) in the plan view.

In the gate electrode 1001, a contact structure part 36 connected to a metal wiring of a wiring layer described below is arranged. The contact structure part 36 has a linear part 36a (an example of a first shape pattern part) formed along the row direction of the inter-pixel separation part 21-1 and a linear part 36b (an example of a second shape pattern part) that intersects with the linear part 36a and is formed along the column direction of the inter-pixel separation part 21-2. Furthermore, in each of the pixels 3a, 3b, 3c, and 3d, a source region 21j1 formed along the row direction of the inter-pixel separation part 21-1 and a drain region 21j2 formed along the column direction of the inter-pixel separation part 21-2 are disposed.

In FIG. 48, the semiconductor structure of the light detection device 1M is schematically configured to include a semiconductor layer 31, a wiring layer 32, a planarization film 33, a color filter layer 34, and an on-chip lens 35. The planarization film 33, the color filter layer 34, and the on-chip lens 35 are stacked in this order on a first surface S1 of the semiconductor layer 31. The wiring layer 32 is stacked on a second surface S2 of the semiconductor layer 31. In addition, the semiconductor structure of the light detection device 1M includes a contact structure part 36.

The on-chip lens 35 is an optical lens used for efficiently condensing light incident in the light detection device 1M from the outside and forming an image on each pixel 3 of the semiconductor layer 31. This on-chip lens 35, typically, is arranged for each pixel 3.

The color filter layer 34 is an optical filter that selectively transmits light with a predetermined wavelength out of light condensed by the on-chip lens 35. In this example, four color filter layers 34 that selectively transmit wavelengths of red light, green light, blue light, and near-infrared light are used, but it is not limited thereto to. A color filter layer 34 corresponding to one of the colors (wavelengths) is arranged in each pixel 3.

In the semiconductor layer 31, an n-type layer 311 and a p-type layer 312 (hereinafter referred to as a p-well 312), which is a well layer, constituting a photodiode PD that is a photoelectric conversion element are disposed. Each n-type layer 311 of the semiconductor layer 31 generates an amount of electric charge corresponding to the intensity of light incident through the on-chip lens 35 and the color filter layer 34, converts it into an electric signal, and outputs the electric signal as a pixel signal.

In the semiconductor layer 31, an inter-pixel separation part 21 that electrically separates pixels 3 that are adjacent to each other from each other is disposed. The inter-pixel separation part 21, for example, is has a trench structure formed through an etching process and extends in a thickness direction of the semiconductor layer 31, that is, a direction denoted by arrow Z in FIG. 48. The inter-pixel separation part 21 prevents light incident on a pixel 3 from entering an adjacent pixel 3. Inside the inter-pixel separation part 21, an n-type region 21b made of polysilicon or the like, and an insulating film 21d interposed between the n-type region 21b and the p-well 312 are disposed.

The n-type layer 311 and the p-well 312 are electrically connected to the metal wiring 321 in the wiring layer 32. In this example, the wiring layer 32 is formed on a semiconductor supporting substrate not shown in the drawing. Typically, the wiring layer 32 is configured by stacking a plurality of layers of metal wirings 321 with interlayer insulating films interposed therebetween. The stacked metal wirings 321 are electrically connected, for example, using vias. The wiring layer 32, for example, is formed using metals such as aluminum (Al), copper (Cu), or the like. On the other hand, the interlayer insulating film is formed of silicon oxide or the like, for example.

The planarization film 33 planarizes a surface of the first surface S1 side of the semiconductor layer 31. A light shielding film 331 is formed in the planarization film 33. The light shielding film 331 is formed in a desired area on the planarization film 33 and is formed in a lattice shape so as to open the photodiode PD. In other words, the light shielding film 331 is formed at a position overlapping the inter-pixel separation part 21 in the plan view. The material composing the light shielding film 331 may be any material that shields light, and, for example, tungsten (W), aluminum (Al) or copper (Cu) may be used.

A gate electrode 1001 is arranged on the second surface S2 side of the inter-pixel separation part 21. In the gate electrode 1001, a contact structure part 36 electrically connected to the metal wiring 321 of the wiring layer 32 is arranged. The gate electrode 1001 is connected to the pixel drive line 10 via the contact structure part 36 and the metal wiring 321, and a drive signal for controlling the pixel transistor is supplied from the vertical drive circuit 4.

The contact structure part 36 shields light transmitted through the n-type layer 311 of the semiconductor layer 31. In the present disclosure, the contact structure part 36 is formed between the semiconductor layer 31 and the wiring layer 32. In accordance with such a configuration, light transmitted through the photodiode PD, that is, the n-type layer 311 is shielded by the contact structure part 36 to prevent the light from entering adjacent photodiodes PD, that is, the n-type layer 311. A material composing the contact structure part 36 may be any material that shields light, and, for example, tungsten (W), aluminum (Al), or copper (Cu) may be used.

### Function and Effect According to 34th Embodiment

As described above, according to the 34th embodiment, by forming the gate electrode 1001 of the pixel transistor across the upper surface part of the inter-pixel separation part 21, even if the pixel 3 is miniaturized, a space for arranging the pixel transistor can be secured, the contact structure part 36 is electrically connected between the gate electrode 1001 and the metal wiring 321 of the wiring layer 32, thus light transmitted through the pixels 3a of the semiconductor layer 31 is shielded by the contact structure part 36, and accordingly, the occurrence of color mixture due to the entry of light into the adjacent pixels 3b, 3c, and 3d can be prevented, whereby the contact resistance for the metal wiring 321 can be further reduced.

Furthermore, according to the 34th embodiment, since the contact structure part 36 has the structure having the linear part 36a along the row direction of the inter-pixel separation part 21-1 and the linear part 36b intersecting with the linear part 36a and formed along the column direction of the inter-pixel separation part 21-2, light transmitted through one pixel 3a of the four pixels 3a, 3b, 3c, 3d adjacent to each other via the inter-pixel separation parts 21-1, 21-2 can be shielded by the contact structure part 36, and, in accordance with this, the occurrence of color mixture due to the entry of light into the three adjacent pixels 3b, 3c, and 3d can be suppressed. The contact structure part 36 may have a structure in which a double linear part described below and dots are aligned in addition to the linear parts 36a and 36b or the like.

### First Modified Example of 34th Embodiment

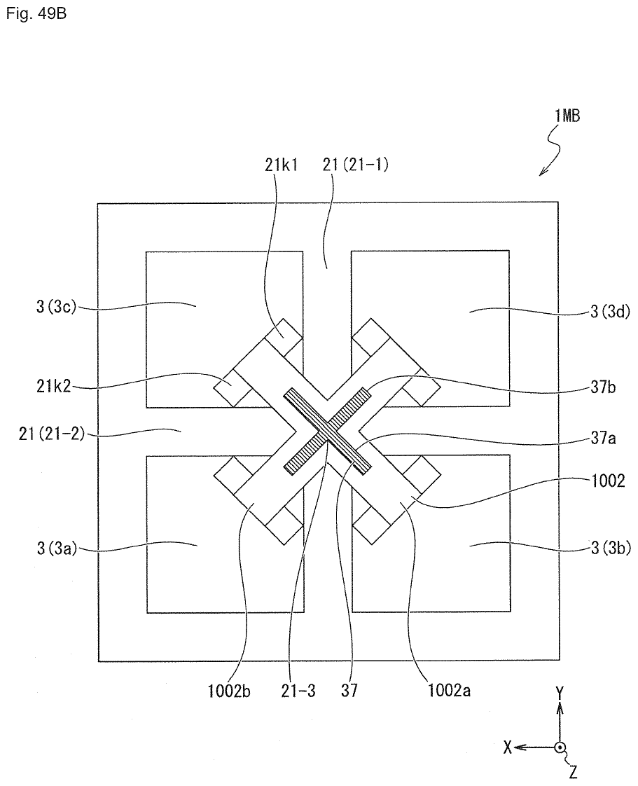

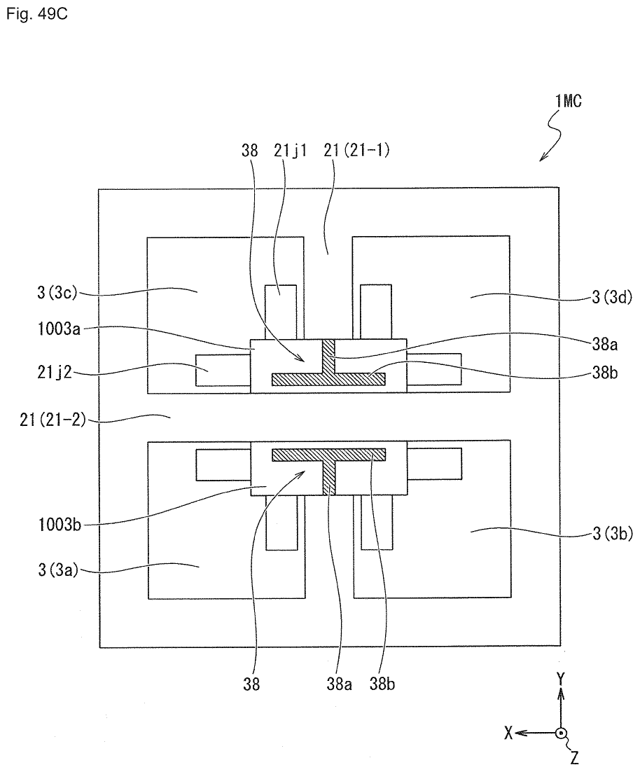

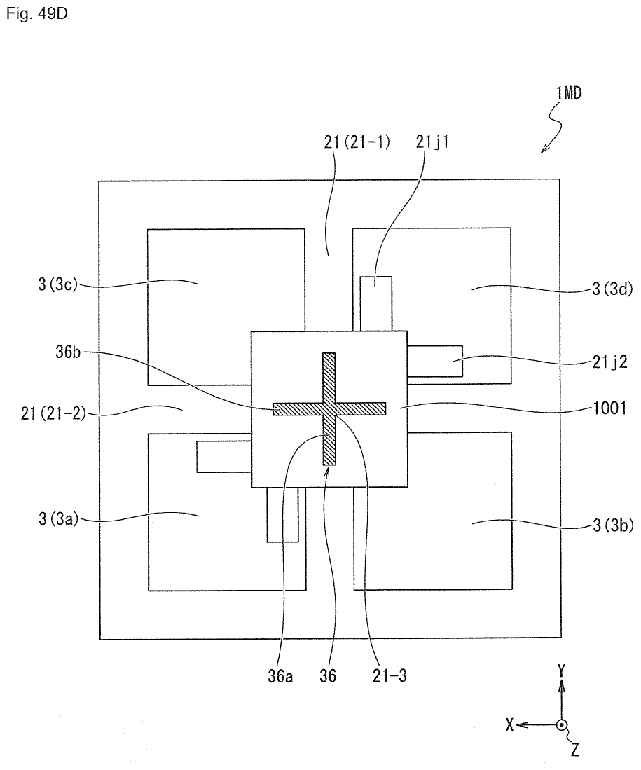

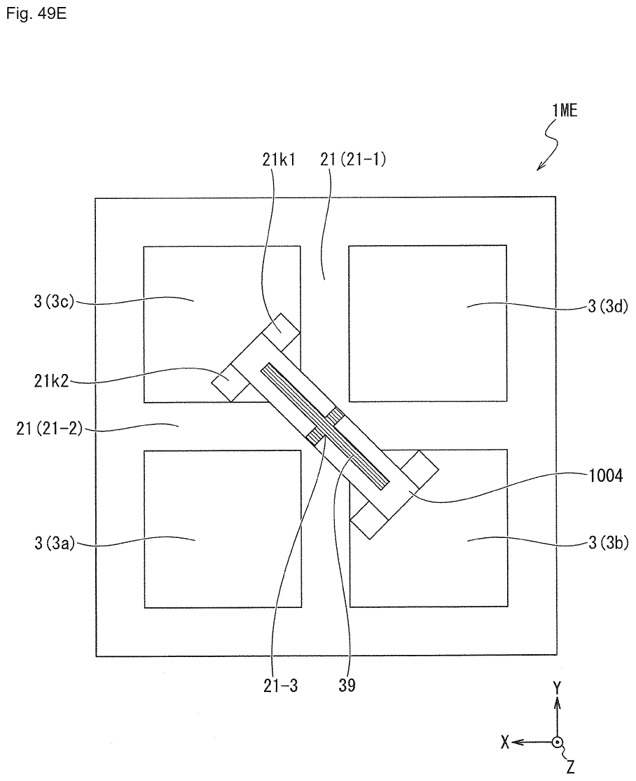

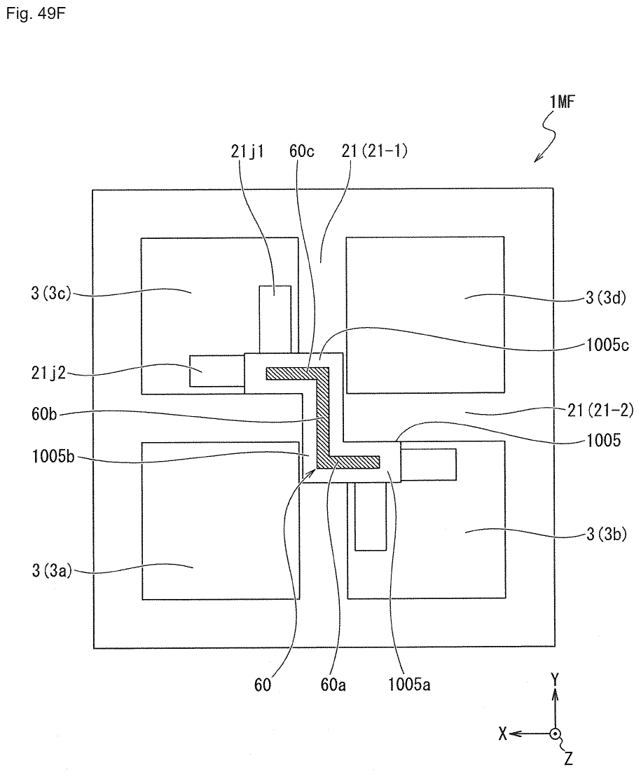

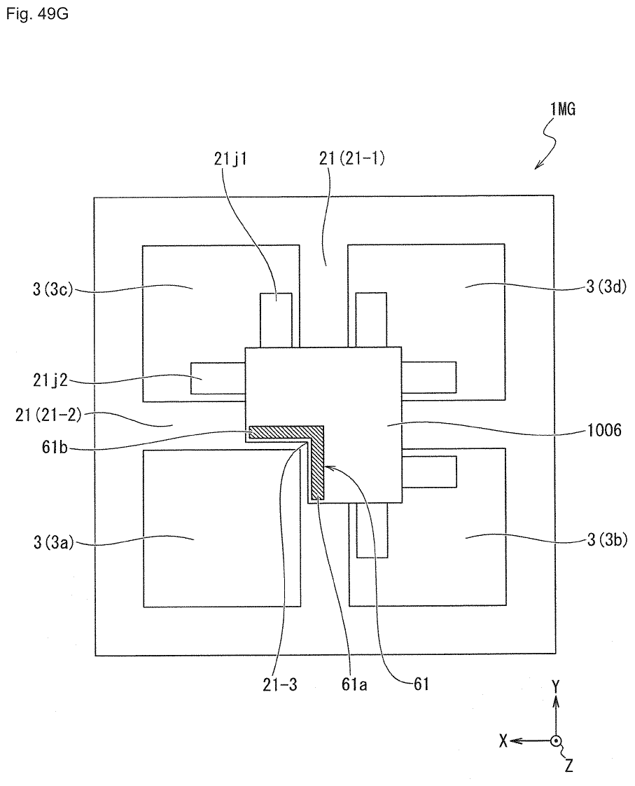

FIG. 49A is a plan view schematically illustrating a configuration example of a pixel block included in a pixel array unit of a light detection device 1MA according to a first modified example of a 34th embodiment of the present technique. In FIG. 49A, the same parts as those in FIG. 47 are denoted with the same reference signs, and detailed descriptions thereof will not be provided.

In FIG. 49A, a gate electrode 1002 of a pixel transistor integrally forms a first part 1002a crossing pixels 3b and 3c positioned at diagonal positions across an upper surface part of an intersection portion 21-3 in the plan view (XY plane) and a second part 1002b crossing pixels 3a and dc positioned at diagonal positions across the upper surface part of the intersection portion 21-3.

In the gate electrode 1002, a contact structure part 37 connected to the metal wiring 321 of the wiring layer 32 is arranged. The contact structure part 37 has a linear part 37a (an example of a first shape pattern part) along a direction in which the first part 1002a of the gate electrode 1002 crosses, and the pixels 3b and 3c are connected and a linear part 37b (an example of a second shape pattern part) formed along a direction in which the second part 1002b of the gate electrode 1002 crosses, and the pixels 3b and 3c are connected.

### Function and Effect According to First Modified Example of 34th Embodiment

According to the first modified example of the 34th embodiment, since the contact structure part 37 is arranged to intersect along the shape of the gate electrode 1002, light transmitted through one pixel 3a among the four pixels 3a, 3b, 3c, and 3d adjacent to each other via the inter-pixel separation part 21 can be shielded by the contact structure part 37, and, in accordance with this, the occurrence of color mixture due to entry of light to the adjacent three pixels 3b, 3c, and 3d can be suppressed.

### Second Modified Example of 34th Embodiment

FIG. 49B is a plan view schematically illustrating a configuration example of a pixel block included in a pixel array unit of a light detection device 1MB according to a second modified example of the 34th embodiment of the present technique. In FIG. 49B, the same parts as those in FIG. 49A are denoted with the same reference signs, and detailed descriptions thereof will not be provided.

A difference from the first modified example is that a source region 21k1 and a drain region 21k2 are disposed along a direction orthogonal to the extending direction of the first part 1002a of the gate electrode 1002 in the pixels 3b and 3c. In addition, a difference from the first modified example is that a source region 21k1 and a drain region 21k2 are disposed along a direction orthogonal to the extending direction of the second part 1002b of the gate electrode 1002 in the pixels 3a and 3d.

functions and Effect According to Second Modified Example of 34th Embodiment

According to the second modified example of the 34th embodiment, functions and effects that are similar to those of the previous first modified example can be acquired.

### Third Modified Example of 34th Embodiment

FIG. 49C is a plan view schematically illustrating a configuration example of a pixel block included in a pixel array unit of a light detection device 1MC according to a third modified example of the 34th embodiment of the present technique. In FIG. 49C, the same parts as those in FIG. 47 are denoted with the same reference signs, and detailed descriptions thereof will not be provided.

In FIG. 49C, a gate electrode 1003a of a pixel transistor crosses two adjacent pixels 3c and 3d across an upper surface part of the inter-pixel separation part 21-1 extending in the row direction (a direction denoted by arrow Y in FIG. 49C) in the plan view (XY plane). A gate electrode 1003b of the pixel transistor crosses two adjacent pixels 3a and 3b across an upper surface part of the inter-pixel separation part 21-1 extending in the row direction in the plan view (XY plane).

In the gate electrode 1003a, a contact structure part 38 connected to a metal wiring 321 of a wiring layer 32 is arranged. The contact structure part 38 has a linear part 38a (an example of a first shape pattern part) formed along the row direction of an inter-pixel separation part 21-1 and a linear part 38b (an example of a second shape pattern part) that intersects with the linear part 38a and is formed along the column direction of an inter-pixel separation part 21-2. Similarly, in a gate electrode 1003b, a contact structure part 38 connected to the metal wiring 321 of the wiring layer 32 is arranged. In addition, in each of the pixels 3a, 3b, 3c, and 3d, a source region 21j1 formed along the row direction of the inter-pixel separation part 21-1 and a drain region 21j2 formed along the column direction of the inter-pixel separation part 21-2 are disposed.

### Function and Effect According to Third Modified Example of 34th Embodiment

According to the third modified example of the 34th embodiment, functions and effects that are similar to those of the previous 34th embodiment can be acquired.

### Fourth Modified Example of 34th Embodiment

FIG. 49D is a plan view schematically illustrating a configuration example of a pixel block included in a pixel array unit of a light detection device 1MD according to a fourth modified example of the 34th embodiment of the present technique. In FIG. 49D, the same parts as those in FIG. 47 are denoted with the same reference signs, and detailed descriptions thereof will not be provided.

In FIG. 49D, a difference from FIG. 47 is that a source region 21j1 formed along the row direction of the inter-pixel separation part 21-1 and a drain region 21j2 formed along the column direction of the inter-pixel separation part 21-2 are provided only in two pixels 3a and 3d. Also according to the fourth modified example of the 34th embodiment, functions and effects that are similar to those of the previous 34th embodiment can be acquired.

### Fifth Modified Example of 34th Embodiment

FIG. 49E is a plan view schematically illustrating a configuration example of a pixel block included in a pixel array unit of a light detection device 1ME according to a fifth modified example of the 34th embodiment of the present technique. In FIG. 49E, the same parts as those in FIG. 49B are denoted with the same reference signs, and detailed descriptions thereof will not be provided.

In FIG. 49E, a difference from FIG. 49B is that a source region 21k1 and a drain region 21k2 are provided only in two pixels 3b and 3c. In FIG. 49E, a gate electrode 1004 of a pixel transistor crosses pixels 3b and 3c located at diagonal positions across an upper surface part of an intersection portion 21-3 in the plan view (XY plane).

In the gate electrode 1004, a contact structure part 39 connected to the metal wiring 321 of the wiring layer 32 is arranged. The contact structure part 39 has a linear part that is crossed by the gate electrode 1004 and is formed along a direction in which the pixel 3b and the pixel 3c are connected. Also according to the fifth modified example of the 34th embodiment, functions and effects that are similar to those of the previous 34th embodiment can be acquired.

### Sixth Modified Example of 34th Embodiment

FIG. 49F is a plan view schematically illustrating a configuration example of a pixel block included in a pixel array unit of a light detection device 1MF according to a sixth modified example of the 34th embodiment of the present technique. In FIG. 49F, the same parts as those in FIG. 47 are denoted with the same reference signs, and detailed descriptions thereof will not be provided.

In FIG. 49F, a difference from FIG. 47 is that a source region 21j1 formed along the row direction of the inter-pixel separation part 21-1 and a drain region 21j2 formed along the column direction of the inter-pixel separation part 21-2 are provided only in two pixels 3b and 3c. In FIG. 49F, a gate electrode 1005 of the pixel transistor crosses the pixels 3b and 3c located at diagonal positions across the upper surface part of an intersection portion 21-3. In the gate electrode 1005, a first part 1005a along the direction connecting the pixel 3b and the inter-pixel separation part 21-1, a second part 1005b along the row direction of the inter-pixel separation part 21-1, and a third part 1005c along the direction connecting the pixel 3c and the inter-pixel separation part 21-1 are integrally formed.

In the gate electrode 1005, a contact structure part 60 connected to the metal wiring 321 of the wiring layer 32 is arranged. The contact structure part 60 has a first linear part 60a formed along a direction connecting the pixel 3b and the inter-pixel separation part 21-1 (a direction denoted by arrow X in FIG. 49F), a second linear part 60b that is orthogonally connected to the first linear part 60a and is formed along the row direction (a direction denoted by arrow Y in FIG. 49F) of the inter-pixel separation part 21-1, and a third linear part 60c that is orthogonally connected to the second linear part 60b and is formed along a direction (a direction denoted by arrow X in FIG. 49F) connecting the pixel 3c and the inter-pixel separation part 21-1.

<function and Effect According to Sixth Modified Example of 34th Embodiment

Also according to the sixth modified example of the 34th embodiment, functions and effects that are similar to those of the 34th embodiment can be acquired. In the sixth modified example of the 34th embodiment, the gate electrode 1005 may have a shape including a first part formed along a direction connecting the pixel 3b and the inter-pixel separation part 21-2, a second part formed along a column direction of the inter-pixel separation part 21-2, and a third part formed along a direction connecting the pixel 3c and the inter-pixel separation part 21-2. In this case, the contact structure part 60 has a first linear part 60a formed along a direction connecting the pixel 3b and the inter-pixel separation part 21-2 (a direction denoted by arrow Y in FIG. 49f), a second linear part 60b formed along the column direction of the inter-pixel separation part 21-2 (a direction denoted by arrow X in FIG. 49F), and a third linear part 60c formed along a direction connecting the pixel 3c and the inter-pixel separation part 21-1 (a direction denoted by arrow Y in FIG. 49F).

### Seventh Modified Example of 34th Embodiment

FIG. 49G is a plan view schematically illustrating a configuration example of a pixel block included in a pixel array unit of a light detection device 1MG according to a seventh modified example of the 34th embodiment of the present technique. In FIG. 49G, the same parts as those in FIG. 47 are denoted with the same reference signs, and detailed descriptions thereof will not be provided.

In FIG. 49G, a gate electrode 1006 of the pixel transistor crosses three adjacent pixels 3b, 3c, and 3d across an upper surface part of an intersection portion 21-3 at which an inter-pixel separation part 21-1 extending in a row direction (a direction denoted by arrow Y in FIG. 49G) in the plan view (XY plane) intersects with an inter-pixel separation part 21-2 extending in a column direction (a direction denoted by arrow X in FIG. 49G) in the plan view.

In the gate electrode 1006, a contact structure part 61 connected to the metal wiring 321 of the wiring layer 32 is arranged. The contact structure part 61 has a linear part 61a (an example of a first shape pattern part) formed along the row direction of the inter-pixel separation part 21-1 and a linear part 61b (an example of a second shape pattern part) that intersects with the linear part 61a and formed along the column direction of the inter-pixel separation part 21-2 and surrounds the pixel 3a. In addition, in each of the pixels 3b, 3c, and 3d, a source region 21j1 formed along the row direction of the inter-pixel separation part 21-1 and a drain region 21j2 formed along the column direction of the inter-pixel separation part 21-2 are disposed.

In the seventh modified example of the 34th embodiment of the present disclosure, a red color filter layer 34 is arranged in the pixel 3a. Then, the pixel 3a generates an amount of electric charge corresponding to the intensity of red light transmitted through the color filter layer 34, converts it into an electric signal, and outputs the electric signal as a pixel signal. In other words, the pixel 3a detects the wavelength of red light.

The red light transmitted through the pixel 3a is shielded by the contact structure part 61, in accordance with this, thereby the occurrence of color mixture due to the entry of the red light into the adjacent pixels 3b, 3c, and 3d can be suppressed, and the contact resistance for the metal wiring 321 can be reduced.

### Function and Effect According to Seventh Modified Example of 34th Embodiment

According to the seventh modified example of the 34th embodiment, by arranging the contact structure part 61 to surround the pixels 3a detecting the wavelength of the red light, the occurrence of color mixture due to the entry of the red light into the adjacent pixels 3b, 3c, and 3d can be reliably suppressed. In the seventh modified example of the 34th embodiment, the contact structure part 61 may be arranged to surround the pixel 3 detecting the wavelength of the near-infrared light (an example of the infrared region). Near-infrared light is easily transmitted through the n-type layer 311 having silicon (Si) as its main material and is easily reflected by the wiring layer 32 to cause color mixture. Thus, by surrounding the pixel 3 detecting the wavelength of the near-infrared light with the contact structure part 61, the occurrence of color mixture due to the entry of the near-infrared light into the adjacent pixels 3b, 3c, and 3d can be reliably suppressed.

### 35th Embodiment

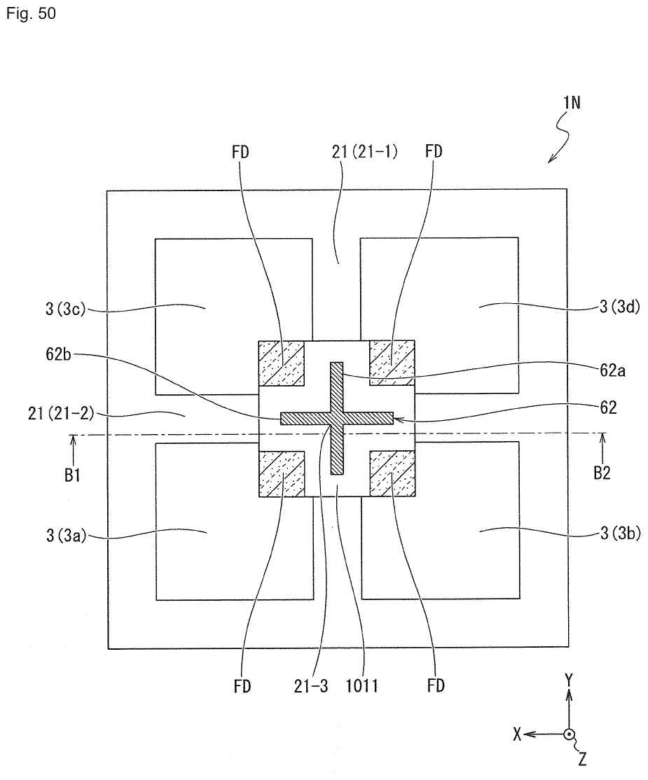

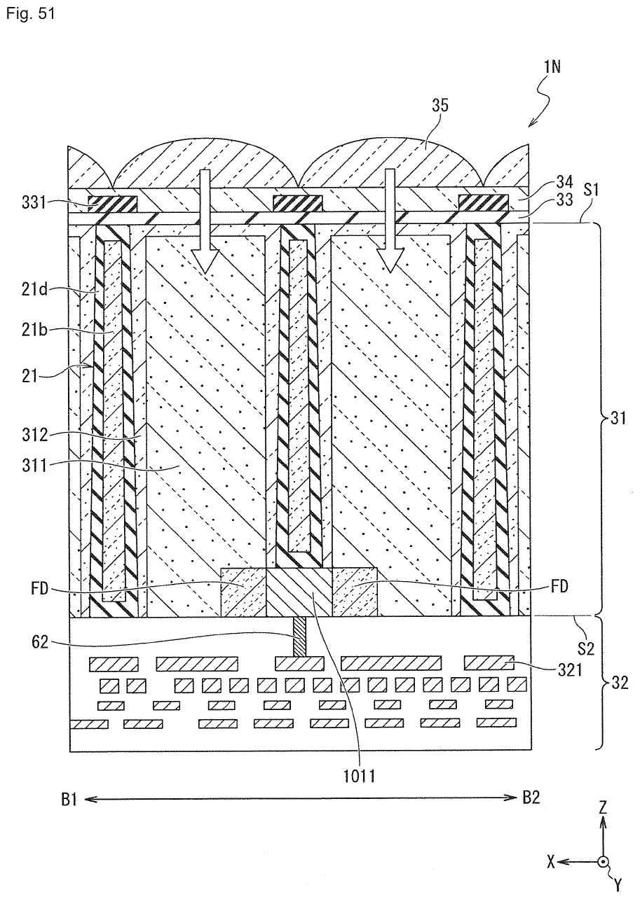

FIG. 50 is a plan view schematically illustrating a configuration example of a pixel block included in a pixel array unit of a light detection device 1N according to a 35th embodiment of the present technique. In FIG. 50, the same parts as those in FIG. 47 are denoted with the same reference signs, and detailed descriptions thereof will not be provided. FIG. 51 is a partial longitudinal cross-sectional view illustrating an example of a semiconductor structure of a pixel 3 illustrated in FIG. 50 on a B1-B2 cross-section. In FIG. 51, the same parts as those in FIG. 48 are denoted with the same characters, and detailed description thereof will not be provided.

In FIG. 50, a side contact part 1011 is arranged in an upper surface part of an intersection portion 21-3 at which an inter-pixel separation part 21-1 extending in a row direction (a direction denoted by arrow Y in FIG. 50) in the plan view (XY plane) intersects with an inter-pixel separation part 21-2 extending in a column direction (a direction denoted by arrow X in FIG. 50) in the plan view. The side contact part 1011 is formed by etching into the inter-pixel separation part 21 and causes the four pixels 3a, 3b, 3c, and 3d to be conductive via the intersection portion 21-3. The gate electrode 1001 of the pixel transistor is arranged on the upper surface of an intersection portion other than the intersection portion 21-3.

In the intersection portion 21-3 of the inter-pixel separation part 21, floating diffusions FD of the four pixels 3a, 3b, 3c, and 3d are arranged. In other words, the side contact part 1011 causes the floating diffusion FD of each of the pixels 3a, 3b, 3c, and 3d to be conductive.

In the side contact part 1011, a contact structure part 62 connected to the metal wiring 321 of the wiring layer 32 is arranged. The contact structure part 62 has a linear part 62a (an example of a first shape pattern part) formed along the row direction of the inter-pixel separation part 21-1 (a direction denoted by arrow Y in FIG. 50) and a linear part 62b (an example of a second shape pattern part) that intersects with the linear part 62a and formed along the column direction of the inter-pixel separation part 21-2 (a direction denoted by arrow X in FIG. 50).

In FIG. 51, the contact structure part 62 shields light that has passed through the n-type layer 311 in the semiconductor layer 31. In accordance with such a configuration, the floating diffusions FD of the four pixels 3a, 3b, 3c, and 3d are concentrically arranged in the intersection portion 21-3 of the inter-pixel separation part 21, that is, the side contact part 1011, light transmitted through the photodiode PD, that is, the n-type layer 311 is shielded by the contact structure part 62, whereby unintended light entering the floating diffusions FD of the adjacent pixels 3a, 3b, 3c, and 3d can be reliably suppressed. In addition, in accordance with miniaturization of the pixel 3, each floating diffusion FD can be arranged more efficiently.

### Function and Effect According to 35th Embodiment

As described above, according to the 35th embodiment, since the side contact part 1011 is formed in the intersection portion 21-3 of the inter-pixel separation part 21 other than the gate electrode, and the contact structure part 62 is electrically connected between the side contact part 1011 and the metal wiring 321 of the wiring layer 32, by effectively using the inter-pixel separation part 21, the occurrence of color mixture due to the entry of light into adjacent pixels 3 can be suppressed, and the contact resistance for the metal wiring 321 can be reduced.

Furthermore, according to the 35th embodiment, by arranging the floating diffusions FD of the four pixels 3a, 3b, 3c, and 3d, which face each other on a diagonal line via the inter-pixel separation part 21, in the side contact part 1011 in a concentrated manner, unintended light entering the floating diffusions FD can be reliably suppressed by the contact structure part 62, and each floating diffusion FD can be arranged more efficiently in accordance with miniaturization of the pixels 3. Furthermore, since the floating diffusion FD of each of the four pixels 3a, 3b, 3c, and 3d can be connected to the metal wiring 321 of the wiring layer 32 by one contact structure part 62, the number of contact wirings for the pixel transistor can be reduced.

### First Modified Example of 35th Embodiment

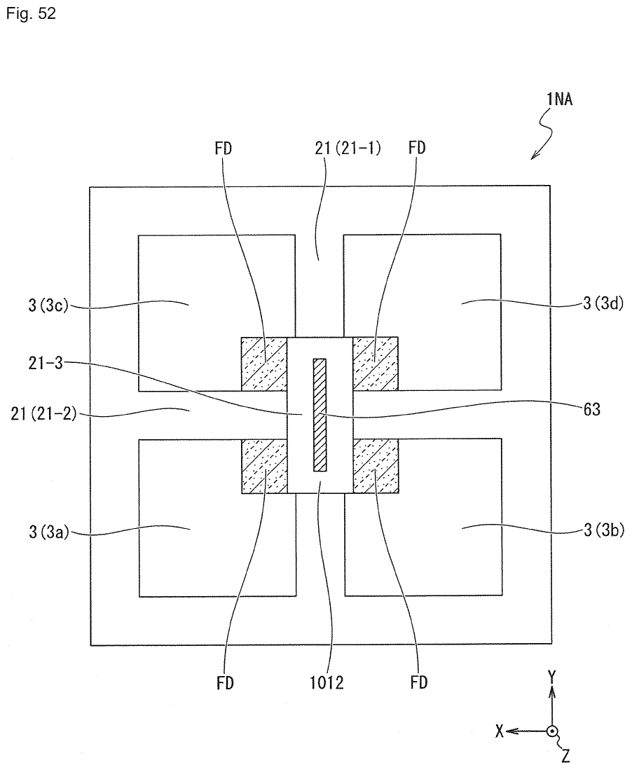

FIG. 52 is a plan view schematically illustrating a configuration example of a pixel block included in a pixel array unit of a light detection device 1NA according to a first modified example of the 35th embodiment of the present technique. In FIG. 52, the same parts as those in FIG. 50 are denoted with the same reference signs, and detailed descriptions thereof will not be provided.

In FIG. 52, a side contact part 1012 is formed only in an intersection portion 21-3 of an inter-pixel separation part 21-1 extending in a row direction (a direction denoted by arrow Y in FIG. 52). In the side contact part 1012, a contact structure part 63 connected to a metal wiring 321 of a wiring layer 32 is arranged. The contact structure part 63 has a linear part along the row direction (a direction denoted by arrow Y in FIG. 52).

### Function and Effect According to First Modified Example of 35th Embodiment

According to the first modified example of the 35th embodiment, functions and effects that are similar to f the preceding 35th embodiment can be acquired.

### Second Modified Example of 35th Embodiment

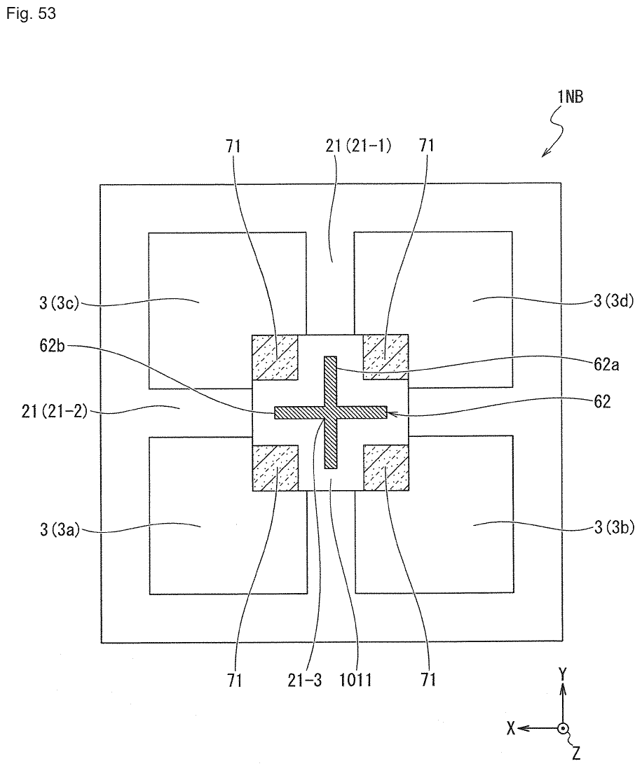

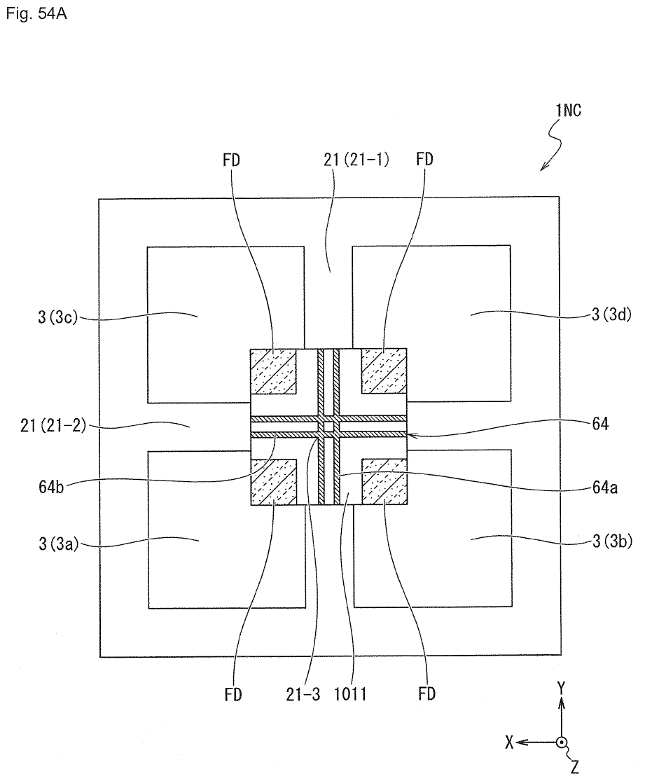

FIG. 53 is a plan view schematically illustrating a configuration example of a pixel block included in a pixel array unit of a light detection device 1NB according to a second modified example of the 35th embodiment of the present technique. In FIG. 53, the same parts as those in FIG. 50 are denoted with the same reference signs, and detailed descriptions thereof will not be provided.

In FIG. 53, a high concentration p-type layer 71, which is a contact part of a p-well 312 of each of four pixels 3a, 3b, 3c, and 3d, is arranged in an intersection portion 21-3 of an inter-pixel separation part 21. The high concentration p-type layer 71 is supplied with a reference potential, for example, the ground potential via a metal wiring 321, and the potential of the p-well 312, that is, the potential of the semiconductor layer 31 is set as the reference potential. In other words, the side contact part 1011 causes high concentration p-type layer 71 of the p-well 312 of each of the pixels 3a, 3b, 3c, and 3d to be conductive.

In accordance with such a configuration, the high concentration p-type layers 71 of the p-wells 312 of the four pixels 3a, 3b, 3c, and 3d are arranged concentrically in the intersection portion 21-3 of the inter-pixel separation part 21, that is, the side contact part 1011, light transmitted through the photodiode PD, that is, the n-type layer 311 is shielded by the contact structure part 62, and thus, unintended light entering the high concentration p-type layer 71 of the adjacent pixels 3a, 3b, 3c, and 3d can be reliably suppressed. Furthermore, in accordance with miniaturization of the pixels 3, the high concentration p-type layer 71 of each p-well 312 can be arranged more efficiently.

### Function and Effect According to Second Modified Example of 35th Embodiment

According to the second modified example of the 35th embodiment, by concentrically arranging the high concentration p-type layer 71 of the p-wells 312 of each of the four pixels 3a, 3b, 3c, and 3d, which face each other on a diagonal line via the inter-pixel separation part 21, in the intersection portion 21-3 of the inter-pixel separation part 21, the entry of unintended light into the high concentration p-type layer 71 of the p-well 312 can be reliably suppressed by the contact structure part 62, and thus, in accordance with miniaturization of the pixels 3, the high concentration p-type layer 71 of the p-wells 312 can be arranged more efficiently. Furthermore, since the high concentration p-type layer 71 of the p-well 312 of each of the four pixels 3a, 3b, 3c, and 3d can be connected to the metal wiring 321 of the wiring layer 32 by one contact structure part 62, the number of contact wirings for the pixel transistor can be also reduced.

Third modified example of 35th Embodiment

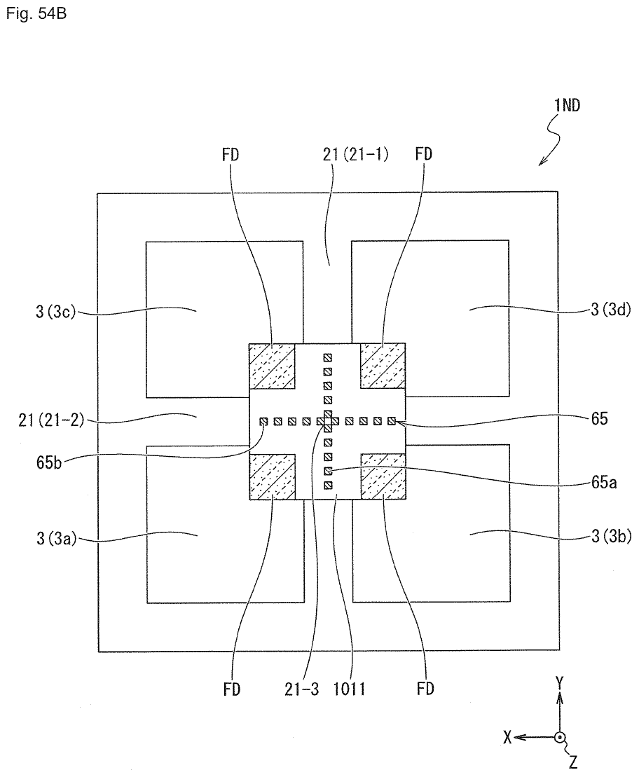

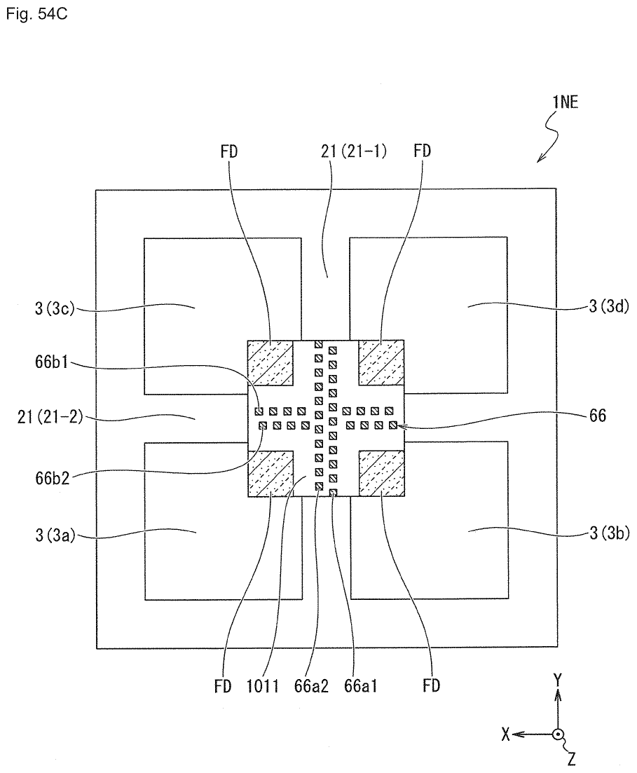

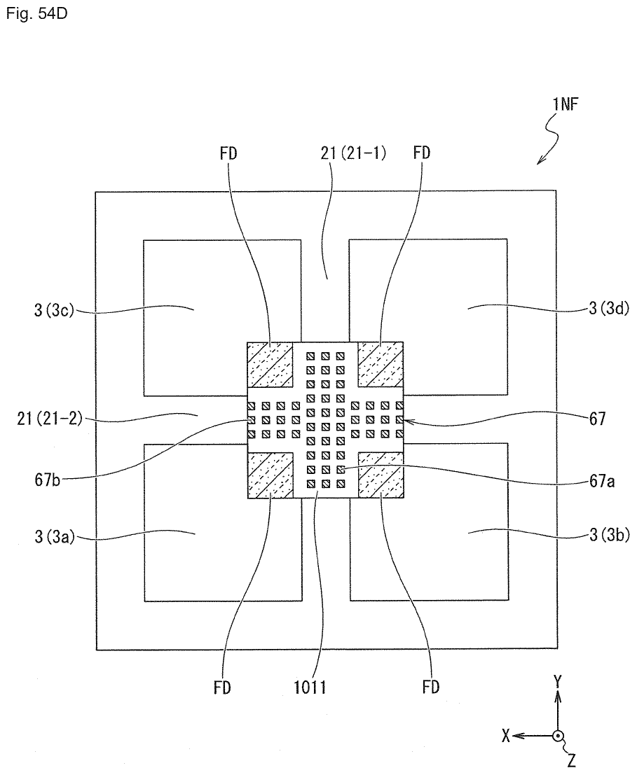

FIG. 54A is a plan view schematically illustrating a configuration example of a pixel block included in a pixel array unit of a light detection device 1NC according to a third modified example of the 35th embodiment of the present technique. In FIG. 54A, the same parts as those in FIG. 50 are denoted with the same reference signs, and detailed descriptions thereof will not be provided.

In FIG. 54A, a difference from FIG. 50 described above is that a contact structure part 64 using a double linear part is arranged in the side contact part 1011. The contact structure part 64 has a double linear part 64a formed along the row direction of an inter-pixel separation part 21-1 (the direction denoted by arrow Y in FIG. 54A) and a double linear part 64b that intersects with the double linear part 64a and is formed along the column direction of an inter-pixel separation part 21-2 (a direction denoted by arrow X in FIG. 54A). Also in the third modified example of the 35th embodiment, functions and effect that are similar to those of the previous 35th embodiment can be acquired, and stable connection to the metal wiring 321 of the wiring layer 32 can be achieved using the double linear parts 64a and 64b.

### Fourth Modified Example of 35th Embodiment

FIG. 54B is a plan view schematically illustrating a configuration example of a pixel block included in a pixel array unit of a light detection device 1ND according to a fourth modified example of the 35th embodiment of the present technique. In FIG. 54B, the same parts as those in FIG. 50 are denoted with the same reference signs, and detailed descriptions thereof will not be provided.

In FIG. 54B, a difference from FIG. 50 described above is that a contact structure part 65, in which a plurality of dots are arranged in one direction, is arranged in the side contact part 1011. The contact structure part 65 has a dot row 65a along the row direction of an inter-pixel separation part 21-1 (a direction denoted by arrow Y in FIG. 54B) and a dot row 65b that intersects with the dot row 65a and is formed along the column direction of an inter-pixel separation part 21-2 (a direction denoted by arrow X in FIG. 54B). Also in the fourth modified example of the 35th embodiment, functions and effects that are similar to those of the previous 35th embodiment can be acquired.

### Fifth Modified Example of 35th Embodiment

FIG. 54C is a plan view schematically illustrating a configuration example of a pixel block included in a pixel array unit of a light detection device 1NE according to a fifth modified example of the 35th embodiment of the present technique. In FIG. 54C, the same parts as those in FIG. 50 are denoted with the same reference signs, and detailed descriptions thereof will not be provided.

In FIG. 54C, a difference from FIG. 50 described above is that a contact structure part 66 in which a plurality of first dots and a plurality of second dots are aligned in one direction is arranged in the side contact part 1011. The contact structure part 66 has a first dot row 66a1 formed along the row direction of the inter-pixel separation part 21-1 (a direction denoted by arrow Y in FIG. 54C) and a second dot row 66a2 that is adjacent to the first dot row 66a1 and is formed along the row direction of the inter-pixel separation part 21-1 (a direction denoted by arrow Y in FIG. 54C). In addition, the contact structure part 66 has a first dot row 66b1 formed along the column direction of the inter-pixel separation part 21-2 (a direction denoted by arrow X in FIG. 54C) and a second dot row 66b2 that is adjacent to the first dot row 66b1 and is formed along the column direction of the inter-pixel separation part 21-1 (a direction denoted by arrow X in FIG. 54C).

One second dot of the second dot row 66a2 is located between two first dots of the first dot row 66a1. In addition, one second dot of the second dot row 66b2 is located between two first dots of the first dot row 66b1. In accordance with such a configuration, even when light transmitted through one pixel 3a among four pixels 3a, 3b, 3c, and 3d adjacent to each other via the inter-pixel separation parts 21-1 and 21-2 passes through a gap between two second dots of the second dot row 66a2, the light is shielded by the first dot of the first dot row 66a1. In addition, even when light transmitted through the pixel 3a passes through a gap between two second dots of the second dot row 66b2, the light is shielded by the first dot of the first dot row 66b1. Also according to the fifth modified example of the 35th embodiment, functions and effects that are similar to those of the previous 35th embodiment can be acquired.

### Sixth Modified Example of 35th Embodiment

FIG. 54D is a plan view schematically illustrating a configuration example of a pixel block included in a pixel array unit of a light detection device 1NF according to a sixth modified example of the 35th embodiment of the present technique. In FIG. 54D, the same parts as those in FIG. 50 are denoted with the same reference signs, and detailed descriptions thereof will not be provided.

In FIG. 54D, the difference from FIG. 50 is that a contact structure part 67, which is a structure in which a plurality of dots are densely arranged, is arranged in a side contact part 1011. The contact structure part 67 has a plurality of (three in FIG. 54D) dot rows 67a formed along the row direction of an inter-pixel separation part 21-1 (a direction denoted by arrow Y in FIG. 54D) and a dot row 67b1 formed along the column direction of an inter-pixel separation part 21-2 (a direction denoted by arrow X in FIG. 54D). Also according to the sixth modified example of the 35th embodiment, functions and effects that are similar to those of the previous 35th embodiment can be acquired.

### 36th Embodiment

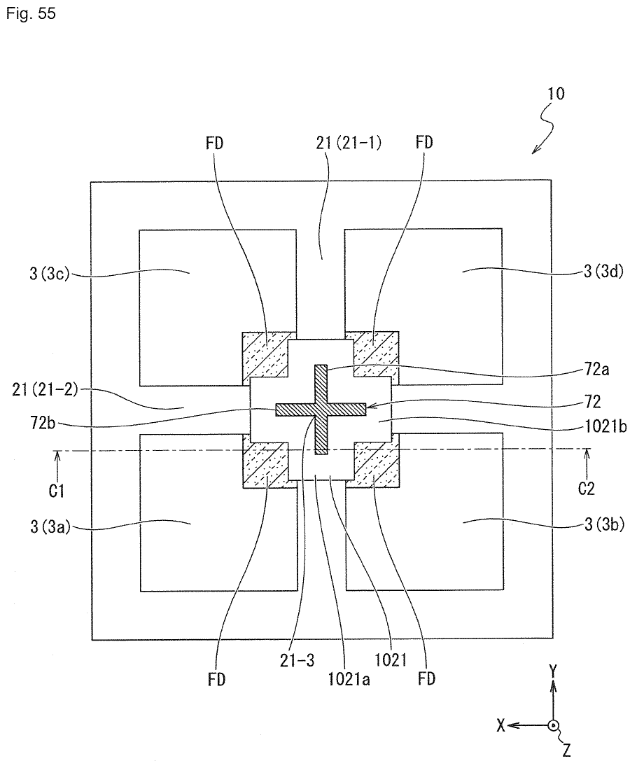

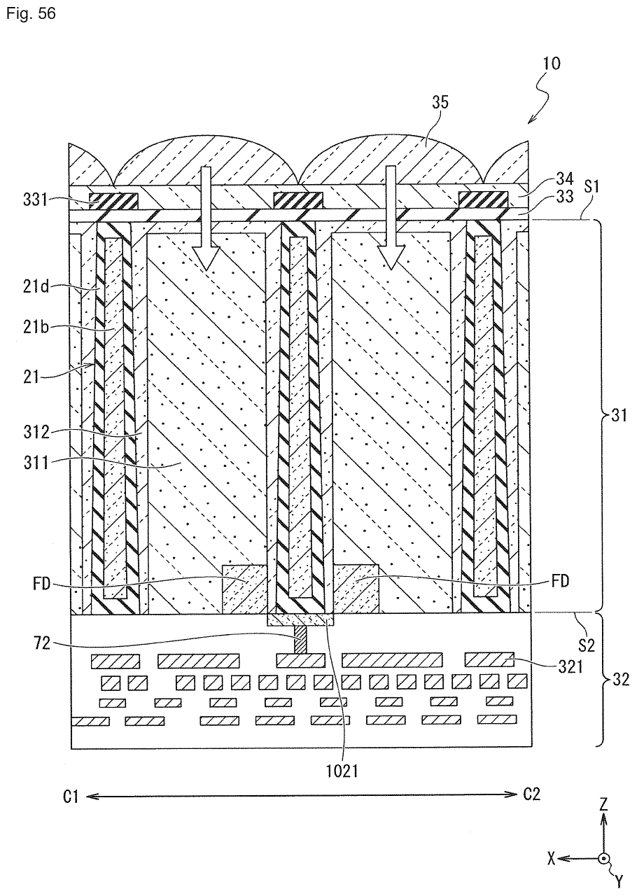

FIG. 55 is a plan view schematically illustrating a configuration example of a pixel block included in a pixel array unit of a light detection device 1O according to a 36th embodiment of the present technique. In FIG. 55, the same parts as those in FIG. 50 are denoted with the same reference signs, and detailed descriptions thereof will not be provided. FIG. 56 is a partial longitudinal cross-sectional view illustrating an example of a semiconductor structure of a pixel 3 on a C1-C2 cross-section illustrated in FIG. 55. In FIG. 56, the same parts as those in FIG. 48 are denoted with the same characters, and detailed description thereof will not be provided.

In FIG. 55, a difference from FIG. 50 described above is that a conduction structure part 1021 is arranged in an upper surface part of an intersection portion 21-3 at which an inter-pixel separation part 21-1 extending in the row direction (a direction denoted by arrow Y in FIG. 55) in the plan view (XY plane) intersects with an inter-pixel separation part 21-2 extending in the column direction (a direction denoted by X in FIG. 55) in the plan view. The conduction structure part 1021 conducts the four pixels 3a, 3b, 3c, 3d. The conduction structure part 1021 has a shape having a first part 1021a along the row direction of the inter-pixel separation part 21-1 (the direction shown by an arrow Y in FIG. 55) and a second part 1021b that intersects with the first part 1021a and is formed along the column direction of the inter-pixel separation part 21-2 (a direction denoted by arrow X in FIG. 55). A material composing the conduction structure part 1021, for example, may be any material that causes four pixels 3a, 3b, 3c, and 3d to be conductive, and for example, polysilicon or barrier metal may be used.

A floating diffusion FD of each of the four pixels 3a, 3b, 3c, and 3d is arranged in the intersection portion 21-3 of the inter-pixel separation part 21. In other words, the conduction structure part 1021 causes the floating diffusion FD of each of the pixels 3a, 3b, 3c, and 3d to be conductive.

In the conduction structure part 1021, a contact structure part 72 connected to the metal wiring 321 of the wiring layer 32 is arranged. The contact structure part 72 has a linear part 72a (an example of a first shape pattern part) formed along the row direction of the inter-pixel separation part 21-1 (a direction denoted by arrow Y in FIG. 55) and a linear part 72b (an example of a second shape pattern part) that intersects with the linear part 72a and is formed along the column direction of the inter-pixel separation part 21-2 (a direction denoted by arrow X in FIG. 55).

In FIG. 56, the contact structure part 72 shields light transmitted through the n-type layer 311 in the semiconductor layer 31. In accordance with such a configuration, the floating diffusion FD of each of the four pixels 3a, 3b, 3c, 3d is concentrically arranged in the intersection portion 21-3 of the inter-pixel separation part 21, and light transmitted through the photodiode PD, that is, the n-type layer 311 is shielded by the contact structure part 72, whereby unintended light entering into the floating diffusion FD of adjacent pixels 3a, 3b, 3c, and 3d can be reliably suppressed. Furthermore, in accordance with miniaturization of the pixels 3, each floating diffusion FD can be arranged more efficiently.

### Function and Effect According to 36th Embodiment

As described above, according to the 36th embodiment, functions and effects that are similar to those of the previous 35th embodiment can be acquired.

### First Modified Example Cation of 36th Embodiment

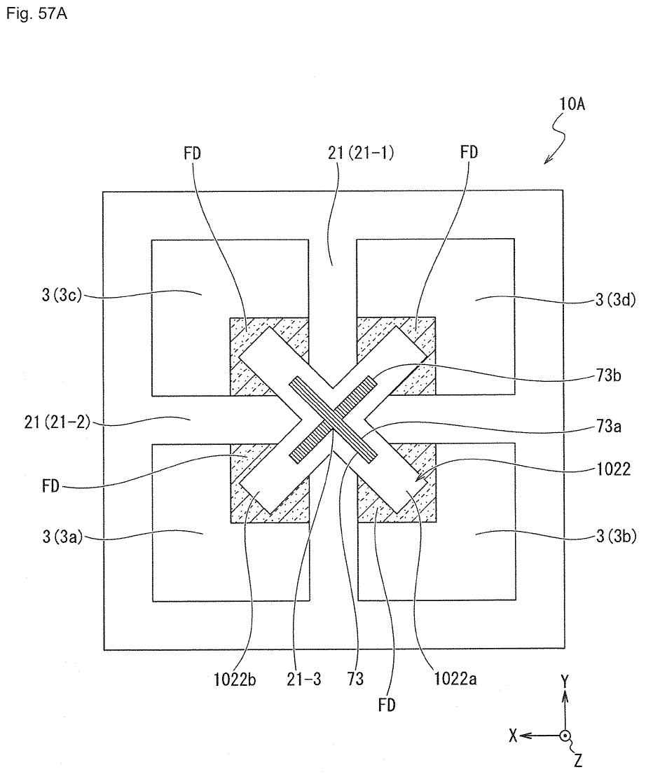

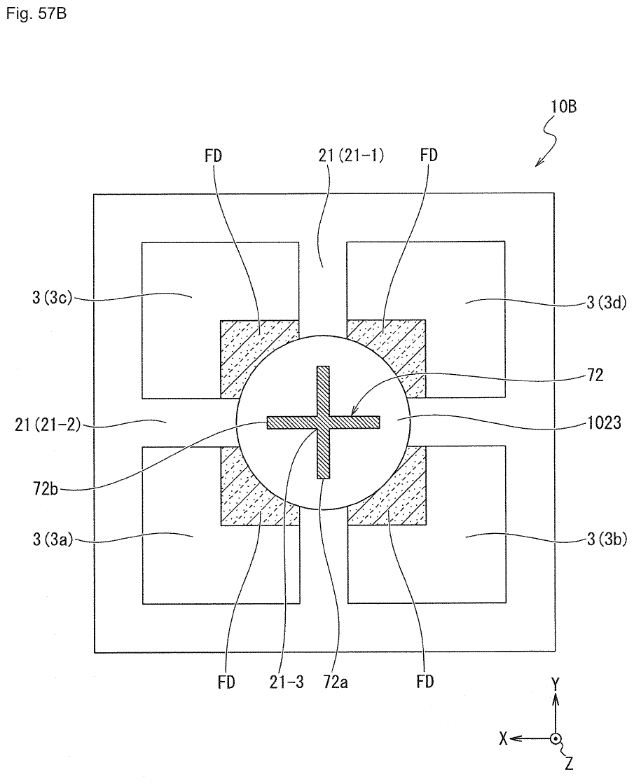

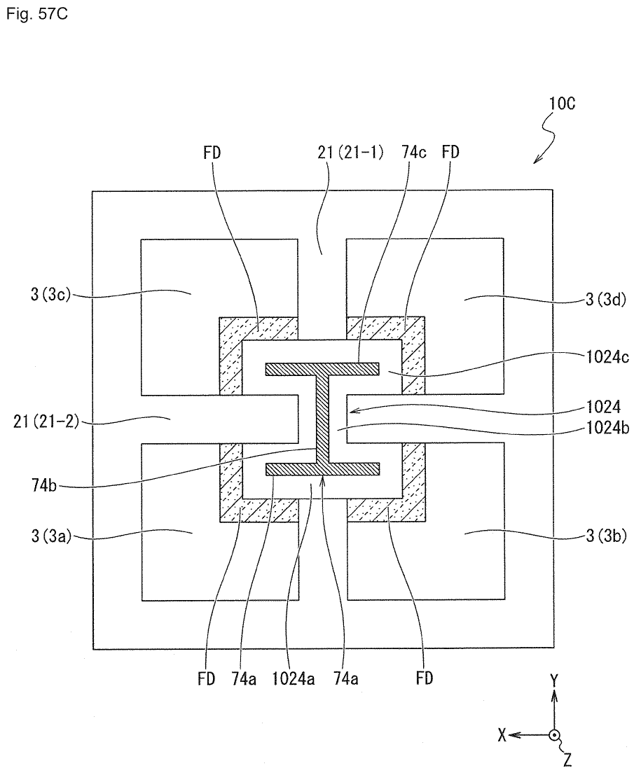

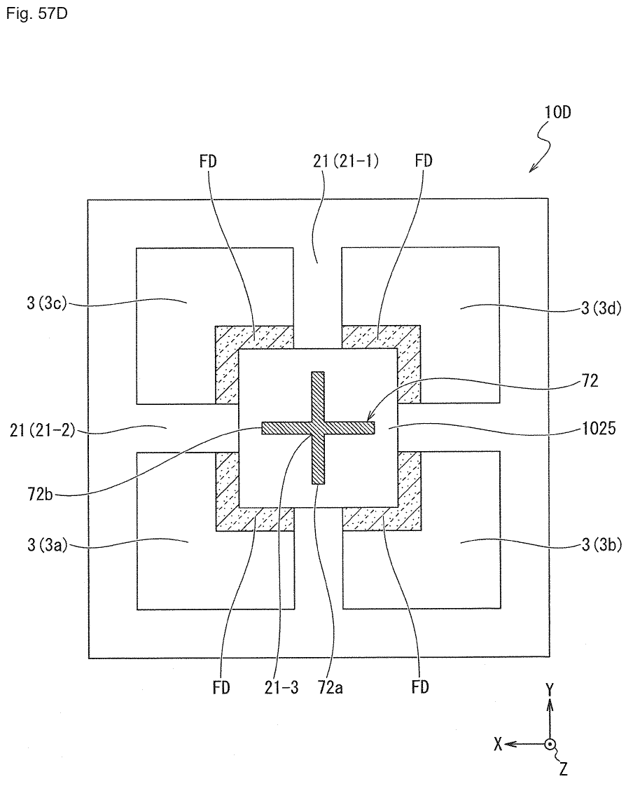

FIG. 57A is a plan view schematically illustrating a configuration example of a pixel block included in a pixel array unit of a light detection device 1OA according to a first modified example of the 36th embodiment of the present technique. In FIG. 57A, the same parts as those in FIG. 55 are denoted with the same reference signs, and detailed descriptions thereof will not be provided.

In FIG. 57A, in a conduction structure part 1022, a first part 1022a crossing a pixel 3b and a pixel 3c located at diagonal positions across an upper surface part of an intersection portion 21-3 in the plan view (XY plane) and a second part 1022b crossing a pixel 3a and a pixel dc located at diagonal positions across an upper surface part of the intersection portion 21-3 are integrally formed.

In the conduction structure part 1022, a contact structure part 73 connected to the metal wiring 321 of the wiring layer 32 is arranged. The contact structure part 73 has a linear part 73a (an example of a first shape pattern part) that is crossed by a first part 1022a of the conduction structure part 1022 and is formed along a direction a pixel 3b and a pixel 3c are connected and a linear part 73b (an example of a second shape pattern part) that is crossed by a second part 1022b of the conduction structure part 1022 and is formed along a direction in which the pixel 3b and the pixel 3c are connected. Also according to the first modified example of the 36th embodiment, functions and effects that are similar to those of the previous 36th embodiment can be acquired.

### Second Modified Example of 36th Embodiment

FIG. 57B is a plan view schematically illustrating a configuration example of a pixel block included in a pixel array unit of a light detection device 10B according to a second modified example of the 36th embodiment of the present technique. In FIG. 57B, the same parts as those in FIG. 55 are denoted with the same reference signs, and detailed descriptions thereof will not be provided.

In FIG. 57B, a conduction structure part 1023 has a circular shape in the plan view (XY plane) and crosses four pixels 3a, 3b, 3c, and 3d across an upper surface part of an intersection portion 21-3. In the conduction structure part 1023, a contact structure part 72 connected to the metal wiring 321 of the wiring layer 32 is arranged. Also according to the second modified example of the 36th embodiment, functions and effects that are similar to those of the previous 36th embodiment can be acquired.

### Third Modified Example of 36th Embodiment

FIG. 57C is a plan view schematically illustrating a configuration example of a pixel block included in a pixel array unit of a light detection device 1° C. according to a third modified example of the 36th embodiment of the present technique. In FIG. 57C, the same parts as those in FIG. 55 are denoted with the same reference signs, and detailed descriptions thereof will not be provided.

In FIG. 57C, in a conduction structure part 1024, a first part 1024a along a direction connecting a pixel 3a and a pixel 3b, a second part 1024b along the row direction (a direction denoted by arrow Y in FIG. 57C) of an inter-pixel separation part 21-1, and a third part 1024c along a direction for connecting a pixels 3c and a pixel 3d are integrally formed.

In the conduction structure part 1024, a contact structure part 74 connected to the metal wiring 321 of the wiring layer 32 is arranged. A contact structure part 74 has a first linear part 74a along a direction for connecting a pixel 3a and a pixel 3b (a direction denoted by arrow X in FIG. 57C), a second linear part 74b that is orthogonally connected to the first linear part 74a and is formed along the row direction of the inter-pixel separation part 21-1 (a direction denoted by Y in FIG. 57C), and a third linear part 74c that is orthogonally connected to the second linear part 74b and is formed along a direction for connecting a pixel 3c and a pixel 3d (a direction denoted by arrow X in FIG. 57C). Also according to the third modified example of the 36th embodiment, functions and effects that are similar to those of the previous 36th embodiment can be acquired.

Fourth modified example of 36th Embodiment

FIG. 57D is a plan view schematically illustrating a configuration example of a pixel block included in a pixel array unit of a light detection device 1OD according to a fourth modified example of the 36th embodiment of the present technique. In FIG. 57D, the same parts as those in FIG. 55 are denoted with the same reference signs, and detailed descriptions thereof will not be provided.

In FIG. 57D, a conduction structure part 1025 has a square shape in the plan view (XY plane) and crosses four pixels 3a, 3b, 3c, and 3d across an upper surface part of an intersection portion 21-3. In the conduction structure part 1025, a contact structure part 72 connected to the metal wiring 321 of the wiring layer 32 is arranged. Also according to the fourth modified example of the 36th embodiment, functions and effects that are similar to those of the previous 36th embodiment can be acquired.

### 37th Embodiment

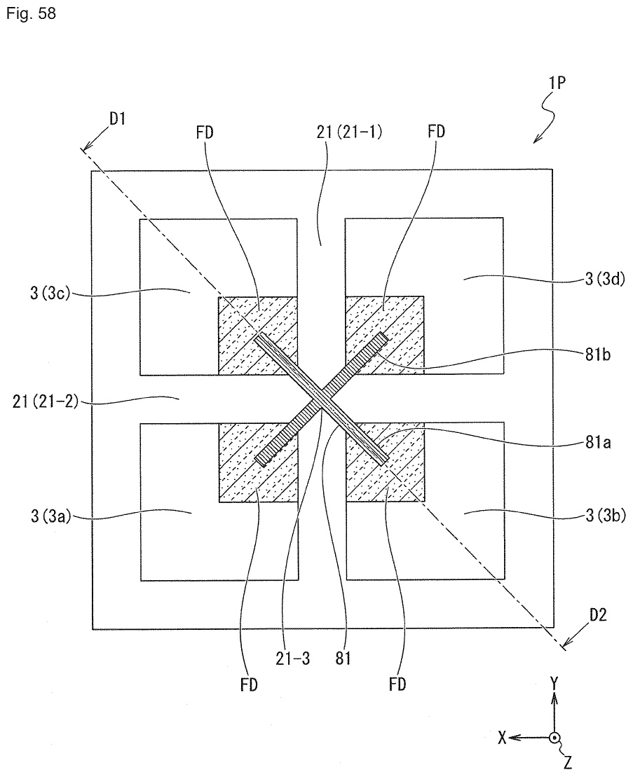

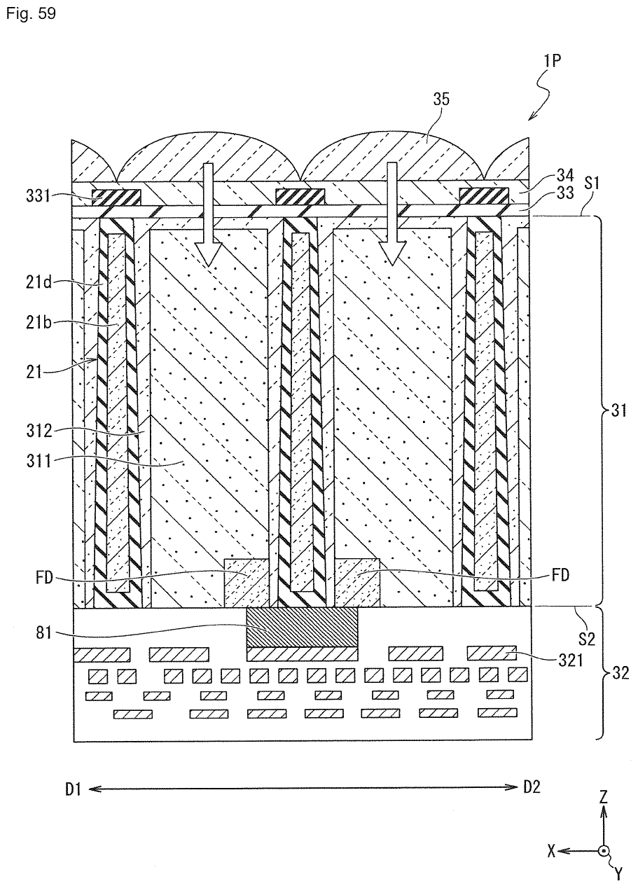

FIG. 58 is a plan view schematically illustrating a configuration example of a pixel block included in a pixel array unit of a light detection device 1P according to a 37th embodiment of the present technique. In FIG. 58, the same parts as those in FIG. 50 are denoted with the same reference signs, and detailed descriptions thereof will not be provided. FIG. 59 is a partial longitudinal cross-sectional view illustrating an example of a semiconductor structure of a pixel 3 on a D1-D2 cross-section illustrated in FIG. 58. In FIG. 59, the same parts as those in FIG. 56 are denoted with the same characters, and detailed description thereof will not be provided.

In FIG. 58, a difference from FIG. 50 described above is that a contact structure part 81 is directly arranged in an upper surface part of an intersection portion 21-3 at which an inter-pixel separation part 21-1 extending in the row direction (a direction denoted by arrow Y in FIG. 58) in the plan view (XY plane) intersects with an inter-pixel separation part 21-2 extending in the column direction (a direction denoted by arrow X in FIG. 58) in the plan view.

As shown in FIG. 59, the contact structure part 81 is connected to the metal wiring 321 of the wiring layer 32. The contact structure part 81 has a linear part 81a (an example of a first shape pattern part) formed along a direction for connecting a pixel 3b and a pixel 3c and a linear part 81b (an example of a second shape pattern part) formed along a direction for connecting the pixel 3b and the pixel 3c.

### Function and Effect According to 37th Embodiment

As described above, according to the 37th embodiment, functions and effects that are similar to those of the previous 35th and 36th embodiments can be acquired.

### 38th Embodiment

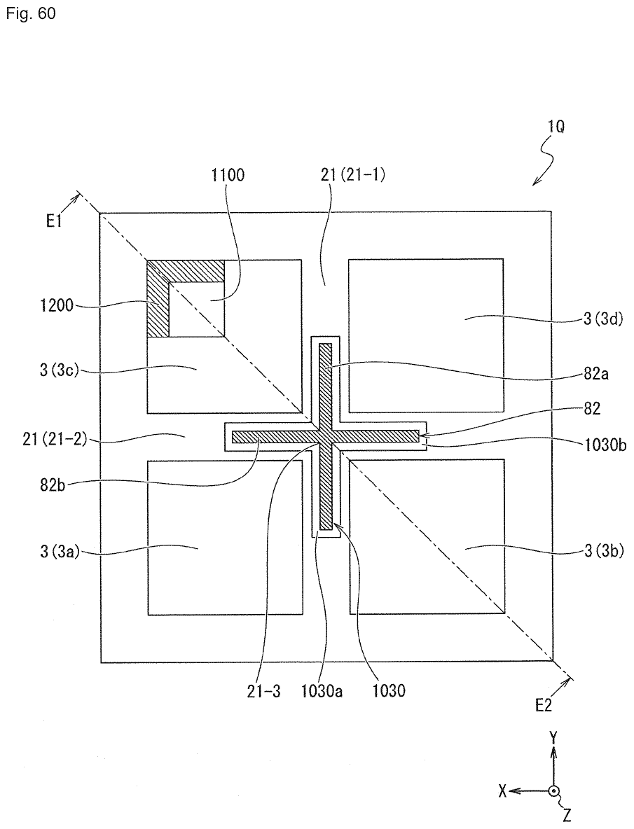

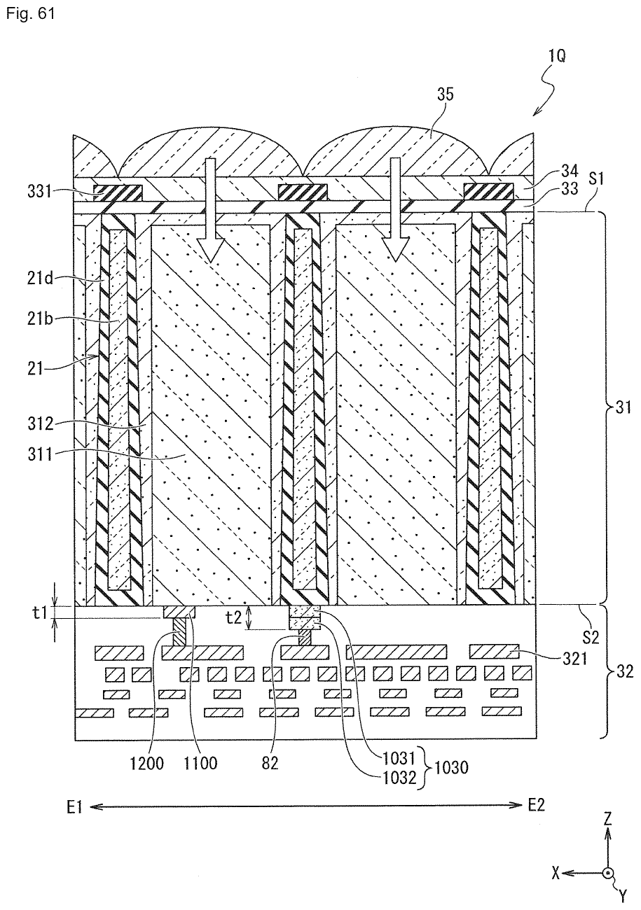

FIG. 60 is a plan view schematically illustrating a configuration example of a pixel block included in a pixel array unit of a light detection device 1Q according to a 38th embodiment of the present technique. In FIG. 60, the same parts as those in FIG. 50 are denoted with the same reference signs, and detailed descriptions thereof will not be provided. In addition, FIG. 61 is a partial longitudinal cross-sectional view illustrating an example of a semiconductor structure of a pixel 3 on an E1-E2 cross-section illustrated in FIG. 60. In FIG. 61, the same parts as those in FIG. 56 are denoted with the same characters, and detailed description thereof will not be provided.

In FIG. 60, a difference from FIG. 50 described above is that a dummy transistor 1030 is arranged in an upper surface part of an intersection portion 21-3 at which an inter-pixel separation part 21-1 extending in the row direction (a direction denoted by arrow Y in FIG. 60) in the plan view (XY plane) intersects with an inter-pixel separation part 21-2 extending in the column direction (a direction denoted by arrow X in FIG. 60) in the plan view. The dummy transistor 1030 has a semiconductor lamination structure made of polysilicon and is a transistor not to be driven. Polysilicon is advantageous for reflection or shielding of light.

The dummy transistor 1030 has a shape having a first part 1030a formed along the row direction (a direction denoted by arrow Y in FIG. 60) of the inter-pixel separation part 21-1 and a second part 1030b that intersects with the first part 1030a and is formed along the column direction (a direction denoted by arrow X in FIG. 60) of the inter-pixel separation part 21-2.

As shown in FIG. 61, in the dummy transistor 1030, a contact structure part 82 connected to the metal wiring 321 of the wiring layer 32 in arranged. The contact structure part 82 has a linear part 82a (an example of the first shape pattern part) formed along the row direction of the inter-pixel separation part 21-1 (a direction denoted by arrow Y in FIG. 60) and a linear part 82b (an example of the second shape pattern part) that intersects with the linear part 82a and formed along the column direction of the inter-pixel separation part 21-2 (a direction denoted by arrow X in FIG. 60).

The pixel transistor 1100 has a gate electrode having a height t1 in a direction protruding toward the wiring layer 32 (a direction denoted by arrow Z in FIG. 61). In the gate electrode of the pixel transistor 1100, a contact structure part 1200 connected to the metal wiring 321 of the wiring layer 32 is arranged. The gate electrode of the pixel transistor 1100 is connected to the pixel drive line 10 via the contact structure part 1200 and the metal wiring 321.

On the other hand, the dummy transistor 1030 is constituted by a first polysilicon laminated part 1031 and a second polysilicon laminated part 1032 laminated on the wiring layer 32 side of the first polysilicon laminated part 1031. In accordance with this, the dummy transistor 1030 has a height t2 higher than the height t1 of the pixel transistor 1100. In addition, by removing the second polysilicon laminated part 1032 from the first polysilicon laminated part 1031, the dummy transistor 1030 can match the height t1 of the pixel transistor 1100. Furthermore, by laminating the second polysilicon laminated part on the wiring layer 32 side of the second polysilicon laminated part 1032, the dummy transistor 1030 can be configured to be higher than the height t2.

In accordance with such a configuration, light transmitted through the photodiode PD, that is, the n-type layer 311 is shielded by the dummy transistor 1030 or the contact structure part 82, whereby entry of the light into the adjacent pixels 3a, 3b, 3c, and 3d can be reliably suppressed.

### Function and Effect According to 38th Embodiment

As described above, according to the 38th embodiment, by changing the height of the dummy transistor 1030 arranged in the intersection portion 21-3 of the inter-pixel separation part 21 with respect to the pixel transistor 1100 that is actually driven, a color mixture suppression effect can be increased.

### Modified Example of 38th Embodiment

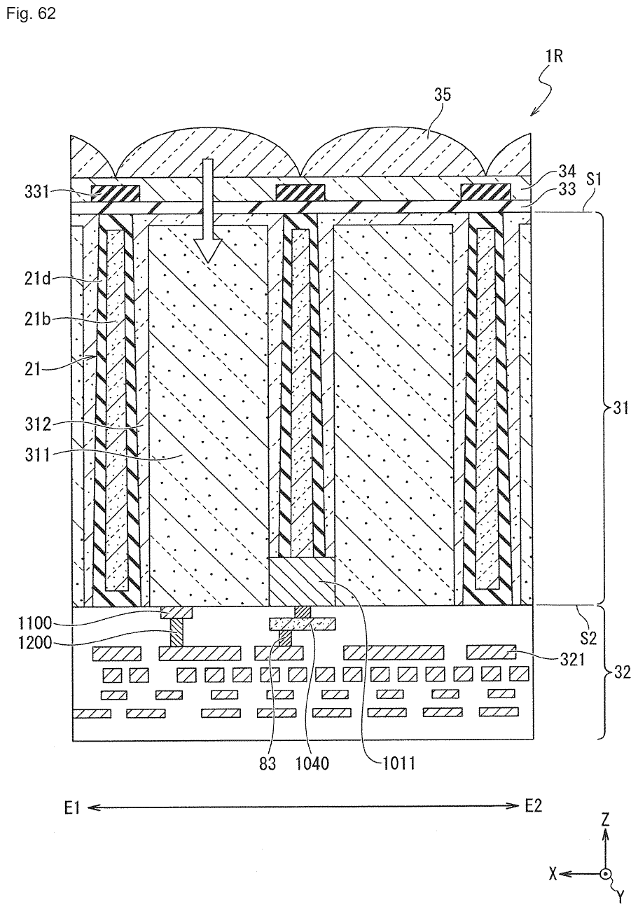

FIG. 62 is a partial longitudinal cross-sectional view illustrating an example of a semiconductor structure on a cross-section of a pixel 3 of a light detection device 1R according to a modified example of the 38th embodiment of the present technique. In FIG. 62, the same parts as those in FIG. 61 are denoted with the same reference signs, and detailed descriptions thereof will not be provided.

In FIG. 62, a difference from FIG. 61 is that a polysilicon wiring 1040 is connected to a side contact part 1011 formed in an intersection portion 21-3 of the inter-pixel separation part 21. In the polysilicon wiring 1040, a contact structure part 83 connected to the metal wiring 321 of the wiring layer 32 is arranged. In accordance with such a configuration, light transmitted through the photodiode PD, that is, the n-type layer 311 is shielded by the polysilicon wiring 1040 or the contact structure part 83, and thus the entry of the light into the adjacent pixels 3a, 3b, 3c, and 3d can be reliably suppressed.

### 39th Embodiment

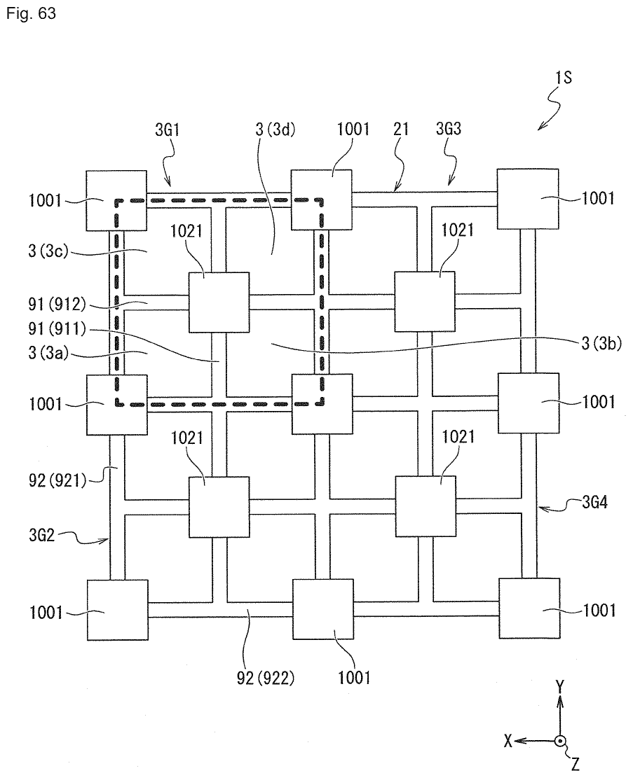

FIG. 63 is a plan view schematically illustrating a configuration example of a pixel block included in a pixel array unit of a light detection device 1S according to a 39th embodiment of the present technique. In FIG. 63, the same parts as those in FIGS. 47 and 55 are denoted with the same characters, and detailed description thereof will not be provided.

In FIG. 63, four pixels 3a, 3b, 3c, and 3d constitute a shared pixel group 3G1 (denoted by dotted lines in FIG. 63) sharing one conductive structure 1021. The inter-pixel separation part 21 has an intra-pixel group separation part 91 arranged between adjacent pixels 3a, 3b, 3c, and 3d in the shared pixel group 3G1 and an inter-pixel group separation part 92 arranged between shared pixel groups 3G2, 3G3, and 3G4 adjacent to the shared pixel group 3G1.

The conduction structure part 1021 is arranged in an upper surface part of an intersection portion at which the intra-pixel group separation part 911 extending in the row direction (a direction denoted by arrow Y in FIG. 63) intersects with the intra-pixel group separation part 912 extending in the column direction (a direction denoted by arrow X in FIG. 63). On the other hand, the gate electrode 1001 of the pixel transistor is arranged in the upper surface part of an intersection portion at which the inter-pixel group separation part 921 extending in the row direction (a direction denoted by arrow Y in FIG. 63) intersects with the inter-pixel-group separation part 922 extending in the column direction (a direction denoted by arrow X in FIG. 63).

### Function and Effect According to 39th Embodiment

As described above, according to the 39th embodiment, even when the miniaturization of the pixels 3 is applied, the conduction structure part 1021 and the gate electrode 1001 of the pixel transistor can be arranged more efficiently inside the shared pixel group 3G1.

### First Modified Example of 39th Embodiment

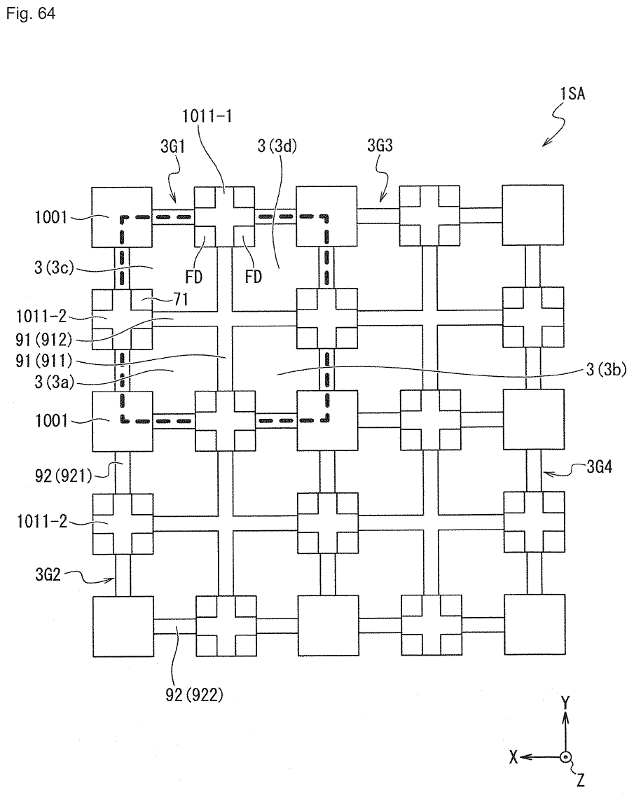

FIG. 64 is a plan view schematically illustrating a configuration example of a pixel block included in a pixel array unit of a light detection device 1SA according to a first modified example of the 39th embodiment of the present technique. In FIG. 64, the same parts as those in FIG. 63 are denoted with the same reference signs, and detailed descriptions thereof will not be provided.

In FIG. 64, a conduction structure part 1011-1 is arranged in an upper surface part of an intersection portion at which the intra-pixel group separation part 911 extending in the row direction (a direction denoted by arrow Y in FIG. 64) intersects with the inter-pixel group separation part 922 extending in the column direction (a direction denoted by arrow X in FIG. 64). A conduction structure part 1011-2 is arranged in an upper surface part of an intersection portion at which the intra-pixel group separation part 912 extending in the column direction (a direction denoted by arrow X in FIG. 64) intersects with the inter-pixel group separation part 921 extending in the row direction (a direction denoted by arrow Y in FIG. 64).

The conduction structure part 1011-1 causes the floating diffusion FD of each of the pixels 3a, 3b, 3c, and 3d to be conductive in the shared pixel group 3G1. In addition, the conduction structure part 1011-2 causes the high concentration p-type layer 71, which is a contact portion of the p-well 312 of each of the pixels 3a, 3b, 3c, and 3d to be conductive in the shared pixel group 3G1.

In this way, according to the first modified example of the 39th embodiment, functions and effects that are similar to those of the previous 39th embodiment can be acquired.

### Second Modified Example of 39th Embodiment

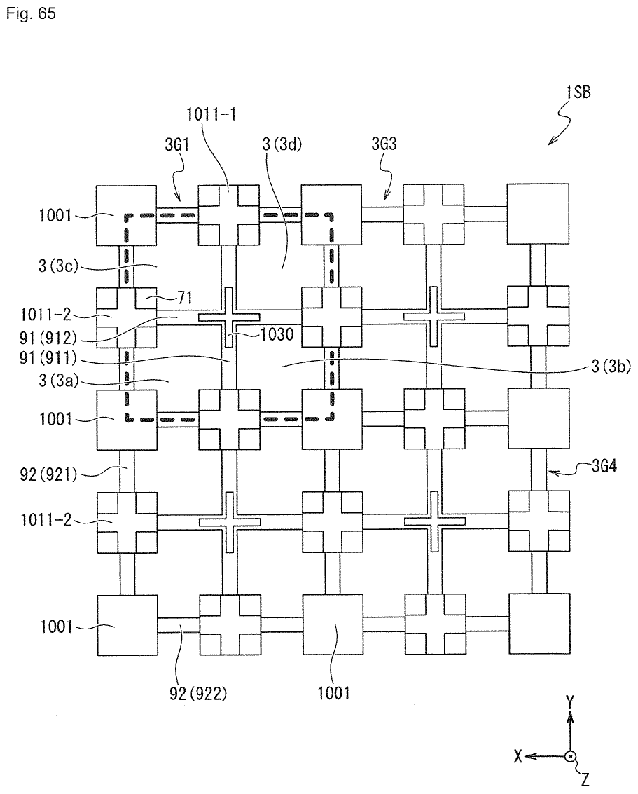

FIG. 65 is a plan view schematically illustrating a configuration example of a pixel block included in a pixel array unit of a light detection device 1SB according to a second modified example of the 39th embodiment of the present technique. In FIG. 65, the same parts as those in FIG. 64 are denoted with the same reference signs, and detailed descriptions thereof will not be provided.

In FIG. 65, a dummy transistor 1030 is arranged in an upper surface part of an intersection portion at which the intra-pixel group separation part 911 extending in the row direction (a direction denoted by arrow Y in FIG. 65) intersects with the intra-pixel group separation part 912 extending in the column direction (a direction denoted by arrow X in FIG. 65).

In this way, according to the second modified example of the 39th embodiment, functions and effects similar to those of the previous 39th embodiment can be acquired, and, by arranging the dummy transistor 1030 inside the shared pixel group 3G1, mixed color can be suppressed.

### Other Embodiments

As in the foregoing description, the present technique has been described with reference to the first to the 39th embodiments, but the description and drawings that form a part of the present disclosure should not be construed as limiting the present technique. When the gist of the disclosed technical content according to the first to 39th embodiments is understood, various alternative embodiments, examples, and operation technology that fall within the range of the present technique will be apparent to a person skilled in the art. The disclosed features according to the first to 39th embodiments may be combined as appropriate so that no contradictions arise. For example, the disclosed features according to multiple different embodiments may be combined and features according to multiple different modifications of the same embodiment may be combined.

Application example to Electronic Apparatus

The light detection devices described above can be used in various electronic devices, for example, an imaging device such as a digital still camera and a digital video camera, a cellular phone having an imaging function, or any other device having an imaging function.

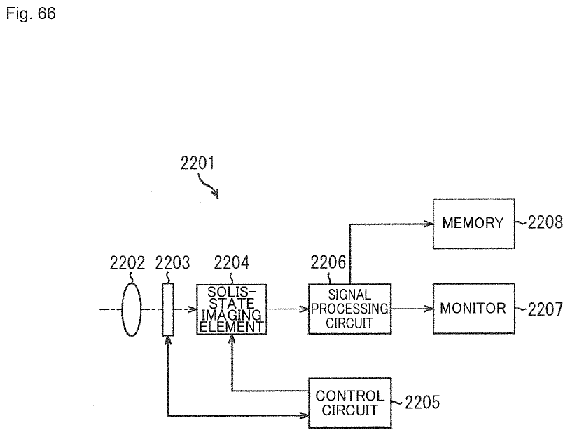

FIG. 66 is a block diagram showing a configuration example of an imaging device as an electronic device to which the present technique is applied.

The imaging device 2201 shown in FIG. 66 includes an optical system 2202, a shutter device 2203, a solid-state imaging element 2204 as a light detection device, a control circuit 2205, a signal processing circuit 2206, a monitor 2207, and two memories 2208, and the imaging device can capture still-images and moving images.

The optical system 2202 includes one or more lenses, and guides light (incident light) from an object to the solid-state imaging element 2204, and forms an image on the light receiving surface of the solid-state imaging element 2204.

The shutter device 2203 is arranged between the optical system 2202 and the solid-state imaging element 2204, and controls a light emission period and a light-blocking period for the solid-state imaging element 2204 according to the control of the control circuit 2205.

The solid-state imaging element 2204 includes a package including the above-described solid-state imaging element. The solid-state imaging element 2204 accumulates signal electric charge for a certain period of time according to the light imaged on the light-receiving surface via the optical system 2202 and the shutter device 2203. The signal electric charge accumulated in the solid-state imaging element 2204 is transferred in response to a drive signal (timing signal) supplied from the control circuit 2205.

The control circuit 2205 outputs a drive signal that controls the transfer operation of the solid-state imaging element 2204 and the shutter operation of the shutter device 2203, and drives the solid-state imaging element 2204 and the shutter device 2203.

The signal processing circuit 2206 performs various kinds of signal processing on the signal electric charge output from the solid-state imaging element 2204. An image (image data) obtained by the signal processing performed by the signal processing circuit 2206 is supplied to the monitor 2207 for display or supplied to the memory 2208 for storage (recording).

In the imaging device 2201 having the configuration, the light detection device 1A to 1L can be used instead of the above solid-state imaging element 2204.

### Application to Moving Body

The technique of the present disclosure (the present technique) can be applied to various products. For example, the technique according to the present disclosure may be implemented as a device equipped in any type of moving body such as an automobile, an electric vehicle, a hybrid electric vehicle, a motorcycle, a bicycle, a personal mobility device, an airplane, a drone, a ship, and a robot.

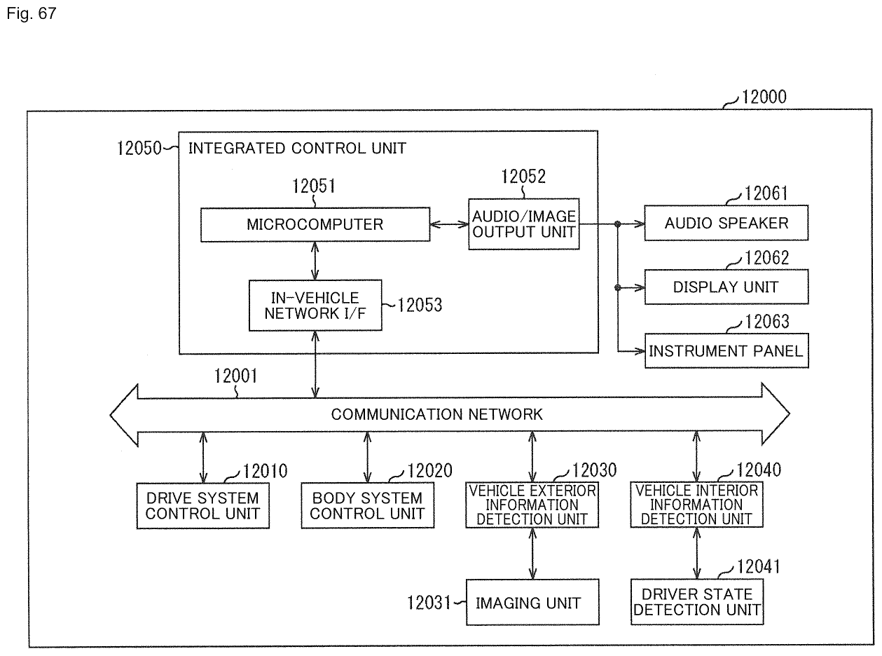

FIG. 67 is a block diagram illustrating a schematic configuration example of a vehicle control system, which is an example of a mobile control system to which the technique according to the present disclosure is applicable.

A vehicle control system 12000 includes a plurality of electronic control units connected thereto via a communication network 12001. In the example illustrated in FIG. 48, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio/image output unit 12052, and an in-vehicle network interface (I/F) 12053 are illustrated.

The drive system control unit 12010 controls the operation of a device related to a vehicle drive system according to various programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls the operations of various devices mounted in the vehicle body, according to various programs. For example, the body system control unit 12020 functions as control devices for a keyless entry system, a smart key system, power window devices, or various lamps such as head lights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the outside of the vehicle having the vehicle control system 12000 mounted thereon. For example, the vehicle exterior information detection unit 12030 is connected with an imaging unit 12031. The vehicle exterior information detection unit 12030 causes the imaging unit 12031 to capture an image of the exterior of the vehicle, and receives the captured image. The vehicle exterior information detection unit 12030 may perform object detection processing or distance detection processing for peoples, cars, obstacles, signs, and letters on the road based on the received image.

The imaging unit 12031 is an optical sensor that receives light and outputs an electrical signal according to the light reception amount of this light. The imaging unit 12031 can also output the electrical signal as an image or as distance measurement information. Furthermore, the light received by the imaging unit 12031 may be visible light or invisible light such as infrared light.

The vehicle interior information detection unit 12040 detects information on the inside of the vehicle. For example, a driver state detection unit 12041 that detects a state of a driver is connected to the vehicle interior information detection unit 12040. The driver state detection unit 12041 includes, for example, a camera that captures an image of a driver, and the vehicle interior information detection unit 12040 may calculate the degree of fatigue or concentration of the driver or may determine whether or not the driver is dozing on the basis of detection information inputted from the driver state detection unit 12041.

The microcomputer 12051 can calculate a control target value of the driving force generation device, the steering mechanism, or the braking device based on the information on the outside or the inside of the vehicle acquired by the vehicle exterior information detection unit 12030 or the vehicle interior information detection unit 12040 and output a control comm and to the drive system control unit 12010. For example, the microcomputer 12051 can perform cooperative control for the purpose of implementing functions of an Advanced Driver Assistance System (ADAS) including collision avoidance or impact mitigation of a vehicle, following traveling based on an inter-vehicle distance, vehicle speed maintenance driving, vehicle collision warning, vehicle lane deviation warning, or the like.

Furthermore, the microcomputer 12051 can perform cooperative control for the purpose of automated driving or the like in which autonomous travel is performed without depending on operations by the driver, by controlling the driving force generator, the steering mechanism, or the braking device or the like on the basis of information about the surroundings of the vehicle, the information being acquired by the vehicle exterior information detection unit 12030 or the vehicle interior information detection unit 12040.

In addition, the microcomputer 12051 can output a control comm and to the body system control unit 12020 on the basis of the information about the outside of the vehicle acquired by the vehicle exterior information detection unit 12030. For example, the microcomputer 12051 can perform cooperative control for the purpose of preventing glare, such as switching from a high beam to a low beam, by controlling the head lamp according to the position of a preceding vehicle or an oncoming vehicle detected by the vehicle exterior information detection unit 12030.

The audio/image output unit 12052 transmits an output signal of at least one of sound and an image to an output device capable of visually or audibly notifying a passenger or the outside of the vehicle about information. In the example of FIG. 67, an audio speaker 12061, a display unit 12062, and an instrument panel 12063 are illustrated as output devices. The display unit 12062 may include at least one of an on-board display and a head-up display, for example.

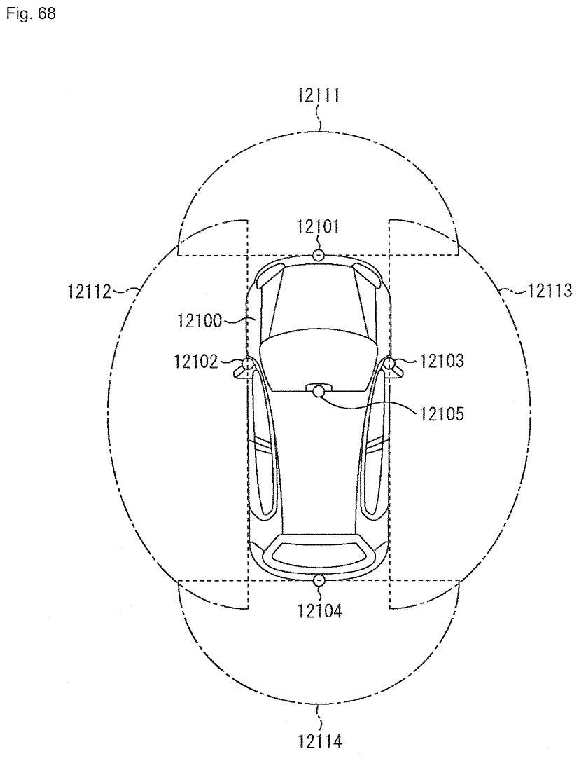

FIG. 68 is a diagram illustrating an example of the installation position of the imaging unit 12031.

In FIG. 68, a vehicle 12100 includes imaging units 12101, 12102, 12103, 12104, and 12105 as the imaging unit 12031.

For example, the imaging units 12101, 12102, 12103, 12104, and 12105 are provided at positions such as a front nose, side-view mirrors, a rear bumper, a back door, and an upper part of a windshield in the vehicle interior of the vehicle 12100. The imaging unit 12101 provided at the front nose and the imaging unit 12105 provided in an upper part of the windshield in the interior of the vehicle mainly capture front view images of the vehicle 12100. The imaging units 12102 and 12103 provided at the side-view mirrors mainly capture images on the sides of the vehicle 12100. The imaging unit 12104 provided at the rear bumper or the back door mainly captures images behind the vehicle 12100. Front view images captured by the imaging unit 12101 and 12105 are mainly used for detecting a preceding vehicle, pedestrians, obstacles, traffic lights, traffic signs, or lanes or the like.

FIG. 68 also shows an example of the imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image viewed from the upper side of the vehicle 12100 can be obtained.

At least one of the imaging units 12101 to 12104 may have a function for acquiring distance information. For example, at least one of the imaging units 12101 to 12104 may be a stereo camera including a plurality of imaging elements or may be an imaging element that has pixels for phase difference detection.

For example, the microcomputer 12051 can extract, particularly, the closest three-dimensional object that is on a traveling path of the vehicle 12100 and that travels at a predetermined speed (e.g., 0 km/h or higher) in the substantially same direction as that of the vehicle 12100, as a preceding vehicle by obtaining a distance to each three-dimensional object in the imaging ranges 12111 to 12114 and a temporal change of this distance (a relative speed with respect to the vehicle 12100) based on the distance information obtained from the imaging units 12101 to 12104. Furthermore, the microcomputer 12051 can set an inter-vehicle distance that needs to be secured in advance in front of the preceding vehicle and can perform automated brake control (also including following stop control) or automated acceleration control (also including following start control). Thus, cooperative control can be performed for the purpose of, for example, automated driving in which autonomous travel is performed without depending on operations by the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104, and can use the three-dimensional data to perform automated avoidance of obstacles. For example, the microcomputer 12051 differentiates surrounding obstacles of the vehicle 12100 into obstacles that can be viewed by the driver of the vehicle 12100 and obstacles that are difficult to view. Furthermore, the microcomputer 12051 determines a collision risk indicating the degree of risk of collision with each obstacle, and when the collision risk is a setting value or more and there is a possibility of collision, outputs an alarm to the driver through the audio speaker 12061 or the display unit 12062, or performs forced deceleration or avoidance steering through the drive system control unit 12010, so that it is possible to perform driving support for collision avoidance.

At least one of the imaging units 12101 to 12104 may be an infrared camera that detects infrared rays. For example, the microcomputer 12051 can recognize a pedestrian by determining whether or not there is a pedestrian in the captured images of the imaging units 12101 to 12104. Such pedestrian recognition is performed by, for example, a procedure of extracting feature points in the captured images of the imaging units 12101 to 12104 that are infrared cameras, and a procedure of performing pattern matching processing on a series of feature points indicating an outline of an object and determining whether or not the object is a pedestrian. When the microcomputer 12051 determines that there is a pedestrian in the captured images of the imaging units 12101 to 12104 and recognizes the pedestrian, the audio/image output unit 12052 controls the display unit 12062 so as to superimpose a square contour line for emphasis on the recognized pedestrian to display. Furthermore, the audio/image output unit 12052 may control the display unit 12062 so as to display an icon indicating a pedestrian or the like at a desired position.

The present disclosure can also take the following configurations.

(1)

A light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; an inter-pixel separation part that extends in the thickness direction of the semiconductor layer and separates the pixels adjacent to each other; and a plurality of pixel transistors that are formed on the second surface part of the semiconductor layer and configure a reading circuit that outputs a pixel signal based on the electric charge, in which the inter-pixel separation part has an upper surface part positioned on the second surface part side of the semiconductor layer, and in which at least one of the plurality of pixel transistors has a gate electrode crossing two or more adjacent pixels across an upper surface part of the inter-pixel separation part in a plan view.

(2)

The light detection device described in (1) described above, in which the gate electrode has a head part that is disposed on an outside of the second surface part of the semiconductor layer via a gate insulating film and an embedded part that protrudes from the head part to the semiconductor layer side and is partly embedded in the upper surface part of the inter-pixel separation part.

(3)

The light detection device described in (2) described above, in which the inter-pixel separation part has a first conductivity-type area disposed in an extending direction, a second conductivity-type area opposite to the first conductivity-type area, and a first insulating film interposed between the first conductivity-type area and the second conductivity-type area, and the gate electrode has a bottom part of the embedded part, a side wall part of the embedded part, and a second insulating film, which is thicker than the gate insulating film disposed in the side wall part, between the bottom part and the first conductivity-type area and the second conductivity-type area of the inter-pixel separation part.

(4)

The light detection device described in (3) described above, in which the gate electrode has an opening part formed from the bottom part of the embedded part toward the head part, and the opening part is in contact with the first insulating film of the inter-pixel separation part.

(5)

The light detection device described in (4) described above, in which the gate electrode has an exposed part that is formed in the head part and exposes the upper surface part of the inter-pixel separation part that is in contact with the opening part.

(6)

The light detection device described in (1) described above, in which the gate electrode has a channel part in the upper surface part of the inter-pixel separation part.

(7)

The light detection device described in (1) described above, in which at least one of the plurality of pixel transistors has a source region and a drain region in the upper surface part of the inter-pixel separation part in a plan view.

(8)

The light detection device described in (1) described above, in which at least one of the plurality of pixel transistors has a source region, a drain region, and a channel part electrically connecting the source region and the drain region in the upper surface part of the inter-pixel separation part in a plan view.

(9)

The light detection device described in (1) described above, further including an element separation part that is formed in the second surface part of the semiconductor layer and has an upper surface part, a side surface part, and a bottom surface part, in which at least one of the plurality of pixel transistors has a gate electrode crossing two or more adjacent pixels across the upper surface part of the inter-pixel separation part in a plan view and a channel part formed from the bottom surface part of the element separation part toward the upper surface part, and the gate electrode has a head part disposed on an outside of the second surface part of the semiconductor layer via a gate insulating film, a first embedded part that protrudes from the head part to the semiconductor layer side and is partly embedded in the upper surface part of the inter-pixel separation part, and a second embedded part that is partly embedded in the upper surface part of the element separation part.

(10)

The light detection device described in (9) described above, in which a bottom part of the first embedded part is in contact with the upper surface part of the inter-pixel separation part, and a bottom part of the second embedded part is in contact with the bottom surface part of the element separation part.

(11)

The light detection device described in (9) described above, in which the element separation part has a third insulating film between the side surface part and a side wall part of the second embedded part of the gate electrode.

(12)

The light detection device described in (9) described above, in which at least one of the plurality of pixel transistors has a gate electrode crossing two or more adjacent pixels across the upper surface part of the inter-pixel separation part in a plan view, a first channel part formed from the bottom surface part of the element separation part positioned in a first pixel crossed by the gate electrode toward the upper surface part, and a second channel part that is formed from the bottom surface part of the element separation part positioned in a second pixel crossed by the gate electrode toward the upper surface part.

(13)

The light detection device described in (12) described above, in which the inter-pixel separation part has a conductive layer disposed in the upper surface part.

(14)

The light detection device described in (13) described above, in which the conductive layer includes: a first contact part connected to a source region of the first channel part and a source region of the second channel part; and a second contact part connected to a drain region of the first channel part and a drain region of the second channel part.

(15)

The light detection device described in (13) described above, in which the first pixel has a first contact part connected to a source region of the first channel part and a source region of the second channel part, and in which the second pixel has a second contact part connected to a drain region of the first channel part and a drain region of the second channel part.

(16)

The light detection device described in (9) described above, further including a fourth insulating film, which is thicker than the gate insulating film, between a bottom part of the second embedded part of the gate electrode and the bottom surface part of the element separation part.

(17)

The light detection device described in (9) described above, in which the inter-pixel separation part has a conductive material disposed in an extending direction.

(18)

The light detection device described in (9) described above, in which the inter-pixel separation part is formed to extend from the first surface part of the semiconductor layer in the thickness direction of the semiconductor layer.

(19)

The light detection device described in (18) described above, in which at least one of the plurality of pixel transistors has a gate electrode crossing two or more adjacent pixels across the upper surface part of the inter-pixel separation part in a plan view, a first channel part formed from the bottom surface part of the element separation part positioned in a first pixel crossed by the gate electrode toward the upper surface part, a second channel part formed from the bottom surface part of the element separation part positioned in a second pixel crossed by the gate electrode toward the upper surface part, and a third channel part formed from the upper surface part of the inter-pixel separation part toward the head part of the gate electrode.

(20)

The light detection device described in (12) described above, further including an intra-pixel separation part that extends in a row direction or a column direction in a plan view along with extending in the thickness direction of the semiconductor layer and separates the first and second pixels into two first pixels and two second pixels respectively, in which the first channel part and the second channel part are formed in a direction parallel to the intra-pixel separation part.

(21)

The light detection device described in (12) described above, further including an intra-pixel separation part that extends in a row direction or a column direction in a plan view along with extending in the thickness direction of the semiconductor layer and separates the first and second pixels into two first pixels and two second pixels respectively, in which the first channel part and the second channel part are formed in a direction perpendicular to the intra-pixel separation part.

(22)

The light detection device described in (12) described above, further including an intra-pixel separation part that extends in a row direction or a column direction in a plan view along with extending in the thickness direction of the semiconductor layer and separates the first and second pixels into two first pixels and two second pixels respectively, in which at least one of plurality of other pixel transistors has a gate electrode that crosses over the upper surface part of the intra-pixel separation part in a plan view.

(23)

The light detection device described in (1) described above, in which each of the plurality of pixels has a floating diffusion part that accumulates the electric charge, the plurality of pixel transistors have amplification transistors each amplifying a potential corresponding to an amount of the electric charge accumulated in the floating diffusion part and outputting a pixel signal corresponding to the amplified potential, at least part of the plurality of pixels configure shared pixels, and the amplification transistor has a gate electrode crossing two or more adjacent pixels across the upper surface part of the inter-pixel separation part for each of the shared pixels.

(24)

The light detection device described in (23) described above, in which the plurality of pixel transistors have selection transistors each selectively deriving a pixel signal output from the amplification transistor, and the selection transistor has a gate electrode crossing two or more adjacent pixels across the upper surface part of the inter-pixel separation part for each of the shared pixels.

(25)

The light detection device described in (24) described above, further including: a first wiring connecting floating diffusion parts of the plurality of pixels; and a second wiring connecting the first wiring and gate electrodes of a plurality of the amplification transistors formed across a plurality of pixels of the shared pixels.

(26)

The light detection device described in (23) described above, in which a plurality of contacts are arranged in the gate electrode.

(27)

The light detection device described in (23) described above, in which the plurality of pixel transistors further have: a reset transistor resetting a signal electric charge accumulated in the floating diffusion part; and a switching transistor for electrically coupling the floating diffusion part to additional capacitance, and the reset transistor and the switching transistor have gate electrodes crossing two or more adjacent pixels across the upper surface part of the inter-pixel separation part for each of the shared pixels.

(28)

The light detection device described in (24) described above, further including: a first conductive material that is formed in the upper surface part of the inter-pixel separation part and electrically connects floating diffusion parts of the plurality of pixels; and a second conductive material that is formed in the upper surface part of the inter-pixel separation part and electrically connects a plurality of channel parts of the amplification transistors of the shared pixels and a plurality of channel parts of the selection transistors of the shared pixels.

(29)

The light detection device described in (23) described above, in which the plurality of amplification transistors of the shared pixels have: a first amplification transistor having a gate electrode crossing two or more adjacent pixels across the upper surface part of the inter-pixel separation part; and a second amplification transistor that is connected in parallel with the first amplification transistor and has a gate electrode crossing two or more adjacent pixels across the upper surface part of the inter-pixel separation part.

(30)

The light detection device described in (27) described above further including: a first wiring electrically connecting the floating diffusion parts of the plurality of pixels; a second wiring electrically connecting the first wiring and the gate electrode of the amplification transistor formed across a plurality of pixels of the shared pixels; a third wiring electrically connecting the second wiring and the switching transistors of the shared pixels; a fourth wiring electrically connecting the amplification transistors of the shared pixels and the selection transistors of the shared pixels; and a fifth wiring electrically connecting the switching transistors of the shared pixels and the reset transistors of the shared pixels.

(31)

The light detection device described in (27) described above further including: a first conductive material that is formed in the upper surface part of the inter-pixel separation part and electrically connects floating diffusion parts of the plurality of pixels; a second conductive material that is formed in the upper surface part of the inter-pixel separation part and electrically connects the amplification transistors of the shared pixels and the selection transistors of the shared pixels; and a third conductive material that is formed in the upper surface part of the inter-pixel separation part and electrically connects the switching transistors of the shared pixels and the reset transistors of the shared pixels.

(32)

The light detection device described in (12) described above further including a wiring that electrically connects a source region of the first channel part and a drain region of the second channel part or a drain region of the first channel part and a source region of the second channel part across the upper surface part of the inter-pixel separation part in a column direction in a plan view.

(33)

The light detection device described in (12) described above further including a conductive layer in the upper surface part of the inter-pixel separation part between a source region of the first channel part and a drain region of the second channel part or a drain region of the first channel part and a source region of the second channel part in a column direction in a plan view.

(34)

The light detection device described in (12) described above, further including a wiring that electrically connects a source region of the first channel part and a drain region of the second channel part or a drain region of the first channel part and a source region of the second channel part across the upper surface part of the inter-pixel separation part in a row direction in a plan view.

(35)

The light detection device described in (12) described above further including a conductive layer in the upper surface part of the inter-pixel separation part between a source region of the first channel part and a drain region of the second channel part or a drain region of the first channel part and a source region of the second channel part in a row direction in a plan view.

(36)

The light detection device described in (12) described above, in which the gate electrode covers a source region of the first channel part and a drain region of the second channel part or a drain region of the first channel part and a source region of the second channel part in a column direction in a plan view, and in which a conductive layer is included in the upper surface part of the inter-pixel separation part between the source region of the first channel part and the drain region of the second channel part or between the drain region of the first channel part and the source region of the second channel part.

(37)

The light detection device described in (1) described above, further including a wiring layer that is stacked on the second surface part of the semiconductor layer and includes a plurality of metal wirings, in which a contact structure part electrically connected to the metal wiring of the wiring layer is arranged in the gate electrode, and the contact structure part shields light that has passed through each pixel of the semiconductor layer out of the light incident in the semiconductor layer.

(38)

The light detection device described in (37) described above, in which the contact structure part has a shape pattern part along a direction of connecting a first pixel and a second pixel crossed by the gate electrode.

(39)

The light detection device described in (37) described above, in which the gate electrode crosses two or more adjacent pixels across an upper surface part of an intersection portion at which an inter-pixel separation part extending in a row direction in a plan view intersects with an inter-pixel separation part extending in a column direction in a plan view. (40)

The light detection device described in (39) described above, in which the contact structure part has a first shape pattern part formed along the row direction of the inter-pixel separation part and a second shape pattern part that intersects with the first shape pattern part and is formed along the column direction of the inter-pixel separation part.

(41)

The light detection device described in (39) described above, in which the contact structure part has a shape pattern part formed along a direction of connecting a first pixel and a second pixel that are crossed by the gate electrode and pass through the intersection portion to be diagonally located.

(42)

The light detection device described in (39) described above, in which the contact structure part has a first shape pattern part formed along a direction of connecting a first pixel and a second pixel that are crossed by the gate electrode and pass through the intersection portion to be diagonally located, and a second shape pattern part that intersects with the first shape pattern part and is formed along a direction of connecting a third pixel and a fourth pixel crossed by the gate electrode.

(43)

The light detection device described in (39) described above, in which the contact structure part has a first shape pattern part formed along a direction of connecting a first pixel and the inter-pixel separation part when the gate electrode passes through the intersection portion and crosses the first pixel and a second pixel that are diagonally located, a second shape pattern part that is connected to the first shape pattern part and is formed along the row direction or the column direction of the inter-pixel separation part, and a third shape pattern part formed along a direction of connecting the second shape pattern part and the second pixel.

(44)

The light detection device described in (39) described above, in which the gate electrode crosses a first pixel, a second pixel, and a third pixel across the upper surface part of the intersection portion of the inter-pixel separation part, and in which the contact structure part has a first shape pattern part formed along a row direction of the inter-pixel separation part and a second shape pattern part formed along a column direction of the inter-pixel separation part, for a fourth pixel that is not crossed by the gate electrode.

(45)

The light detection device described in (44) described above, in which the fourth pixel is a pixel that detects a wavelength of red light or a pixel that detects a wavelength of an infrared region.

(46)

The light detection device described in (37) described above, in which the gate electrode crosses two or more adjacent pixels across an upper surface part of a first intersection portion at which an inter-pixel separation part extending in a row direction in a plan view intersects with an inter-pixel separation part extending in a column direction in a plan view, and a structure part other than the gate electrode of the pixel transistor is arranged in a second intersection portion other than the first intersection portion.

(47)

The light detection device described in (46) described above, in which the structure part arranged in the second intersection portion is at least one of a contact structure part connected to the metal wiring of the wiring layer, a conduction structure part, in which the contact structure part is arranged, and in which at least part of a plurality of pixels separated by the inter-pixel separation part are caused to be conductive, a dummy transistor, in which the contact structure part is arranged, and in which a semiconductor lamination structure formed from polysilicon is provided, and a polysilicon wiring in which the contact structure part is arranged.

(48)

The light detection device described in (47) described above, in which the conduction structure part arranged in the second intersection portion causes the floating diffusion parts of part of a plurality of pixels separated by the inter-pixel separation part to be conductive.

(49)

The light detection device described in (47) described above, in which the conduction structure part arranged in the second intersection portion causes contact parts of the well regions of part of the plurality of pixels separated by the inter-pixel separation part to be conductive.

(50)

The light detection device described in (47) described above, in which the dummy transistor arranged in the second intersection portion has a height allowing protrusion to the wiring layer to be different from a height of the pixel transistor protruding to the wiring layer.

(51)

The light detection device described in (38) described above, in which the shape pattern part of the contact structure has at least one of a linear part, a double linear part, a structure in which a plurality of dots are aligned in one direction, a structure in which a plurality of first dots are aligned in one direction, and a plurality of second dots adjacent to the plurality of first dots are positioned between the plurality of first dots and are aligned in a same direction as that of the plurality of first dots, and a structure in which a plurality of dots are densely arranged.

(52)

The light detection device described in (47) described above, in which the conduction structure part arranged in the second intersection portion has any one of a side contact part formed by etching into the inter-pixel separation part and a structure part other than the side contact part.

(53)

The light detection device described in (37) described above, in which at least part of the plurality of pixels configure a shared pixel group sharing a conduction structure part, in which the contact structure part is arranged, and in which at least part of a plurality of pixels separated by the inter-pixel separation part are caused to be conductive, and the gate electrodes of the pixel transistors, the inter-pixel separation part has an intra-pixel group separation part arranged between pixels adjacent to each other among the shared pixel group and an inter-pixel group separation part arranged between shared pixel groups adjacent to each other, and the conduction structure part is arranged in the upper surface part of a first intersection portion at which an intra-pixel group separation part extending in a row direction intersects with an intra-pixel group separation part extending in a column direction, and the gate electrode of the pixel transistor is arranged in the upper surface part of a second intersection portion at which an inter-pixel group separation part extending in the row direction intersects with an inter-pixel group separation part extending in the column direction.

(54)

The light detection device described in (37) described above, in which at least part of the plurality of pixels configure a shared pixel group sharing a conduction structure part, in which the contact structure part is arranged, and in which at least part of a plurality of pixels separated by the inter-pixel separation part are caused to be conductive, and the gate electrodes of the pixel transistors, and in which the inter-pixel separation part has an intra-pixel group separation part arranged between pixels that are adjacent to each other in the shared pixel group and an inter-pixel group separation part arranged between shared pixel groups that are adjacent to each other, and in which the gate electrode of the pixel transistor is arranged in the upper surface part of a first intersection portion at which an inter-pixel group separation part extending in a row direction intersects with an inter-pixel group separation part extending in a column direction, and the conduction structure part is arranged in the upper surface part of a second intersection portion at which the intra-pixel group separation part intersects with the inter-pixel group separation part.

(55)

The light detection device described in (54) described above, in which, in the upper surface part of a third intersection portion at which an intra-pixel group separation part extending in a row direction intersects with an intra-pixel group separation part extending in a column direction, the contact structure part is arranged, and a dummy transistor having a semiconductor lamination structure made of polysilicon is arranged.

(56)

The light detection device described in (54) described above, in which each of the plurality of pixels has a floating diffusion part that accumulates the electric charge, the conduction structure part arranged in the second intersection portion causes the floating diffusion parts of part of a plurality of pixels separated by the inter-pixel separation part to be conductive.

(57)

The light detection device described in (54) described above, in which each of the plurality of pixels has a contact part of a well region used for supplying a potential to the semiconductor layer, the conduction structure part arranged in the second intersection portion causes contact parts of the well regions of part of a plurality of pixels separated by the inter-pixel separation part to be conductive.

(58)

An electronic device including a light detecting device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; an inter-pixel separation part that extends in the thickness direction of the semiconductor layer and separates the pixels adjacent to each other; and a plurality of pixel transistors that are formed on the second surface part of the semiconductor layer and configure a reading circuit that outputs a pixel signal based on the electric charge, in which the inter-pixel separation part has an upper surface part positioned on the second surface part side of the semiconductor layer, at least one of the plurality of pixel transistors has a gate electrode crossing two or more adjacent pixels across an upper surface part of the inter-pixel separation part in a plan view.

(59)

A light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; a wiring layer that is laminated on the second surface part of the semiconductor layer and includes a plurality of metal wirings; and an inter-pixel separation part extending in the thickness direction of the semiconductor layer and separating the pixels adjacent to each other, in which the inter-pixel separation part has an upper surface part positioned on the second surface part side of the semiconductor layer, and a contact structure part electrically connected to the metal wiring of the wiring layer is arranged in the upper surface part of the inter-pixel separation part, and the contact structure part shields light that has passed through each pixel of the semiconductor layer out of the light incident in the semiconductor layer.

(60)

The light detection device described in (59) described above, in which the contact structure part has a first shape pattern part formed along the row direction of the inter-pixel separation part and a second shape pattern part that intersects with the first shape pattern part and is formed along the column direction of the inter-pixel separation part.

(61)

The light detection device described in (60) described above, in which the first and second shape pattern parts have at least one of a linear part, a double linear part, a structure in which a plurality of dots are aligned in one direction, a structure in which a plurality of first dots are aligned in one direction, and a plurality of second dots adjacent to the plurality of first dots are positioned between the plurality of first dots and are aligned in a same direction as that of the plurality of first dots, and a structure in which a plurality of dots are densely arranged.

(62)

A light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; a wiring layer that is laminated on the second surface part of the semiconductor layer and includes a plurality of metal wirings; and an inter-pixel separation part extending in the thickness direction of the semiconductor layer and separating the pixels adjacent to each other, in which the inter-pixel separation part has an upper surface part positioned on the second surface part side of the semiconductor layer, a conduction structure part causing at least part of a plurality of pixels separated by the inter-pixel separation part to be conductive is arranged in the upper surface part of the inter-pixel separation part, a contact structure part electrically connected to the metal wiring of the wiring layer is arranged in the conduction structure part, and the contact structure part shields light that has passed through each pixel of the semiconductor layer out of the light incident in the semiconductor layer.

(63)

The light detection device described in (62) described above, in which the conduction structure part causes floating diffusion parts of part of a plurality of pixels separated by the inter-pixel separation part to be conductive.

(64)

The light detection device described in (62) described above, in which the conduction structure part causes contact parts of well regions of a plurality of pixels separated by the inter-pixel separation part to be conductive.

(65)

The light detection device described in (62) described above, in which the contact structure part has a shape pattern part formed along a direction of connecting a first pixel and a second pixel crossed by the conduction structure part.

(66)

The light detection device described in (62) described above, in which the conduction structure part crosses two or more adjacent pixels across the upper surface part of an intersection portion at which an inter-pixel separation part extending in a row direction in a plan view intersects with an inter-pixel separation part extending in a column direction in a plan view.

(67)

The light detection device described in (62) described above, in which the contact structure part has a first shape pattern part formed along the row direction of the inter-pixel separation part and a second shape pattern part that intersects with the first shape pattern part and is formed along the column direction of the inter-pixel separation part.

(68)

The light detection device described in (62) described above, in which the contact structure part has a shape pattern part formed along a direction of connecting a first pixel and a second pixel that are crossed by the conduction structure part and pass through the intersection portion to be diagonally located.

(69)

The light detection device described in (62) described above, in which the contact structure part has a first shape pattern part formed along a direction of connecting a first pixel and a second pixel that are crossed by the conduction structure part and pass through the intersection portion to be diagonally located and a second shape pattern part that intersects with the first shape pattern part and is formed along a direction of connecting a third pixel and a fourth pixel crossed by the conduction structure part.

(70)

The light detection device described in (62) described above, in which the contact structure part has a first shape pattern part formed along a direction of connecting a first pixel and the inter-pixel separation part when the conduction structure part passes through the intersection portion and crosses the first pixel and a second pixel that are diagonally located, a second shape pattern part that is connected to the first shape pattern part and is formed along the row direction or the column direction of the inter-pixel separation part, and a third shape pattern part formed along a direction of connecting the second shape pattern part and the second pixel.

(71)

The light detection device described in (65) described above, in which the shape pattern part of the contact structure has at least one of a linear part, a double linear part, a structure in which a plurality of dots are aligned in one direction, a structure in which a plurality of first dots are aligned in one direction, and a plurality of second dots adjacent to the plurality of first dots are positioned between the plurality of first dots and are aligned in a same direction as that of the plurality of first dots, and a structure in which a plurality of dots are densely arranged.

(72)

The light detection device described in (62) described above, in which the conduction structure part has any one of a side contact part formed by etching into the inter-pixel separation part and a structure part other than the side contact part.

(73)

A light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; a wiring layer that is laminated on the second surface part of the semiconductor layer and includes a plurality of metal wirings; and an inter-pixel separation part extending in the thickness direction of the semiconductor layer and separating the pixels adjacent to each other, in which the inter-pixel separation part has an upper surface part positioned on the second surface part side of the semiconductor layer, a dummy transistor having a semiconductor lamination structure made of polysilicon is arranged in the upper surface part of the inter-pixel separation part, a contact structure part electrically connected to the metal wiring of the wiring layer is arranged in the dummy transistor, and the contact structure part shields light that has passed through each pixel of the semiconductor layer out of the light incident in the semiconductor layer.

(74)

The light detection device described in (73) described above, in which the dummy transistor has a height allowing protrusion to the wiring layer to be different from a height of the pixel transistor protruding to the wiring layer.

(75)

A light detection device including: a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view; a wiring layer that is laminated on the second surface part of the semiconductor layer and includes a plurality of metal wirings; and an inter-pixel separation part extending in the thickness direction of the semiconductor layer and separating the pixels adjacent to each other, in which the inter-pixel separation part has an upper surface part positioned on the second surface part side of the semiconductor layer, a polysilicon wiring is arranged in the upper surface part of the inter-pixel separation part, a contact structure part electrically connected to the metal wiring of the wiring layer is arranged in the polysilicon wiring, and the contact structure part shields light that has passed through each pixel of the semiconductor layer out of the light incident in the semiconductor layer.

### REFERENCE SIGNS LIST

1A, 1B, 1C, 1D, 1E, 1F, 1G, 1H, 1I, 1J, 1K, 1L, 1M, 1MA, 1MB, 1MC, 1MD, 1ME, 1MF, 1 MG, 1N, 1NA, 1NB, 1NC, 1ND, 1NE, 1NF, 10, 10A, 140OB, 10C, 10D, 1P, 1Q, 1R, 1S, 1SA, 1SB Light detection device
2 Semiconductor chip
2A Pixel array unit
2B Peripheral portion
3, 3a, 3b, 3c, 3d, 3e, 3f Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Pixel block
16, 16A Reading circuit
21, 21A, 21B, 21C, 21D, 21E, 21H, 21a-1, 21b-1 Inter-pixel separation part
21-3 Intersection portion
31 Semiconductor layer
21a, 24b Upper surface part
21b n-type region
21c p-type region
21d, 24a Insulating film
21e, 21g3, 21h3, 21i3 Channel part
21f1, 21g1, 21h1, 21i1 Source region
21f2, 21g2, 21h2, 21i2 Drain region
21c-1 Intersection portion
22, 22a, 22b, 22c, 22d Element separation part
24 Inter-pixel separation part (RDTI)
25 Intra-pixel separation part
31 Semiconductor layer
32 Wiring layer
33 Planarization film
34 Color filter layer
35 On-chip lens
36, 37, 38, 39, 60, 61, 62, 63, 64, 65, 66, 67, 72, 73, 74, 81,
82, 83 Contact structure part
38a, 38b, 61a, 61b Linear part
64a, 64b Double linear part
65a, 65b, 67a, 67b Dot row
66a1, 66b1 First dot row
66a2, 66b2 Second dot row
41, 41A, 41B, 41C, 41D, 41E, 41F, 41G, 41H, 43A, 43B, 43C, 43D,
43E, 43F, 1001, 1002, 1003a, 1003b, 1004, 1005, 1006 Gate electrode
3G1, 3G2, 3G3, 3G4 Shared pixel group
41a, 43a Head part
41b, 43c1, 43c2 Embedded part
41c Channel part
41d Insulating film
41e Opening part
41f Exposed part
42 Gate insulating film
51 Element separating part
53 Conductive layer
55 Conductive material
71 High concentration p-type layer
91 Intra-pixel group separation part
92 Inter-pixel group separation part
221 Side surface part
222 Insulating film
223 Bottom surface part
224 Insulating film
311 n-type layer
312 p-well
321 Metal wiring
441 First channel part
442 Second channel part
443 Third channel part
541 First contact part
542 Second contact part
1011 Side contact part
1022 Conduction structure part
1030 Dummy transistor
1040 Polysilicon part
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Drive system control unit
12020 Body system control unit
12030 Vehicle exterior information detection unit
12031 Imaging unit
12040 Vehicle interior information detection unit
12041 Driver state detection unit
12050 Integrated control unit
12051 Microcomputer
12052 Audio/image output portion
12061 Audio speaker
12062 Display portion
12063 Instrument panel
12100 Vehicle
12101 to 12105 Imaging unit
12111 to 12114 Imaging range

1. A light detection device comprising:
a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view;
an inter-pixel separation part that extends in the thickness direction of the semiconductor layer and separates the pixels adjacent to each other; and
a plurality of pixel transistors that are formed on the second surface part of the semiconductor layer and configure a reading circuit that outputs a pixel signal based on the electric charge,
wherein the inter-pixel separation part has an upper surface part positioned on the second surface part side of the semiconductor layer, and
wherein at least one of the plurality of pixel transistors has a gate electrode crossing two or more adjacent pixels across an upper surface part of the inter-pixel separation part in a plan view.

2. The light detection device according to claim 1, wherein the gate electrode has a head part that is disposed on an outside of the second surface part of the semiconductor layer via a gate insulating film and an embedded part that protrudes from the head part to the semiconductor layer side and is partly embedded in the upper surface part of the inter-pixel separation part.

3. The light detection device according to claim 2, wherein the inter-pixel separation part has a first conductivity-type area disposed in an extending direction, a second conductivity-type area opposite to the first conductivity-type area, and a first insulating film interposed between the first conductivity-type area and the second conductivity-type area, and
wherein the gate electrode has a bottom part of the embedded part, a side wall part of the embedded part, and a second insulating film, which is thicker than the gate insulating film disposed in the side wall part, between the bottom part and the first conductivity-type area and the second conductivity-type area of the inter-pixel separation part.

4. The light detection device according to claim 3, wherein the gate electrode has an opening part formed from the bottom part of the embedded part toward the head part, and wherein the opening part is in contact with the first insulating film of the inter-pixel separation part.

5. The light detection device according to claim 4, wherein the gate electrode has an exposed part that is formed in the head part and exposes the upper surface part of the inter-pixel separation part that is in contact with the opening part.

6. The light detection device according to claim 1, wherein the gate electrode has a channel part in the upper surface part of the inter-pixel separation part.

7. The light detection device according to claim 1, wherein at least one of the plurality of pixel transistors has a source region and a drain region in the upper surface part of the inter-pixel separation part in a plan view.

8. The light detection device according to claim 1, wherein at least one of the plurality of pixel transistors has a source region, a drain region, and a channel part electrically connecting the source region and the drain region in the upper surface part of the inter-pixel separation part in a plan view.

9. The light detection device according to claim 1, further comprising an element separation part that is formed in the second surface part of the semiconductor layer and has an upper surface part, a side surface part, and a bottom surface part, wherein at least one of the plurality of pixel transistors has a gate electrode crossing two or more adjacent pixels across the upper surface part of the inter-pixel separation part in a plan view and a channel part formed from the bottom surface part of the element separation part toward the upper surface part, and wherein the gate electrode has a head part disposed on an outside of the second surface part of the semiconductor layer via a gate insulating film, a first embedded part that protrudes from the head part to the semiconductor layer side and is partly embedded in the upper surface part of the inter-pixel separation part, and a second embedded part that is partly embedded in the upper surface part of the element separation part.

10. The light detection device according to claim 9,
wherein a bottom part of the first embedded part is in contact with the upper surface part of the inter-pixel separation part, and
wherein a bottom part of the second embedded part is in contact with the bottom surface part of the element separation part.

11. The light detection device according to claim 9, wherein the element separation part has a third insulating film between the side surface part and a side wall part of the second embedded part of the gate electrode.

12. The light detection device according to claim 9, wherein at least one of the plurality of pixel transistors has a gate electrode crossing two or more adjacent pixels across the upper surface part of the inter-pixel separation part in a plan view, a first channel part formed from the bottom surface part of the element separation part positioned in a first pixel crossed by the gate electrode toward the upper surface part, and a second channel part that is formed from the bottom surface part of the element separation part positioned in a second pixel crossed by the gate electrode toward the upper surface part.

13. The light detection device according to claim 12, wherein the inter-pixel separation part has a conductive layer disposed in the upper surface part.

14. The light detection device according to claim 13, wherein the conductive layer includes:
a first contact part connected to a source region of the first channel part and a source region of the second channel part; and
a second contact part connected to a drain region of the first channel part and a drain region of the second channel part.

15. The light detection device according to claim 13,
wherein the first pixel has a first contact part connected to a source region of the first channel part and a source region of the second channel part, and
wherein the second pixel has a second contact part connected to a drain region of the first channel part and a drain region of the second channel part.

16. The light detection device according to claim 9, further comprising a fourth insulating film, which is thicker than the gate insulating film, between a bottom part of the second embedded part of the gate electrode and the bottom surface part of the element separation part.

17. The light detection device according to claim 9, wherein the inter-pixel separation part has a conductive material disposed in an extending direction.

18. The light detection device according to claim 9, wherein the inter-pixel separation part is formed to extend from the first surface part of the semiconductor layer in the thickness direction of the semiconductor layer.

19. The light detection device according to claim 18, wherein at least one of the plurality of pixel transistors has a gate electrode crossing two or more adjacent pixels across the upper surface part of the inter-pixel separation part in a plan view, a first channel part formed from the bottom surface part of the element separation part positioned in a first pixel crossed by the gate electrode toward the upper surface part, a second channel part formed from the bottom surface part of the element separation part positioned in a second pixel crossed by the gate electrode toward the upper surface part, and a third channel part formed from the upper surface part of the inter-pixel separation part toward the head part of the gate electrode.

20. The light detection device according to claim 12, further comprising an intra-pixel separation part that extends in a row direction or a column direction in a plan view along with extending in the thickness direction of the semiconductor layer and separates the first and the second pixels into two first pixels and two second pixels respectively,
wherein the first channel part and the second channel part are formed in a direction parallel to the intra-pixel separation part.

21. The light detection device according to claim 12, further comprising an intra-pixel separation part that extends in a row direction or a column direction in a plan view along with extending in the thickness direction of the semiconductor layer and separates the first and the second pixels into two first pixels and two second pixels respectively,
wherein the first channel part and the second channel part are formed in a direction perpendicular to the intra-pixel separation part.

22. The light detection device according to claim 12, further comprising an intra-pixel separation part that extends in a row direction or a column direction in a plan view along with extending in the thickness direction of the semiconductor layer and separates the first and the second pixels into two first pixels and two second pixels respectively,
wherein at least one of plurality of other pixel transistors has a gate electrode that crosses over the upper surface part of the intra-pixel separation part in a plan view.

23. The light detection device according to claim 1, wherein each of the plurality of pixels has a floating diffusion part that accumulates the electric charge,
wherein the plurality of pixel transistors have amplification transistors each amplifying a potential corresponding to an amount of the electric charge accumulated in the floating diffusion part and outputting a pixel signal corresponding to the amplified potential,
wherein at least part of the plurality of pixels configure shared pixels, and
wherein the amplification transistor has a gate electrode crossing two or more adjacent pixels across the upper surface part of the inter-pixel separation part for each of the shared pixels.

24. The light detection device according to claim 23,
wherein the plurality of pixel transistors have selection transistors each selectively deriving a pixel signal output from the amplification transistor, and
wherein the selection transistor has a gate electrode crossing two or more adjacent pixels across the upper surface part of the inter-pixel separation part for each of the shared pixels.

25. The light detection device according to claim 24, further comprising:
a first wiring connecting floating diffusion parts of the plurality of pixels; and
a second wiring connecting the first wiring and gate electrodes of a plurality of the amplification transistors formed across a plurality of pixels of the shared pixels.

26. The light detection device according to claim 23, wherein a plurality of contacts are arranged in the gate electrode.

27. The light detection device according to claim 23, wherein the plurality of pixel transistors further have:
a reset transistor resetting a signal electric charge accumulated in the floating diffusion part; and
a switching transistor for electrically coupling the floating diffusion part to additional capacitance, and wherein the reset transistor and the switching transistor have gate electrodes crossing two or more adjacent pixels across the upper surface part of the inter-pixel separation part for each of the shared pixels.

28. The light detection device according to claim 24, further comprising:
a first conductive material that is formed in the upper surface part of the inter-pixel separation part and electrically connects floating diffusion parts of the plurality of pixels; and
a second conductive material that is formed in the upper surface part of the inter-pixel separation part and electrically connects a plurality of channel parts of the amplification transistors of the shared pixels and a plurality of channel parts of the selection transistors of the shared pixels.

29. The light detection device according to claim 23, wherein the plurality of amplification transistors of the shared pixels have:
a first amplification transistor having a gate electrode crossing two or more adjacent pixels across the upper surface part of the inter-pixel separation part; and
a second amplification transistor that is connected in parallel with the first amplification transistor and has a gate electrode crossing two or more adjacent pixels across the upper surface part of the inter-pixel separation part.

30. The light detection device according to claim 27 further comprising:
a first wiring electrically connecting the floating diffusion parts of the plurality of pixels;
a second wiring electrically connecting the first wiring and the gate electrode of the amplification transistor formed across a plurality of pixels of the shared pixels;
a third wiring electrically connecting the second wiring and the switching transistors of the shared pixels;
a fourth wiring electrically connecting the amplification transistors of the shared pixels and the selection transistors of the shared pixels; and
a fifth wiring electrically connecting the switching transistors of the shared pixels and the reset transistors of the shared pixels.

31. The light detection device according to claim 27 further comprising:
a first conductive material that is formed in the upper surface part of the inter-pixel separation part and electrically connects floating diffusion parts of the plurality of pixels;
a second conductive material that is formed in the upper surface part of the inter-pixel separation part and electrically connects the amplification transistors of the shared pixels and the selection transistors of the shared pixels; and
a third conductive material that is formed in the upper surface part of the inter-pixel separation part and electrically connects the switching transistors of the shared pixels and the reset transistors of the shared pixels.

32. The light detection device according to claim 12 further comprising a wiring that electrically connects a source region of the first channel part and a drain region of the second channel part or a drain region of the first channel part and a source region of the second channel part across the upper surface part of the inter-pixel separation part in a column direction in a plan view.

33. The light detection device according to claim 12 further comprising a conductive layer in the upper surface part of the inter-pixel separation part between a source region of the first channel part and a drain region of the second channel part or a drain region of the first channel part and a source region of the second channel part in a column direction in a plan view.

34. The light detection device according to claim 12, further comprising a wiring that electrically connects a source region of the first channel part and a drain region of the second channel part or a drain region of the first channel part and a source region of the second channel part across the upper surface part of the inter-pixel separation part in a row direction in a plan view.

35. The light detection device according to claim 12 further comprising a conductive layer in the upper surface part of the inter-pixel separation part between a source region of the first channel part and a drain region of the second channel part or a drain region of the first channel part and a source region of the second channel part in a row direction in a plan view.

36. The light detection device according to claim 12,
wherein the gate electrode covers a source region of the first channel part and a drain region of the second channel part or a drain region of the first channel part and a source region of the second channel part in a column direction in a plan view, and
wherein a conductive layer is included in the upper surface part of the inter-pixel separation part between the source region of the first channel part and the drain region of the second channel part or between the drain region of the first channel part and the source region of the second channel part.

37. The light detection device according to claim 1, further comprising a wiring layer that is stacked on the second surface part of the semiconductor layer and includes a plurality of metal wirings,
wherein a contact structure part electrically connected to the metal wiring of the wiring layer is arranged in the gate electrode, and
wherein the contact structure part shields light that has passed through each pixel of the semiconductor layer out of the light incident in the semiconductor layer.

38. The light detection device according to claim 37, wherein the contact structure part has a shape pattern part along a direction of connecting a first pixel and a second pixel crossed by the gate electrode.

39. The light detection device according to claim 37, wherein the gate electrode crosses two or more adjacent pixels across an upper surface part of an intersection portion at which an inter-pixel separation part extending in a row direction in a plan view intersects with an inter-pixel separation part extending in a column direction in a plan view.

40. The light detection device according to claim 39, wherein the contact structure part has a first shape pattern part formed along the row direction of the inter-pixel separation part and a second shape pattern part that intersects with the first shape pattern part and is formed along the column direction of the inter-pixel separation part.

41. The light detection device according to claim 39, wherein the contact structure part has a shape pattern part formed along a direction of connecting a first pixel and a second pixel that are crossed by the gate electrode and pass through the intersection portion to be diagonally located.

42. The light detection device according to claim 39, wherein the contact structure part has a first shape pattern part formed along a direction of connecting a first pixel and a second pixel that are crossed by the gate electrode and pass through the intersection portion to be diagonally located, and a second shape pattern part that intersects with the first shape pattern part and is formed along a direction of connecting a third pixel and a fourth pixel crossed by the gate electrode.

43. The light detection device according to claim 39, wherein the contact structure part has a first shape pattern part formed along a direction of connecting a first pixel and the inter-pixel separation part when the gate electrode passes through the intersection portion and crosses the first pixel and a second pixel that are diagonally located, a second shape pattern part that is connected to the first shape pattern part and is formed along the row direction or the column direction of the inter-pixel separation part, and a third shape pattern part formed along a direction of connecting the second shape pattern part and the second pixel.

44. The light detection device according to claim 39, wherein the gate electrode crosses a first pixel, a second pixel, and a third pixel across the upper surface part of the intersection portion of the inter-pixel separation part, and wherein the contact structure part has a first shape pattern part formed along a row direction of the inter-pixel separation part and a second shape pattern part formed along a column direction of the inter-pixel separation part, for a fourth pixel that is not crossed by the gate electrode.

45. The light detection device according to claim 44, wherein the fourth pixel is a pixel that detects a wavelength of red light or a pixel that detects a wavelength of an infrared region.

46. The light detection device according to claim 37,
wherein the gate electrode crosses two or more adjacent pixels across an upper surface part of a first intersection portion at which an inter-pixel separation part extending in a row direction in a plan view intersects with an inter-pixel separation part extending in a column direction in a plan view, and
wherein a structure part other than the gate electrode of the pixel transistor is arranged in a second intersection portion other than the first intersection portion.

47. The light detection device according to claim 46, wherein the structure part arranged in the second intersection portion is at least one of a contact structure part connected to the metal wiring of the wiring layer, a conduction structure part, in which the contact structure part is arranged and in which at least part of a plurality of pixels separated by the inter-pixel separation part are caused to be conductive, a dummy transistor, in which the contact structure part is arranged, and in which a semiconductor lamination structure formed from polysilicon is provided, and a polysilicon wiring in which the contact structure part is arranged.

48. The light detection device according to claim 47,
wherein each of the plurality of pixels has a floating diffusion part that accumulates the electric charge, and
wherein the conduction structure part arranged in the second intersection portion causes the floating diffusion parts of part of a plurality of pixels separated by the inter-pixel separation part to be conductive.

49. The light detection device according to claim 47,
wherein each of the plurality of pixels has a contact part of a well region used for supplying a potential to the semiconductor layer, and
wherein the conduction structure part arranged in the second intersection portion causes contact parts of the well regions of part of the plurality of pixels separated by the inter-pixel separation part to be conductive.

50. The light detection device according to claim 47, wherein the dummy transistor arranged in the second intersection portion has a height allowing protrusion to the wiring layer to be different from a height of the pixel transistor protruding to the wiring layer.

51. The light detection device according to claim 38, wherein the shape pattern part of the contact structure has at least one of a linear part, a double linear part, a structure in which a plurality of dots are aligned in one direction, a structure in which a plurality of first dots are aligned in one direction, and a plurality of second dots adjacent to the plurality of first dots are positioned between the plurality of first dots and are aligned in a same direction as that of the plurality of first dots, and a structure in which a plurality of dots are densely arranged.

52. The light detection device according to claim 47, wherein the conduction structure part arranged in the second intersection portion has any one of a side contact part formed by etching into the inter-pixel separation part and a structure part other than the side contact part.

53. The light detection device according to claim 37,
wherein at least part of the plurality of pixels configure a shared pixel group sharing a conduction structure part, in which the contact structure part is arranged, and in which at least part of a plurality of pixels separated by the inter-pixel separation part are caused to be conductive, and the gate electrodes of the pixel transistors,
wherein the inter-pixel separation part has an intra-pixel group separation part arranged between pixels adjacent to each other among the shared pixel group and an inter-pixel group separation part arranged between shared pixel groups adjacent to each other, and
wherein the conduction structure part is arranged in the upper surface part of a first intersection portion at which an intra-pixel group separation part extending in a row direction intersects with an intra-pixel group separation part extending in a column direction, and the gate electrode of the pixel transistor is arranged in the upper surface part of a second intersection portion at which an inter-pixel group separation part extending in the row direction intersects with an inter-pixel group separation part extending in the column direction.

54. The light detection device according to claim 37,
wherein at least part of the plurality of pixels configure a shared pixel group sharing a conduction structure part, in which the contact structure part is arranged, and in which at least part of a plurality of pixels separated by the inter-pixel separation part are caused to be conductive, and the gate electrodes of the pixel transistors, and
wherein the inter-pixel separation part has an intra-pixel group separation part arranged between pixels that are adjacent to each other in the shared pixel group and an inter-pixel group separation part arranged between shared pixel groups that are adjacent to each other, and
wherein the gate electrode of the pixel transistor is arranged in the upper surface part of a first intersection portion at which an inter-pixel group separation part extending in a row direction intersects with an inter-pixel group separation part extending in a column direction, and the conduction structure part is arranged in the upper surface part of a second intersection portion at which the intra-pixel group separation part intersects with the inter-pixel group separation part.

55. The light detection device according to claim 54, wherein, in the upper surface part of a third intersection portion at which an intra-pixel group separation part extending in a row direction intersects with an intra-pixel group separation part extending in a column direction, the contact structure part is arranged, and a dummy transistor having a semiconductor lamination structure made of polysilicon is arranged.

56. The light detection device according to claim 54, wherein each of the plurality of pixels has a floating diffusion part that accumulates the electric charge, and
wherein the conduction structure part arranged in the second intersection portion causes the floating diffusion parts of part of a plurality of pixels separated by the inter-pixel separation part to be conductive.

57. The light detection device according to claim 54, wherein each of the plurality of pixels has a contact part of a well region used for supplying a potential to the semiconductor layer, and
wherein the conduction structure part arranged in the second intersection portion causes contact parts of the well regions of part of a plurality of pixels separated by the inter-pixel separation part to be conductive.

58. An electronic device comprising a light detecting device including:
a semiconductor layer that has a first surface part and a second surface part positioned on sides opposite to each other in a thickness direction and in which a plurality of pixels generating electric charge through photoelectric conversion based on light incident in the first surface part are formed in a matrix pattern in a plan view;
an inter-pixel separation part that extends in the thickness direction of the semiconductor layer and separates the pixels adjacent to each other; and
a plurality of pixel transistors that are formed on the second surface part of the semiconductor layer and configure a reading circuit that outputs a pixel signal based on the electric charge,
wherein the inter-pixel separation part has an upper surface part positioned on the second surface part side of the semiconductor layer, and
wherein at least one of the plurality of pixel transistors has a gate electrode crossing two or more adjacent pixels across an upper surface part of the inter-pixel separation part in a plan view.
